(19) United States
(12) Patent Application Publication
(10) Pub. No.: US 2026/0343854 A1
(43) Pub. Date: Oct. 29, 2026

(54) SEMICONDUCTOR DEVICE INCLUDING WORD LINE AND BACK-GATE LINE

(71) Applicant: SAMSUNG ELECTRONICS CO., LTD., Suwon-si (KR)

(72) Inventors: Minju KANG, Suwon-si (KR); Heejae CHAE, Suwon-si (KR); Hyunjin LEE, Suwon-si (KR); Huijung KIM, Suwon-si (KR); Yongkwan KIM, Suwon-si (KR); Sujin KANG, Suwon-si (KR)

(73) Assignee: SAMSUNG ELECTRONICS CO., LTD., Suwon-si (KR)

(21) Appl. No.: 19/641,996

(22) Filed: Apr. 8, 2026

(30) Foreign Application Priority Data
Apr. 29, 2025 (KR) 10-2025-0056747

(51) Int. Cl. H10B 12/00

(52) U.S. Cl. CPC H10B 12/30

(57) ABSTRACT

A semiconductor device includes a first channel pattern extending in a first direction, a second channel pattern adjacent to the first channel pattern and extending in the first direction, a bit line connected to a first end of the first channel pattern and a first end of the second channel pattern and extending in a second direction orthogonal to the first direction, an information storage element connected to a second end of the second channel pattern, the second end of the second channel pattern being opposite to the first end of the second channel pattern in the first direction, a word line provided between the first channel pattern and the second channel pattern and adjacent to the information storage element in the first direction, and a back-gate line adjacent to at least one of the first channel pattern and the second channel pattern.

### CROSS-REFERENCE TO RELATED APPLICATION

This application is based on and claims priority under 35 U.S.C. § 119 to Korean Patent Application No. 10-2025-0056747, filed on Apr. 29, 2025, in the Korean Intellectual Property Office, the disclosure of which is incorporated by reference herein in its entirety.

### BACKGROUND

The present disclosure relates to a semiconductor device, and more particularly, to a semiconductor device including a word line and a back-gate line.

With the demand for compact and multifunctionalized high-performance electronic products, the integration density of semiconductor devices is increasing. Semiconductor devices having increased integration density are required. In particular, high operational reliability is required with the trend toward the high integration density of semiconductor devices.

### SUMMARY

One or more example embodiments of the present disclosure provide a semiconductor device including a plurality of memory cells and which may have increased integration density and improved operational reliability.

According to an aspect of the disclosure, a semiconductor device includes: a first channel pattern extending in a first direction; a second channel pattern adjacent to the first channel pattern and extending in the first direction; a bit line connected to a first end of the first channel pattern and a first end of the second channel pattern and extending in a second direction orthogonal to the first direction; an information storage element connected to a second end of the second channel pattern, the second end of the second channel pattern being opposite to the first end of the second channel pattern in the first direction; a word line between the first channel pattern and the second channel pattern and adjacent to the information storage element in the first direction; and a back-gate line adjacent to at least one of the first channel pattern and the second channel pattern.

According to an aspect of the disclosure, a semiconductor device includes: a substrate; first channel patterns extending in a first direction on the substrate; second channel patterns extending in the first direction on the substrate and spaced apart from the first channel patterns in a second direction that is orthogonal to the first direction; bit lines connected to first ends of the first channel patterns and first ends of the second channel patterns and extending in the second direction; information storage elements connected to second ends of the second channel patterns, the second ends of the second channel patterns being opposite to the first ends of the second channel patterns in the first direction; word lines, each of the word lines being between one of the first channel patterns and one of the second channel patterns, which are adjacent to each other in the second direction, each of the word lines being adjacent to one of the information storage elements in the first direction, and each of the word lines extending in a third direction that is orthogonal to the first direction and the second direction; and back-gate lines adjacent to the information storage elements and extending in the third direction.

According to an aspect of the disclosure, a semiconductor device includes: a substrate; first channel patterns extending in a first horizontal direction on the substrate; second channel patterns extending in the first horizontal direction on the substrate and spaced apart from the first channel patterns in a vertical direction; bit lines connected to first ends of the first channel patterns and first ends of the second channel patterns and extending in the vertical direction; information storage elements connected to second ends of the second channel patterns, the second ends of the second channel patterns being opposite to the first ends of the second channel patterns in the first horizontal direction; word lines, each of the word lines being between one of the first channel patterns and one of the second channel patterns, which are adjacent to each other in the vertical direction, each of the word lines being adjacent to one of the information storage elements in the first horizontal direction, and each of the word lines extending in a second horizontal direction that is orthogonal to the first horizontal direction; back-gate lines adjacent to the second channel patterns and the information storage elements, and extending in the second horizontal direction; first gate dielectric layers between the first channel patterns and the information storage elements; second gate dielectric layers between the second channel patterns and the back-gate lines; and third gate dielectric layers between the first channel patterns and the word lines and between the second channel patterns and the word lines, wherein each of the word lines is spaced apart from an adjacent one of the information storage elements by a first separation distance in the first horizontal direction, and wherein each of the back-gate lines is spaced apart from an adjacent one of the information storage elements by a second separation distance in the vertical direction, and the second separation distance is less than the first separation distance.

According to aspect of the disclosure, a method of manufacturing a semiconductor device includes: forming, on a substrate, a stack structure including a plurality of first channel layers, a plurality of first sacrificial layers, a plurality of second sacrificial layers, and a plurality of third sacrificial layers; forming a deep trench hole passing through the stack structure; forming a first isolation trench and a second isolation trench through the stack structure, the first isolation trench and the second isolation trench dividing the plurality of first channel layers into a plurality of first channel patterns and being in communication with the deep trench hole; forming a plurality of first removal spaces and a plurality of second removal spaces by removing the plurality of first sacrificial layers and the plurality of second sacrificial layers through the second isolation trench; forming a plurality of information storage elements; filling a plurality of third removal spaces corresponding to portions of the plurality of second sacrificial layers; forming a plurality of fourth removal spaces by removing the plurality of third sacrificial layers through the second isolation trench; forming a plurality of second channel layers covering inner surfaces of the plurality of fourth removal spaces; forming a plurality of back-gate lines filling portions of the plurality of fourth removal spaces; and forming a plurality of gate lines filling portions of the plurality of second removal spaces.

The method may further include forming at least one plate electrode in the second isolation trench and forming a plurality of bit lines in the first isolation trench.

The method may further include forming a plurality of second channel patterns by removing portions of the plurality of second channel layers through the first isolation trench.

The plurality of first channel patterns may extend in a first horizontal direction on the substrate, the plurality of second channel patterns may be spaced apart from the plurality of first channel patterns in a vertical direction and may extend in the first horizontal direction on the substrate, the plurality of bit lines may be connected to ends of the plurality of first channel patterns and ends of the plurality of second channel patterns in the first horizontal direction and may extend in the vertical direction, and the plurality of information storage elements may be connected to opposite ends of the plurality of second channel patterns in the first horizontal direction.

The at least one plate electrode may be spaced apart from the plurality of bit lines, the plurality of second channel patterns, and the plurality of information storage elements and may be connected to opposite ends of the plurality of first channel patterns in the first horizontal direction.

The stack structure may be formed such that the plurality of first channel patterns are spaced apart from each other in the vertical direction, the plurality of first sacrificial layers are spaced apart from each other in the vertical direction, the plurality of second sacrificial layers are spaced apart from each other in the vertical direction, and the plurality of third sacrificial layers are spaced apart from each other in the vertical direction.

The stack structure may be formed such that each of the plurality of first channel layers is between a first sacrificial layer and a second sacrificial layer, which are adjacent to each other in the vertical direction among the plurality of first sacrificial layers and the plurality of second sacrificial layers, each of the plurality of first sacrificial layers is between first channel layers adjacent to each other in the vertical direction among the plurality of first channel layers, each of the plurality of second sacrificial layers is between a first channel layer and a third sacrificial layer, which are adjacent to each other among the plurality of first channel layers and the plurality of third sacrificial layers, and each of the plurality of third sacrificial layers is between second sacrificial layers adjacent to each other in the vertical direction among the plurality of second sacrificial layers.

Each of the plurality of word lines may be spaced apart from an adjacent one of the plurality of information storage elements by a first separation distance, and each of the plurality of back-gate lines may be spaced apart from an adjacent one of the plurality of information storage elements by a second separation distance that is less than the first separation distance.

Each of the plurality of word lines may be spaced apart from an adjacent one of the plurality of bit lines by a third separation distance, and each of the plurality of back-gate lines may be spaced apart from an adjacent one of the plurality of bit lines by a fourth separation distance that is greater than the third separation distance.

Each of the plurality of back-gate lines and the adjacent one of the plurality of information storage elements may at least partially overlap with each other in the vertical direction

### BRIEF DESCRIPTION OF THE DRAWINGS

The above and other aspects, features, and advantages of certain embodiments of the present disclosure will be more apparent from the following detailed description taken in conjunction with the accompanying drawings, in which:

FIG. 1 is a conceptual perspective view of a semiconductor device according to one or more example embodiments;

FIG. 2 is an equivalent circuit diagram of a memory cell of a semiconductor device, according to one or more example embodiments;

FIG. 3 illustrates a memory cell of a semiconductor device, according to one or more example embodiments;

FIG. 4 illustrates a semiconductor device including a plurality of memory cells, according to one or more example embodiments;

FIG. 5 is a conceptual perspective view of a semiconductor device including a plurality of memory cells, according to one or more example embodiments;

FIGS. 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, and 33D are diagrams illustrating a method of manufacturing a semiconductor device, according to one or more example embodiments;

FIGS. 34A, 34B, 34C, and 34D are diagrams illustrating a semiconductor device according to one or more example embodiments;

FIG. 35 illustrates a memory cell of a semiconductor device, according to one or more example embodiments;

FIGS. 36A, 36B, and 36C illustrate memory cells of semiconductor devices, respectively, according to one or more example embodiments;

FIG. 37 illustrates a memory cell of a semiconductor device, according to one or more example embodiments;

FIGS. 38A, 38B, 38C and 38D are diagrams illustrating a semiconductor device according to one or more example embodiments;

FIG. 39 is a diagram illustrating a semiconductor device according to one or more example embodiments;

FIG. 40 is a diagram illustrating a semiconductor device according to one or more example embodiments;

FIGS. 41A, 41B, and 41C illustrate memory cells of semiconductor devices, respectively, according to one or more example embodiments;

FIG. 42 is a conceptual perspective view of a semiconductor device including a plurality of memory cells, according to one or more example embodiments;

FIGS. 43A, 43B, 43C, 43D, and 43E illustrate memory cells of semiconductor devices, respectively, according to one or more example embodiments;

FIGS. 44A and 44B illustrate word lines of semiconductor devices, respectively, according to one or more example embodiments;

FIGS. 45A, 45B, and 45C illustrate information storage elements of semiconductor devices, respectively, according to one or more example embodiments;

FIG. 46 illustrates a semiconductor device including a plurality of memory cells, according to one or more example embodiments;

FIG. 47 illustrates a semiconductor device including a plurality of memory cells, according to one or more example embodiments;

FIG. 48 illustrates a memory cell of a semiconductor device, according to one or more example embodiments;

FIGS. 49A and 49B are respectively conceptual perspective views of semiconductor devices including a plurality of memory cells, according to one or more example embodiments; and

FIGS. 50A and 50B respectively illustrate semiconductor devices including a plurality of memory cells, according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

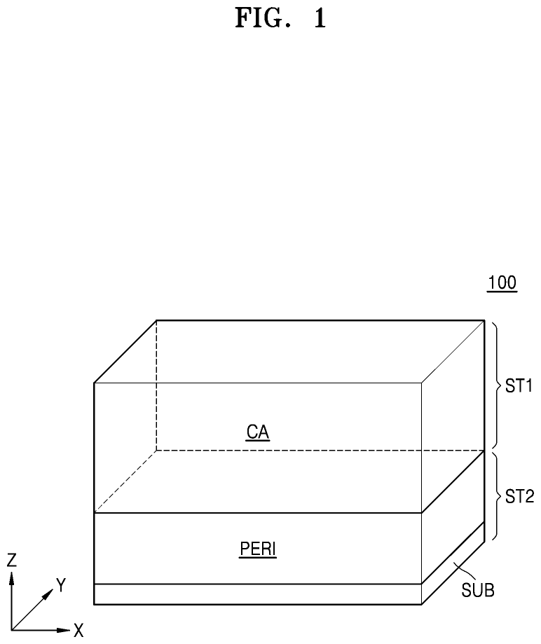

FIG. 1 is a conceptual perspective view of a semiconductor device according to one or more example embodiments.

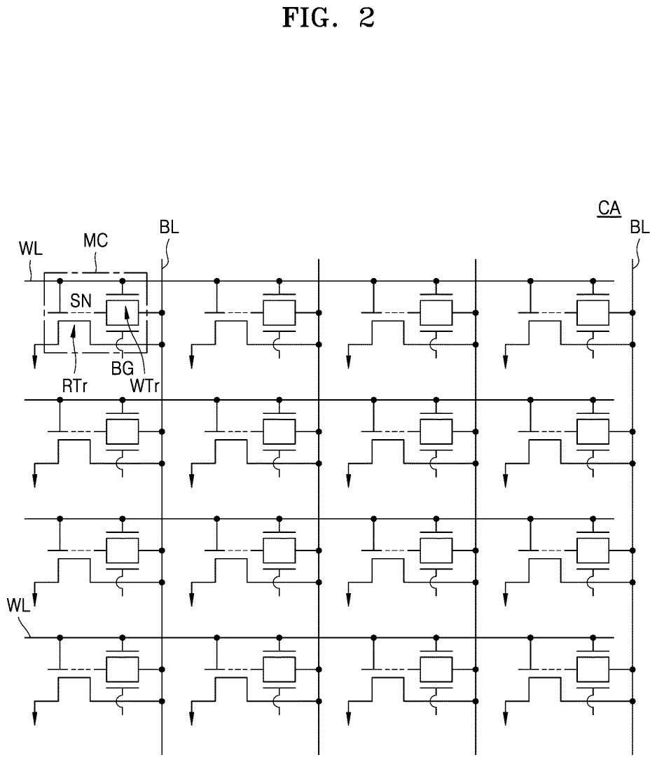

Referring to FIG. 1, a semiconductor device 100 may include a first structure ST1 and a second structure ST2, which are stacked in the vertical direction. In one or more example embodiments, the second structure ST2 may be arranged below the first structure ST1 but one or more example embodiments are not limited thereto. For example, the second structure ST2 may be arranged above the first structure ST1. The first structure ST1 may include a memory cell array CA. The memory cell array CA may include memory cells MC described with reference to FIG. 2 below.

The second structure ST2 may include a peripheral circuit region PERI on a peripheral substrate SUB. The peripheral circuit region PERI may include a peripheral circuit element including a peripheral transistor. For example, logic elements, such as an inverter circuit, a NAND gate circuit, a NOR gate circuit, an AND gate circuit, an OR gate circuit, an XOR gate circuit, an XNOR gate circuit, a NOT gate circuit, and an antifuse, may be arranged in the peripheral circuit region PERI. The peripheral circuit region PERI may also include peripheral circuits, such as a sense amplifier and a sub word line driver, which are used for the operation of the memory cells MC, and peripheral circuits for input/output of data or a command or input of power/ground.

The first structure ST1 may be bonded to the second structure ST2. In one or more example embodiments, the first structure ST1 may be bonded to the second structure ST2 through metal-oxide hybrid bonding. For example, the first structure ST1 may include first bonding pads on the bottom surface thereof, and the second structure ST2 may include second bonding pads, on the top surface thereof, which are bonded to the first bonding pads. After the first bonding pads face the second bonding pads, the first bonding pads and the second bonding pads may be expanded by heat to contact each other and thus be joined by diffusion bonding, thereby forming a single body through diffusion of metal atoms included therein. The first bonding pads and the second bonding pads may each include a material including copper (Cu). The first bonding pads and the second bonding pads may electrically connect the first structure ST1 to the second structure ST2. In one or more example embodiments, the first structure ST1 may be bonded to the second structure ST2 through direct bonding. For example, the semiconductor device 100 may include connection vias, which extend in the vertical direction (e.g., a Z direction) and pass through the bonding surface between the first structure ST1 and the second structure ST2. The connection vias may electrically connect the first structure ST1 to the second structure ST2.

FIG. 2 is an equivalent circuit diagram of a memory cell of a semiconductor device, according to one or more example embodiments.

Referring to FIG. 2, according to one or more example embodiments a memory cell array CA may include a plurality of memory cells MC. The memory cells MC may be connected to bit lines BL and word lines WL. Each of the memory cells MC may include a write transistor Wtr, a read transistor Rtr, and a storage node SN. The storage node SN may function as a gate (e.g., a floating gate) of the read transistor Rtr and may be electrically connected to the write transistor Wtr. For example, the storage node SN may be electrically connected to the channel of the write transistor Wtr.

Each of the memory cells MC may be selected by one of the bit lines BL and one of the word lines WL. Each of the memory cells MC may function as a dynamic random access memory (DRAM), on which a write operation for storing information and a read operation for reading information may be performed, and may not include a capacitor. For example, each of the memory cells MC may store information in the storage node SN instead of a capacitor and may be referred to as two-transistor (2T) memory cell.

The write transistor Wtr may store charges in the storage node SN. The threshold voltage of the read transistor Rtr having the storage node SN as the gate thereof may vary with the amount of charges stored in the storage node SN. According to the threshold voltage of the read transistor Rtr, information stored in a memory cell MC may be read as “0” or “1”.

An end of the channel of the write transistor Wtr may be connected to a bit line BL, and an opposite end of the channel of the write transistor Wtr may be connected to the storage node SN. A gate of the write transistor Wtr may be electrically connected to a word line WL.

An end of the channel of the read transistor Rtr may be connected to the bit line BL, and an opposite end of the channel of the read transistor Rtr may be grounded. The gate of the read transistor Rtr may be electrically connected to the word line WL. The word line WL may function as the gate of the read transistor Rtr together with the storage node SN. For example, the storage node SN and the word line WL may be used to turn on or off the read transistor Rtr.

The bit line BL may be electrically connected to the memory cell MC. For example, the bit line BL may be electrically connected to the channel of the write transistor Wtr and to the channel of the read transistor Rtr.

The memory cell array CA may include back-gate lines BG. Each of the back-gate lines BG may be adjacent to, but spaced apart from, the storage node SN of the memory cell MC. Each back-gate line BG may increase the difference between the threshold voltage of the write transistor Wtr and the threshold voltage of the read transistor Rtr.

Although it is illustrated in FIG. 2 that the back-gate lines BG respectively included the memory cells MC are separate from each other, one or more example embodiments are not limited thereto. Like the word lines WL, the back-gate lines BG may be formed to extend along adjacent memory cells MC.

The write transistor Wtr and the read transistor Rtr of each of the memory cells MC of the memory cell array CA may be connected to one word line WL, and a threshold voltage difference between the write transistor Wtr and the read transistor Rtr may increase due to a back-gate line BG. Accordingly, the integration density and the operational reliability of the semiconductor device 100 including the memory cell array CA may be increased.

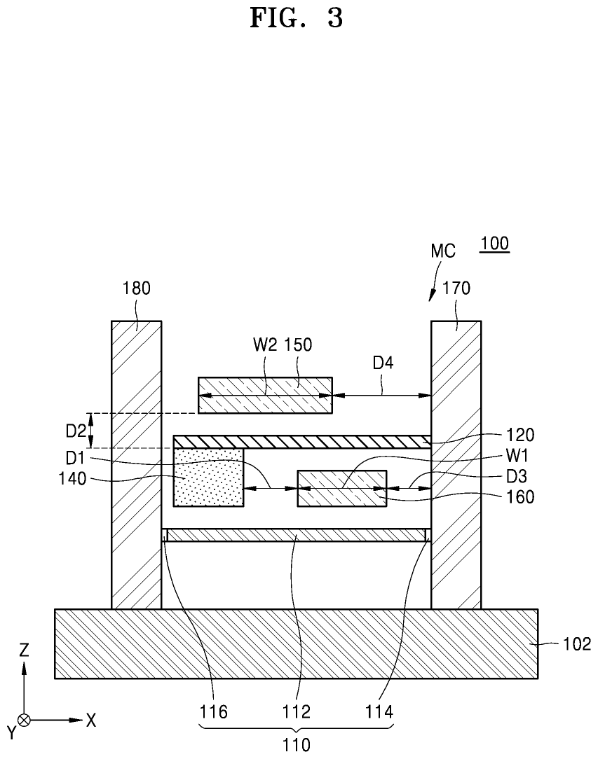

FIG. 3 illustrates a memory cell MC of the semiconductor device 100, according to one or more example embodiments.

Referring to FIG. 3, the semiconductor device 100 may include a first channel pattern 110, a second channel pattern 120, an information storage element 140, a word line 160, a back-gate line 150, a bit line 170, and a plate electrode 180, which are arranged on a substrate 102. The first channel pattern 110, the second channel pattern 120, the information storage element 140, the word line 160, the back-gate line 150, the bit line 170, and the plate electrode 180 may form the memory cell MC.

The read transistor Rtr described with reference to FIG. 2 may include the first channel pattern 110, and the write transistor Wtr may include the second channel pattern 120. The information storage element 140 may be electrically connected to the second channel pattern 120 and may include the storage node SN described with reference to FIG. 2. The word line 160 may correspond to the word line WL described with reference to FIG. 2, the back-gate line 150 may correspond to the back-gate line BG described with reference to FIG. 2, and the bit line 170 may correspond to the bit line BL described with reference to FIG. 2.

For example, the substrate 102 may include a semiconductor material, such as a Group IV semiconductor material, a Group III-V semiconductor material, a Group II-VI semiconductor material, or a Group II-VI oxide semiconductor material. For example, the Group IV semiconductor material may include silicon (Si), germanium (Ge), or silicon-germanium (Si—Ge). For example, the Group III-V semiconductor material may include gallium arsenide (GaAs), indium phosphide (InP), gallium phosphide (GaP), indium arsenide (InAs), indium antimony, or indium gallium arsenide (InGaAs). For example, the Group II-VI semiconductor material may include zinc telluride (ZnTe) or cadmium sulfide (CdS). The substrate 102 may further include impurities. The substrate 102 may include a silicon substrate, a silicon-on-insulator (SOI) substrate, a germanium substrate, a germanium-on-insulator (GOI) substrate, a silicon-germanium substrate, or a substrate including an epitaxial layer. The substrate 102 may correspond to a substrate included in the first structure ST1 in FIG. 1 or the peripheral substrate SUB included in the second structure ST2.

The first channel pattern 110 may extend in a first horizontal direction (e.g., an X direction). The first channel pattern 110 may be in contact with the bit line 170 and the plate electrode 180. In the first horizontal direction (the X direction), an end of the first channel pattern 110 may be in contact with and connected to the bit line 170, and an opposite end of the first channel pattern 110 may be in contact with and connected to the plate electrode 180. The first channel pattern 110 may include a monocrystalline semiconductor material, a polycrystalline semiconductor material, or an oxide semiconductor material. For example, the monocrystalline semiconductor material may include a Group IV semiconductor, a Group III-V compound semiconductor, or a Group II-VI compound semiconductor. In one or more example embodiments, the first channel pattern 110 may include a monocrystalline semiconductor material such as Si or a polycrystalline semiconductor material such as polysilicon.

In one or more example embodiments, the monocrystalline or polycrystalline semiconductor material of the first channel pattern 110 may not contact either the bit line 170 or the plate electrode 180. For example, the first channel pattern 110 may include a first channel region 112 including a monocrystalline semiconductor material or a polycrystalline semiconductor material, a first silicide layer 114, and a second silicide layer 116. The first channel region 112 may be arranged between the first silicide layer 114 and the second silicide layer 116. The first silicide layer 114 may be in contact with the bit line 170. The second silicide layer 116 may be spaced apart from the first silicide layer 114 in the first horizontal direction (the X direction) and may be in contact with the plate electrode 180. The first channel region 112 may be spaced apart from the bit line 170 with the first silicide layer 114 between the first channel region 112 and the bit line 170 and may be spaced apart from the plate electrode 180 with the second silicide layer 116 between the first channel region 112 and the plate electrode 180.

The second channel pattern 120 may extend in the first horizontal direction (the X direction). The second channel pattern 120 may be adjacent to, and spaced apart from, the first channel pattern 110 in the vertical direction (the Z direction). The second channel pattern 120 may be in contact with the bit line 170 and the information storage element 140. An end of the second channel pattern 120 in the first horizontal direction (the X direction) may be in contact with, and connected to, the bit line 170. An opposite end of the second channel pattern 120 may be in contact with, and connected to, the information storage element 140.

The second channel pattern 120 may include a monocrystalline semiconductor material, a polycrystalline semiconductor material, an oxide semiconductor material, or a two-dimensional (2D) semiconductor material. For example, the oxide semiconductor material may include at least one selected from the group consisting of indium gallium zinc oxide (IGZO), indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), zinc oxynitride (ZnON), magnesium zinc oxide (MgZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), aluminum zinc tin oxide (AlZnSnO), gallium zinc tin oxide (GaZnSnO), and zirconium zinc tin oxide (ZrZnSnO). The 2D semiconductor material may include at least one selected from the group consisting of a transition metal dichalcogenide (TMD) material layer that may have a semiconductor characteristic, a black phosphorous material layer, and a hexagonal boron-nitride material layer. For example, the 2D semiconductor material may include at least one selected from the group consisting of BiOSe, Crl, WSe₂, MoS₂, TaS, WS, SnSe, ReS, β-SnTe, MnO, AsS, P(black), InSe, h-BN, GaSe, GaN, SrTiO, MXene, Janus 2D materials, graphene, and a carbon nanotube. In one or more example embodiments, the second channel pattern 120 may include the oxide semiconductor material or the 2D semiconductor material. The oxide semiconductor material or the 2D semiconductor material of the second channel pattern 120 may be in direct contact with the bit line 170. In one or more example embodiments, the second channel pattern 120 may include an oxide semiconductor material such as IGZO.

In one or more example embodiments, the second channel pattern 120 may include a channel contact in its portion adjacent to the bit line 170. The channel contact may include doped polysilicon, metal, conductive metal nitride, a metal-semiconductor compound, a metal compound, conductive metal oxide, graphene, a carbon nanotube, or a combination thereof. For example, the channel contact may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof. The channel contact may correspond to a portion of the second channel pattern 120 into which an impurity, such as H or O, is implanted.

The information storage element 140 may be in contact with, and electrically connected to, the second channel pattern 120. For example, at least a portion of the information storage element 140 may overlap the second channel pattern 120 in the vertical direction (the Z direction) and may be spaced apart from the first channel pattern 110 in the vertical direction (the Z direction). The information storage element 140 may be adjacent to the first channel pattern 110. For example, at least a portion of the information storage element 140 may be adjacent to, and overlap, the first channel pattern 110 in the vertical direction (the Z direction). A thickness of the information storage element 140 in the vertical direction (the Z direction) may be equal to or greater than a thickness of the second channel pattern 120 in the vertical direction (the Z direction). The information storage element 140 may be spaced apart from the substrate 102 in the vertical direction (the Z direction) and spaced apart from the plate electrode 180 in the first horizontal direction (the X direction).

Here, the vertical direction (the Z direction) may be perpendicular to the top surface of the substrate 102, and the first horizontal direction (the X direction) and a second horizontal direction (e.g., a Y direction) may be parallel to the top surface of the substrate 102 and orthogonal with each other. The first horizontal direction (the X direction), the vertical direction (the Z direction), and the second horizontal direction (the Y direction) may be respectively referred to as a first direction, a second direction, and a third direction, which are orthogonal with one another.

The information storage element 140 may include an oxide semiconductor material, a 2D semiconductor material, a conductive material, or a combination thereof. The conductive material may include doped monocrystalline silicon, doped polycrystalline silicon, metal, conductive metal nitride, a metal-semiconductor compound, conductive metal oxide, conductive graphene, a carbon nanotube, or a combination thereof. For example, the information storage element 140 may include an oxide semiconductor material. In one or more example embodiments, the second channel pattern 120 and the information storage element 140 may include the same material. For example, the second channel pattern 120 and the information storage element 140 may form a single body. In one or more example embodiments, the second channel pattern 120 and the information storage element 140 may be formed as one body with the same material so that no interface defining the boundary between the second channel pattern 120 and the information storage element 140 is formed.

The word line 160 may be adjacent to both the first channel pattern 110 and the second channel pattern 120. The word line 160 may be arranged between the first channel pattern 110 and the second channel pattern 120 in the vertical direction (the Z direction) to be spaced apart from each of the first channel pattern 110 and the second channel pattern 120, which are included in the memory cell MC. For example, at least a portion of the word line 160 may extend in the second horizontal direction (the Y direction) between the first channel pattern 110 and the second channel pattern 120. At least a portion of the word line 160 may overlap the first channel pattern 110 in the vertical direction (the Z direction), and at least a portion of the word line 160 may overlap the second channel pattern 120 in the vertical direction (the Z direction). The word line 160 may function as the gate of the write transistor Wtr in FIG. 2 and may also function as the gate of the read transistor Rtr in FIG. 2. For example, at least a portion of the information storage element 140 and at least a portion of the word line 160 may be adjacent to the first channel pattern 110 so that the word line 160 may function as the gate of the read transistor Rtr together with the information storage element 140. For example, when charges are stored in the information storage element 140, the word line 160 may function as the gate of the read transistor Rtr. The word line 160 may be adjacent to both the first channel pattern 110 and the second channel pattern 120, may function as the gate of each of the write transistor Wtr and the read transistor Rtr, and may increase the integration density of the semiconductor device 100.

The word line 160 may include metal, conductive metal nitride, a metal compound, conductive metal oxide, graphene, a carbon nanotube, or a combination thereof. For example, the word line 160 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof.

The back-gate line 150 may be adjacent to the information storage element 140. For example, the back-gate line 150 may be adjacent to and spaced apart from the information storage element 140. The back-gate line 150 may be adjacent to the first channel pattern 110 and/or the second channel pattern 120. For example, the back-gate line 150 may be adjacent to the first channel pattern 110 and/or the second channel pattern 120 and may be spaced apart from each of the first channel pattern 110 and the second channel pattern 120. In one or more example embodiments, the back-gate line 150 may be closer to the second channel pattern 120 than to the first channel pattern 110. For example, the back-gate line 150 may be adjacent to the second channel pattern 120 and may be spaced apart from the second channel pattern 120 in the vertical direction (the Z direction). For example, at least a portion of the back-gate line 150 may be adjacent to the second channel pattern 120 and may extend in the second horizontal direction (the Y direction). At least a portion of the back-gate line 150 may overlap the second channel pattern 120 in the vertical direction (the Z direction). In one or more example embodiments, at least a portion of the back-gate line 150 may overlap the information storage element 140 in the vertical direction (the Z direction) but one or more example embodiments are not limited thereto. For example, the back-gate line 150 may be adjacent to the information storage element 140 and may not overlap the information storage element 140 in the vertical direction (the Z direction).

The back-gate line 150 may include metal, conductive metal nitride, a metal compound, conductive metal oxide, graphene, a carbon nanotube, or a combination thereof. For example, the back-gate line 150 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof.

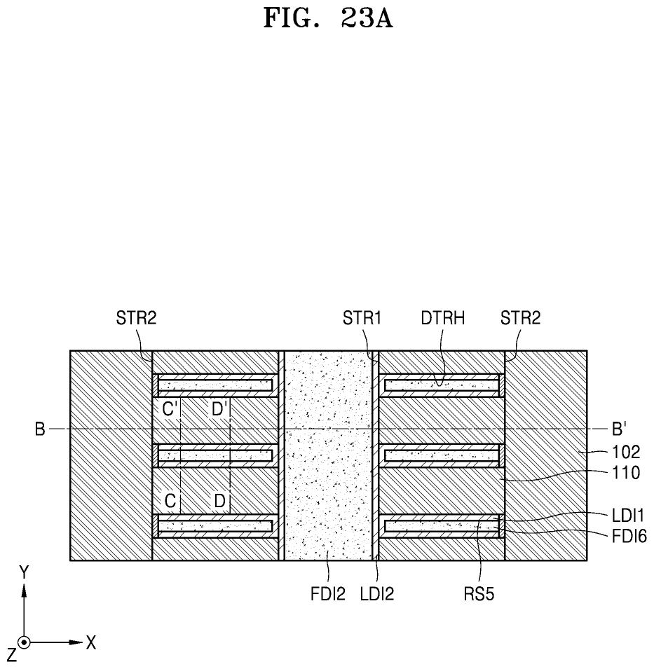

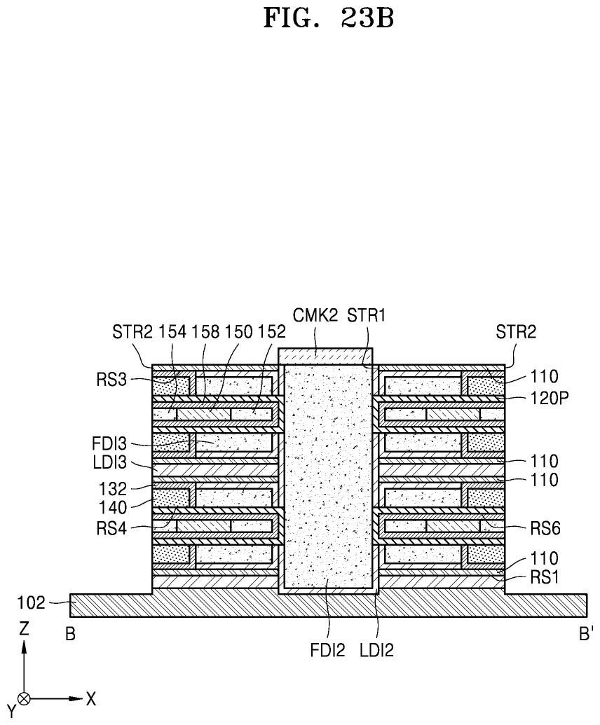

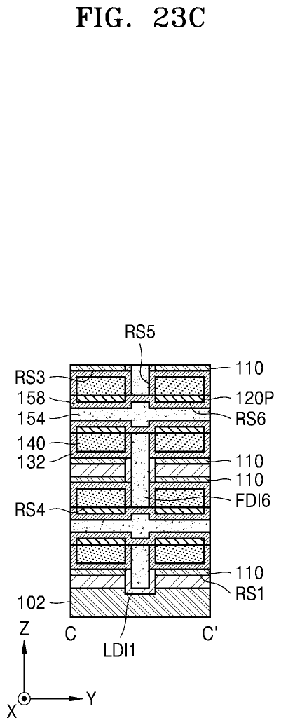

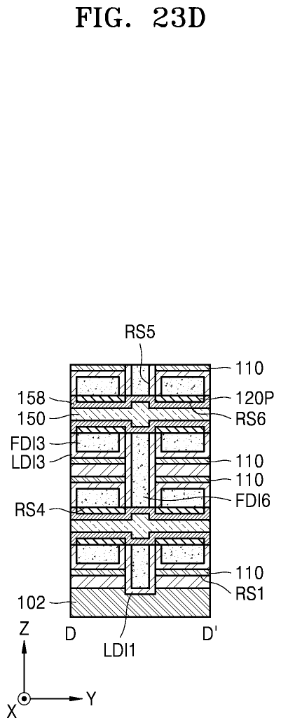

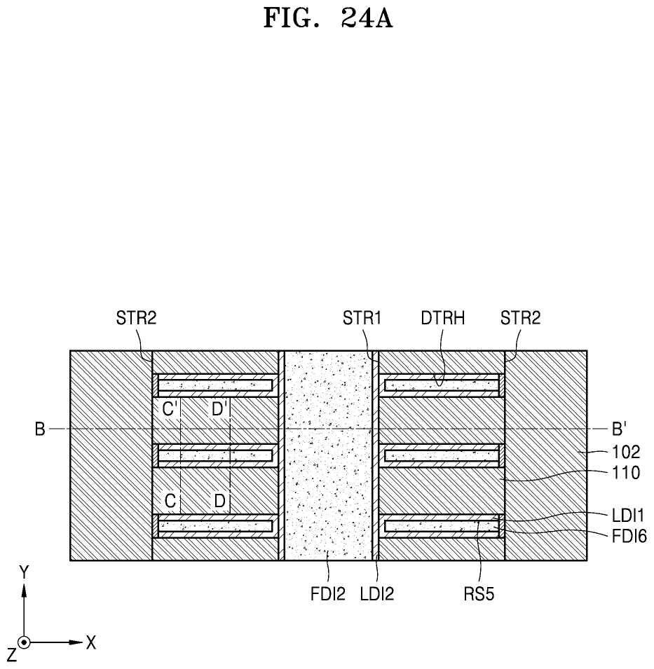

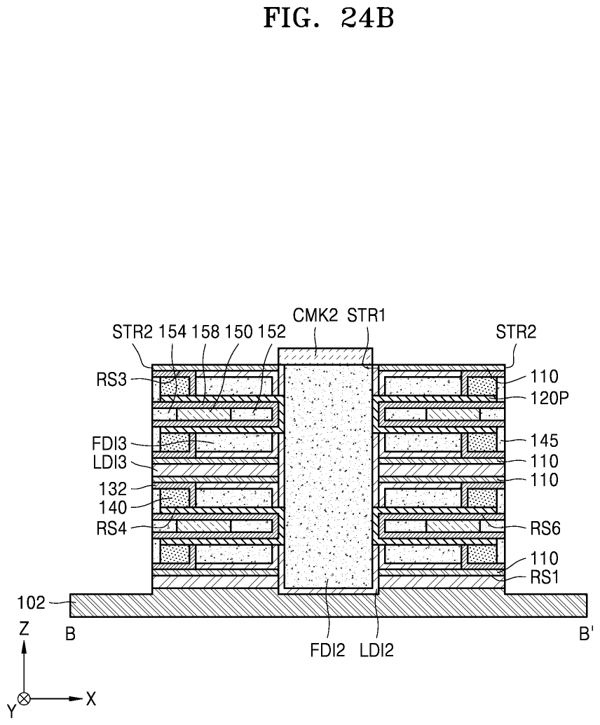

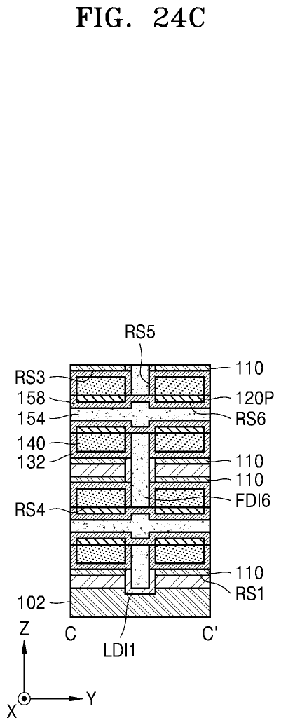

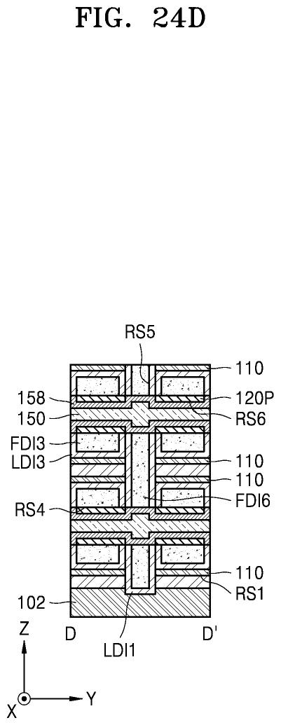

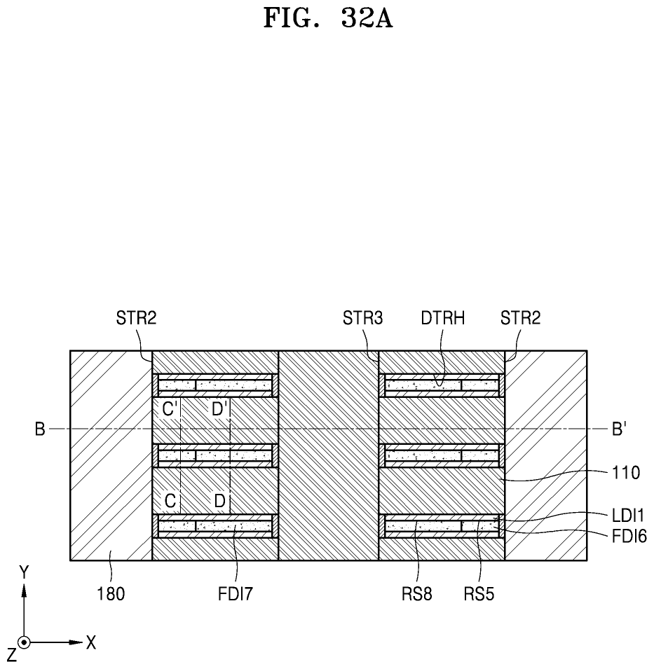

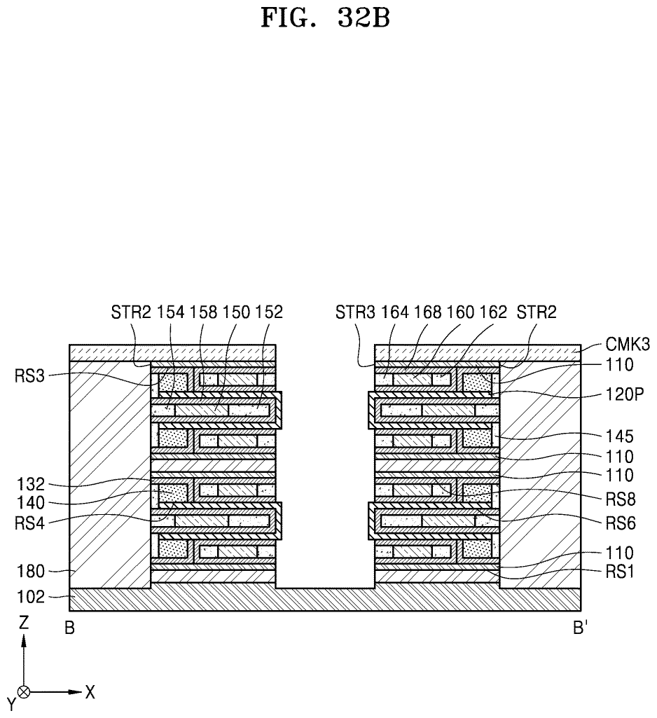

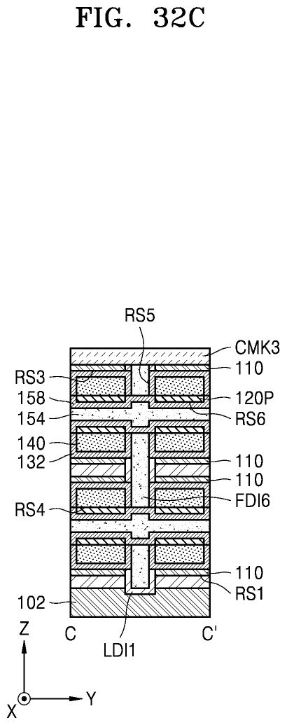

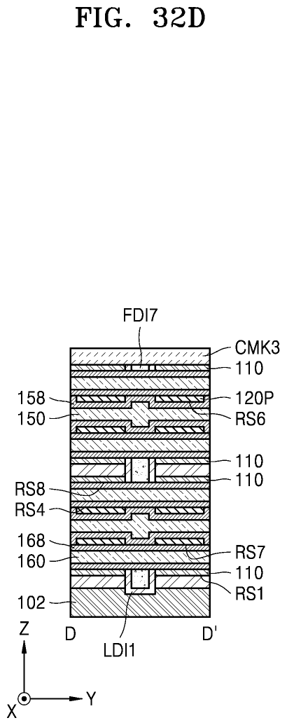

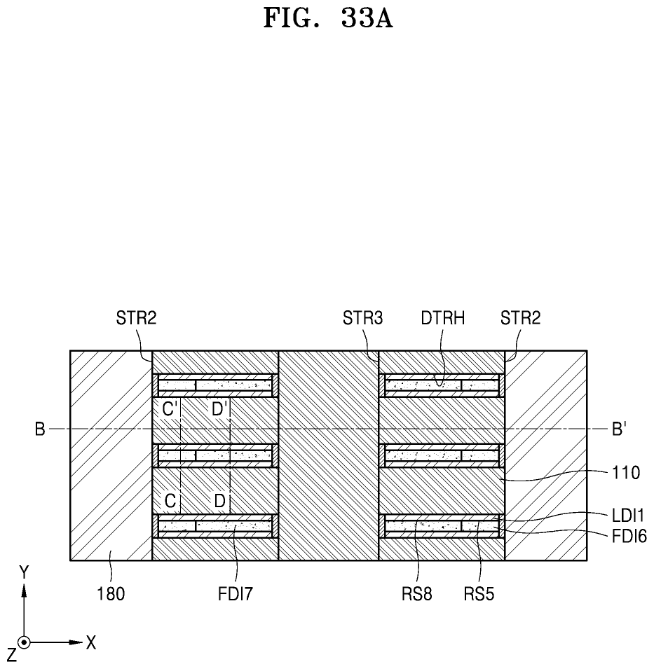

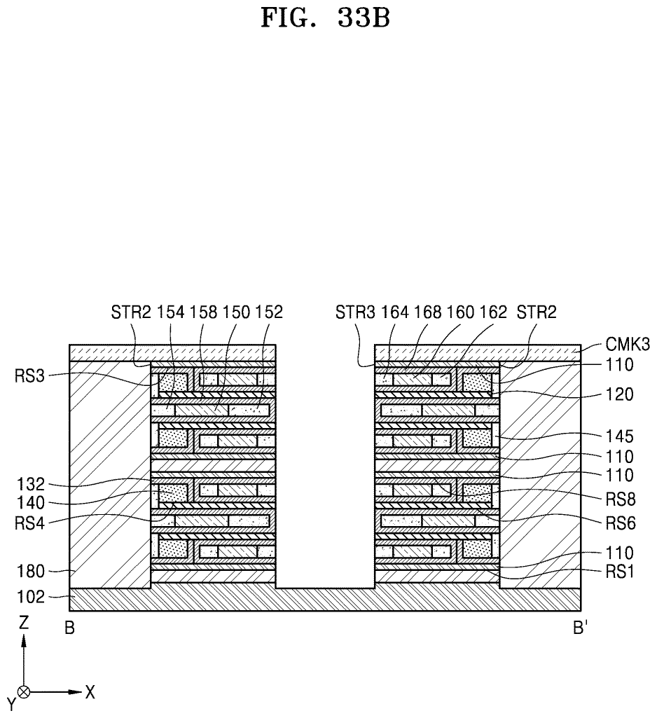

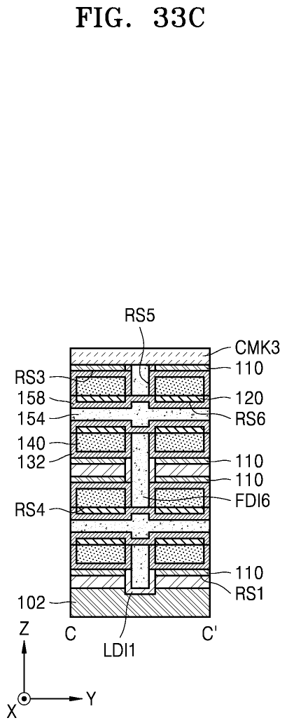

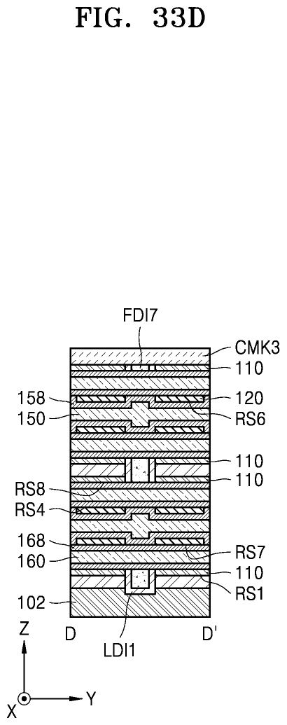

The information storage element 140 may be spaced apart from the word line 160 by a first separation distance D1 and from the back-gate line 150 by a second separation distance D2. The second separation distance D2 may be less than the first separation distance D1. In the first horizontal direction (the X direction), the word line 160 may have a first horizontal width W1, and the back-gate line 150 may have a second horizontal width W2. In one or more example embodiments, the second horizontal width W2 may be greater than the first horizontal width W1. A separation distance between the information storage element 140 and the back-gate line 150 and a horizontal width of the back-gate line 150 may be determined by a horizontal width in the first horizontal direction (the X direction) of each of a first separation insulating layer 152 and a second separation insulating layer 154, which are described with reference to FIGS. 23A, 23B, 23C, and 23D below. A separation distance between the information storage element 140 and the plate electrode 180 may be determined by the horizontal width in the first horizontal direction (the X direction) of a third separation insulating layer 145 described with reference to FIGS. 24A, 24B, 24C, and 24D below. A separation distance between the information storage element 140 and the word line 160 and a horizontal width of the word line 160 may be determined by the horizontal width in the first horizontal direction (the X direction) of each of a fourth separation insulating layer 162 and a fifth separation insulating layer 164, which are described with reference to FIGS. 32A, 32B, 33C, and 32D below.

The bit line 170 may extend in the vertical direction (the Z direction). The bit line 170 may be in contact with, and electrically connected to, the first channel pattern 110 and the second channel pattern 120. For example, the bit line 170 may be in contact with an end of the first channel pattern 110 and an end of the second channel pattern 120 in the first horizontal direction (the X direction).

The bit line 170 may include doped polysilicon, metal, conductive metal nitride, a metal-semiconductor compound, a metal compound, conductive metal oxide, graphene, a carbon nanotube, or a combination thereof. For example, the bit line 170 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof.

In one or more example embodiments, the bit line 170 may include a plurality of conductive layers stacked sequentially. For example, the conductive layers may include at least one selected from the group consisting of doped polycrystalline silicone, a silicide material, and metal. However, the number of layers and the type of material of the bit line 170 may vary with one or more example embodiments.

The bit line 170 may be spaced apart from the word line 160 by a third separation distance D3 and from the back-gate line 150 by a fourth separation distance D4. In one or more example embodiments, the fourth separation distance D4 may be greater than the third separation distance D3.

The plate electrode 180 may be in contact with the first channel pattern 110. The plate electrode 180 may be in contact with the opposite end of the first channel pattern 110 in the first horizontal direction (the X direction). The plate electrode 180 may be spaced apart from the second channel pattern 120. For example, the plate electrode 180 may be electrically grounded in one or more example embodiments.

The plate electrode 180 may include metal, conductive metal nitride, a metal compound, conductive metal oxide, graphene, a carbon nanotube, or a combination thereof. For example, the plate electrode 180 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof.

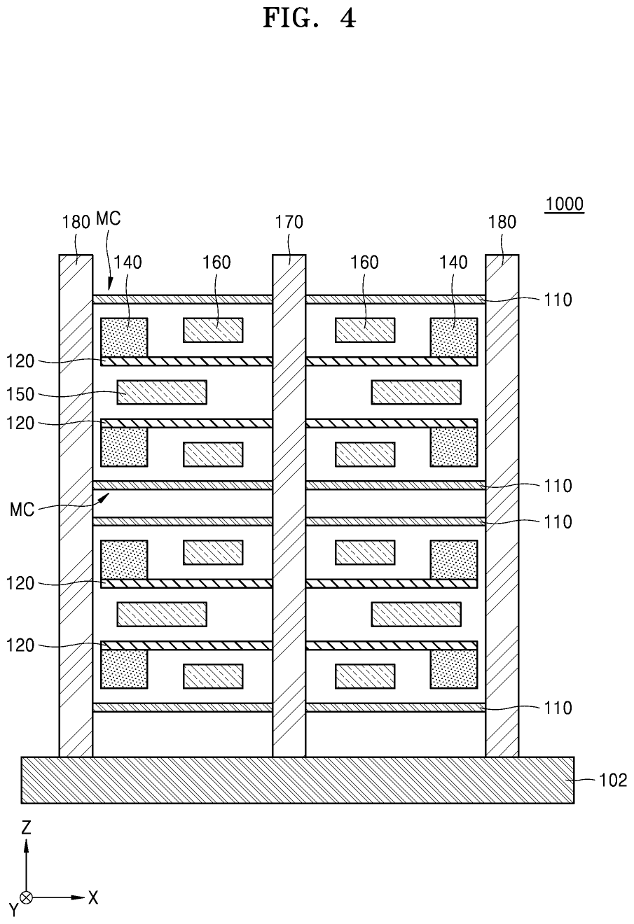

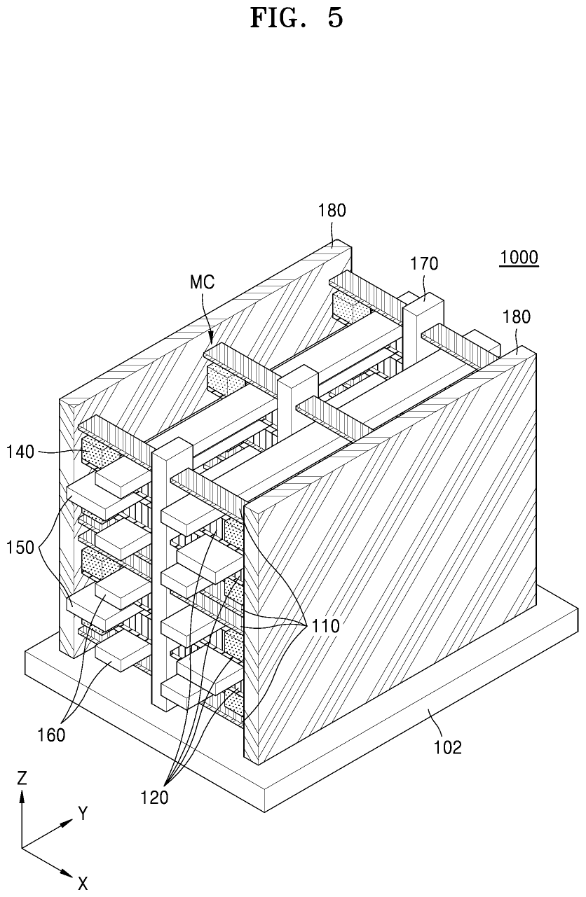

FIG. 4 illustrates a semiconductor device including a plurality of memory cells, according to one or more example embodiments. FIG. 5 is a conceptual perspective view of a semiconductor device including a plurality of memory cells, according to one or more example embodiments.

Referring to FIGS. 4 and 5, a semiconductor device 1000 may include the plurality of memory cells MC each including the first channel pattern 110, the second channel pattern 120, the information storage element 140, the word line 160, the back-gate line 150, the bit line 170, and the plate electrode 180.

First channel patterns 110 may extend in the first horizontal direction (the X direction) and may be arranged in rows spaced apart from one another in the second horizontal direction (the Y direction) and the vertical direction (the Z direction). Second channel patterns 120 may extend in the first horizontal direction (the X direction) and may be arranged in rows spaced apart from one another in the second horizontal direction (the Y direction) and the vertical direction (the Z direction). A second channel pattern 120 may be spaced apart from a first channel pattern 110 in the vertical direction (the Z direction). The second channel pattern 120 may be in contact with the bit line 170 and the information storage element 140. The information storage element 140 may be in contact with, and electrically connected to, the second channel pattern 120. The information storage element 140 may be adjacent to, and spaced apart from, the first channel pattern 110.

The word line 160 may be adjacent to both the first channel pattern 110 and the second channel pattern 120. The word line 160 may be arranged between the first channel pattern 110 and the second channel pattern 120 of one memory cell MC in the vertical direction (the Z direction) to be spaced apart from the first channel pattern 110 and the second channel pattern 120 of the memory cell MC.

The back-gate line 150 may be adjacent to the information storage element 140. In one or more example embodiments, the back-gate line 150 may be closer to the second channel pattern 120 than to the first channel pattern 110. For example, the back-gate line 150 may be arranged to be adjacent to, and spaced apart from, the second channel pattern 120 in the vertical direction (the Z direction). For example, at least a portion of the back-gate line 150 may be adjacent to the second channel pattern 120 and may extend in the second horizontal direction (the Y direction).

Bit lines 170 may extend in the vertical direction (the Z direction) and may be arranged in rows spaced apart from one another in the second horizontal direction (the Y direction). The bit lines 170 may be in contact with, and electrically connected to, the first channel patterns 110 and the second channel patterns 120. For example, the bit lines 170 may be in contact with ends of the first channel patterns 110 and ends of the second channel patterns 120 in the first horizontal direction (the X direction).

The plate electrode 180 may be in contact with the first channel patterns 110. For example, the plate electrode 180 may be in contact with opposite ends of the first channel patterns 110 in the first horizontal direction (the X direction). Although it is illustrated in FIGS. 4 and 5 that the plate electrode 180 has a plate shape extending in the first horizontal direction (the X direction) and the second horizontal direction (the Y direction) and is in contact with a plurality of second channel patterns 120, which are arranged in rows in the first horizontal direction (the X direction) and the second horizontal direction (the Y direction), one or more example embodiments are not limited thereto. According to one or more example embodiments, a plurality of plate electrodes 180 may be arranged and may each be in contact with a plurality of first channel patterns 110. In one or more example embodiments, the plate electrode 180 may be electrically grounded.

The plurality of memory cells MC may be arranged in rows in the first horizontal direction (the X direction), the second horizontal direction (the Y direction), and the vertical direction (the Z direction). In one or more example embodiments, two memory cells MC adjacent to each other in the first horizontal direction (the X direction) may be in mirror symmetry with each other in the first horizontal direction (the X direction). In one or more example embodiments, two memory cells MC adjacent to each other in the vertical direction (the Z direction) may be in mirror symmetry with each other in the vertical direction (the Z direction). Two second channel patterns 120 adjacent to each other in the vertical direction (the Z direction) may be arranged between two first channel patterns 110 spaced apart from each other in the vertical direction (the Z direction), and two first channel patterns 110 spaced adjacent to each other in the vertical direction (the Z direction) may be arranged between two second channel patterns 120 spaced apart from each other in the vertical direction (the Z direction).

Each of a plurality of word lines 160 may be arranged between a first channel pattern 110 and a second channel pattern 120 of one memory cell MC in the vertical direction (the Z direction) to be spaced apart from the first channel pattern 110 and the second channel pattern 120 of the memory cell MC. Each of a plurality of back-gate lines 150 may be arranged between two second channel patterns 120 respectively included in two memory cells MC in the vertical direction (the Z direction) to be spaced apart from the two second channel patterns 120 of the two memory cells MC in the vertical direction (the Z direction). For example, two word lines 160 may be respectively arranged at opposite sides of one back-gate line 150 in the vertical direction (the Z direction), and the word line 160 may have the back-gate line 150 at one side thereof and another word line 160 at an opposite side thereof in the vertical direction (the Z direction).

A plurality of bit lines 170 and the plurality of plate electrodes 180 may be alternately arranged in the first horizontal direction (the X direction). Although it is illustrated in FIGS. 4 and 5 that one plate electrode 180 extending in the second horizontal direction (the Y direction) and the vertical direction (the Z direction) is in contact with the plurality of first channel patterns 110 arranged in rows in the second horizontal direction (the Y direction) and the vertical direction (the Z direction), one or more example embodiments are not limited thereto. According to one or more example embodiments, the plurality of plate electrodes 180 may be arranged in the second horizontal direction (the Y direction), and each of the plate electrodes 180 may be in contact with the plurality of first channel patterns 110 arranged in the vertical direction (the Z direction).

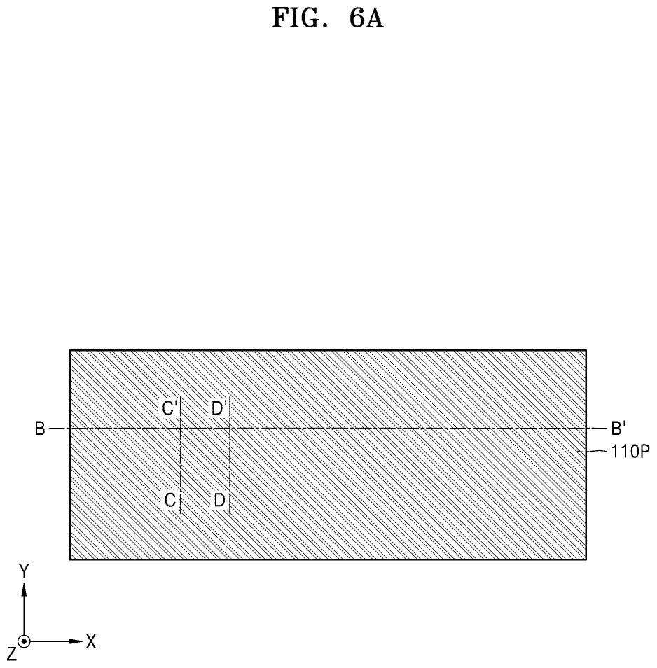

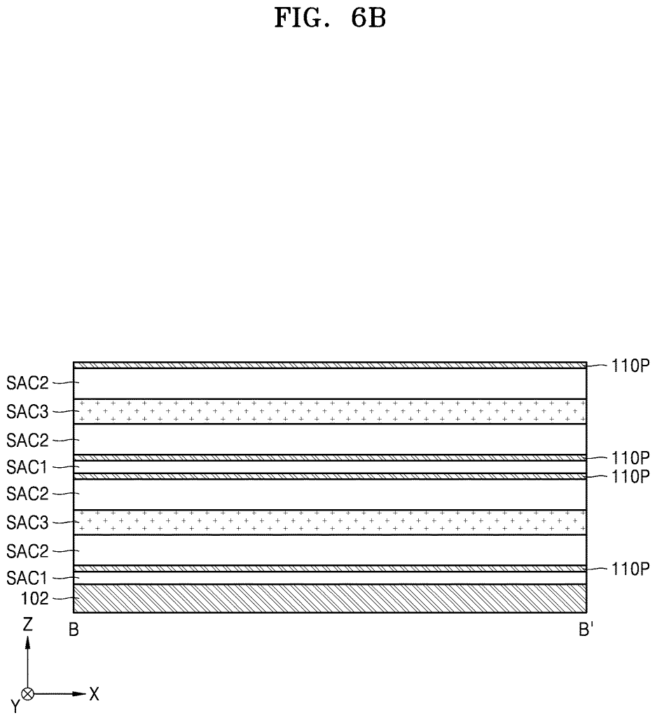

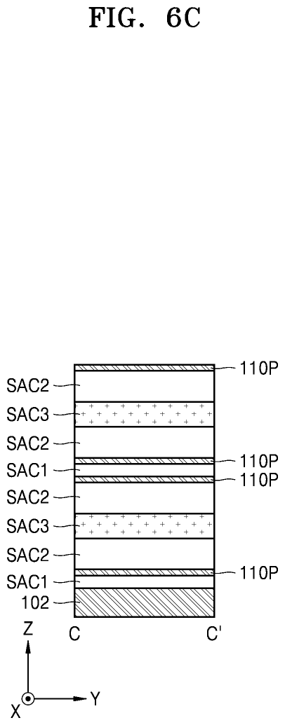

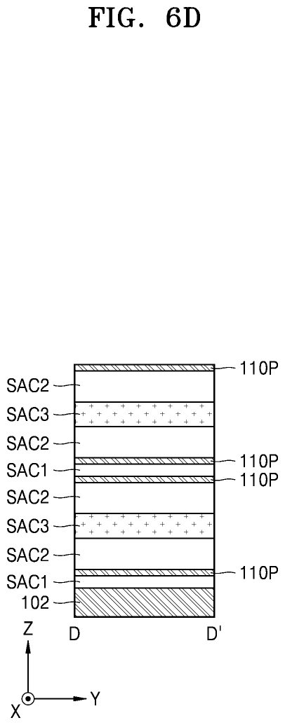

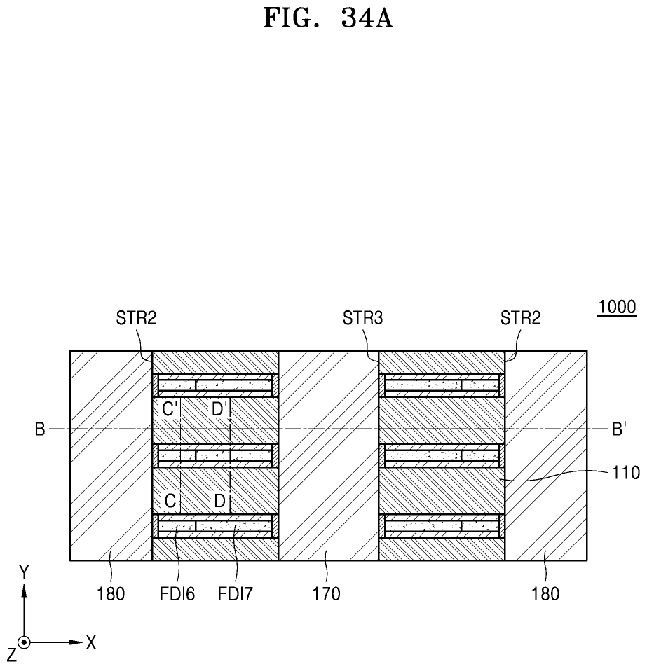

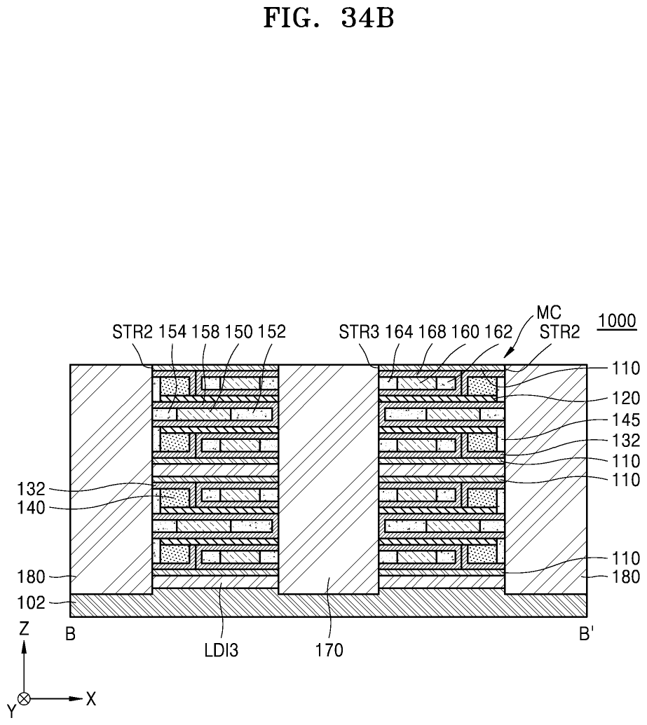

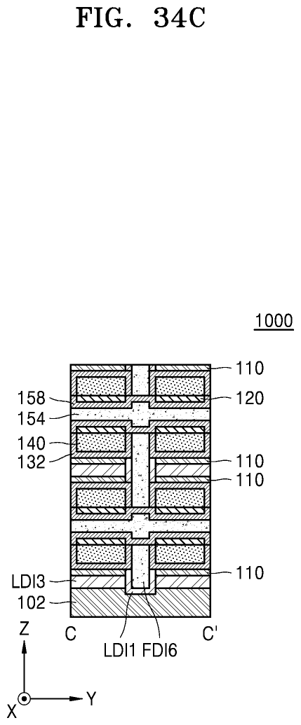

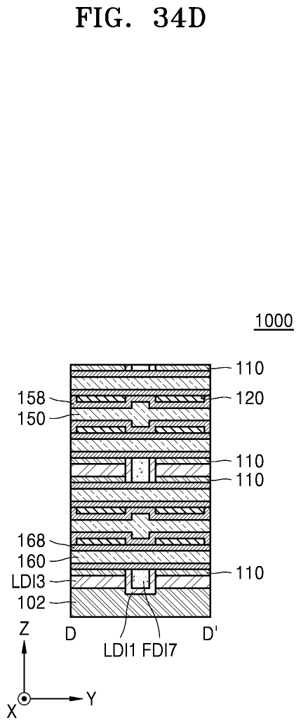

FIGS. 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, and 33D are diagrams illustrating a method of manufacturing a semiconductor device, according to one or more example embodiments. FIGS. 34A, 34B, 34C, and 34D are diagrams illustrating a semiconductor device according to one or more example embodiments. In detail, FIGS. 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B, 32B, 33B, and 34B are cross-sectional views taken along line B-B′ in FIGS. 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, and 34A, respectively. FIGS. 6C, 7C, 8C, 9C, 10C, 11C, 12C, 13C, 14C, 15C, 16C, 17C, 18C, 19C, 20C, 21C, 22C, 23C, 24C, 25C, 26C, 27C, 28C, 29C, 30C, 31C, 32C, 33C, and 34C are cross-sectional views taken along line C-C′ in FIGS. 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, and 34A, respectively. FIGS. 6D, 7D, 8D, 9D, 10D, 11D, 12D, 13D, 14D, 15D, 16D, 17D, 18D, 19D, 20D, 21D, 22D, 23D, 24D, 25D, 26D, 27D, 28D, 29D, 30D, 31D, 32D, 33D, and 34D are cross-sectional views taken along line D-D′ in FIGS. 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, and 34A, respectively.

Referring to FIGS. 6A, 6B, 6C, and 6D, a plurality of first channel layers 110P, a plurality of first sacrificial layers SAC1, a plurality of second sacrificial layers SAC2, and a plurality of third sacrificial layers SAC3 may be formed on the substrate 102. The first channel layers 110P may be spaced apart from each other in the vertical direction (the Z direction), the first sacrificial layers SAC1 may be spaced apart from each other in the vertical direction (the Z direction), the second sacrificial layers SAC2 may be spaced apart from each other in the vertical direction (the Z direction), and the third sacrificial layers SAC3 may be spaced apart from each other in the vertical direction (the Z direction),

A first channel layer 110P may be between a first sacrificial layer SAC1 and a second sacrificial layer SAC2, which are adjacent to each other in the vertical direction (the Z direction). A first sacrificial layer SAC1 may be between first channel layers 110P adjacent to each other in the vertical direction (the Z direction). The second sacrificial layer SAC2 may be between the first channel layer 110P and a third sacrificial layer SAC3, which are adjacent to each other in the vertical direction (the Z direction). The third sacrificial layer SAC3 may be between second sacrificial layers SAC2 adjacent to each other in the vertical direction (the Z direction). For example, the first channel pattern 110 in FIGS. 4 and 5 may be formed from the first channel layer 110P, the second channel pattern 120 may be formed in a portion of the second sacrificial layer SAC2 adjacent to the third sacrificial layer SAC3, the back-gate line 150 may be formed in a portion of the third sacrificial layer SAC3, and the word line 160 may be formed in a portion of the second sacrificial layer SAC2.

Although it is illustrated in FIGS. 6B, 6C, and 6D that a first sacrificial layer SAC1, the first channel layer 110P, the second sacrificial layer SAC2, the third sacrificial layer SAC3, the second sacrificial layer SAC2, and the first channel layer 110P are repeatedly arranged in the vertical direction (the Z direction), one or more example embodiments are not limited thereto. For example, the arrangement of the plurality of first channel layers 110P, the plurality of first sacrificial layers SAC1, the plurality of second sacrificial layers SAC2, and the plurality of third sacrificial layers SAC3 on the substrate 102 in the vertical direction (the Z direction) may be changed according to the arrangement of the first channel pattern 110, the second channel pattern 120, the back-gate line 150, and the word line 160 on the substrate 102 in the vertical direction (the Z direction).

The first channel layer 110P may include a monocrystalline semiconductor material, a polycrystalline semiconductor material, or an oxide semiconductor material. The first sacrificial layer SAC1 may include a material having an etch selectivity with respect to the first channel layer 110P and the third sacrificial layer SAC3. The second sacrificial layer SAC2 may include a material having an etch selectivity with respect to the first channel layer 110P and the third sacrificial layer SAC3. In one or more example embodiments, the first sacrificial layer SAC1 may include a material having the same etching characteristic as, or a similar etching characteristic, to a material of the second sacrificial layer SAC2. For example, the first sacrificial layer SAC1 and the second sacrificial layer SAC2 may each include SiGe. The third sacrificial layer SAC3 may include a material having an etch selectivity with respect to the first channel layer 110P, the first sacrificial layer SAC1, and the second sacrificial layer SAC2. For example, the third sacrificial layer SAC3 may include SiC. The first sacrificial layer SAC1 may be thicker than the first channel layer 110P. The second sacrificial layer SAC2 may be thicker than the first sacrificial layer SAC1. The third sacrificial layer SAC3 may be thicker than the first sacrificial layer SAC1. The thickness of the third sacrificial layer SAC3 may be less than or similar to the thickness of the second sacrificial layer SAC2.

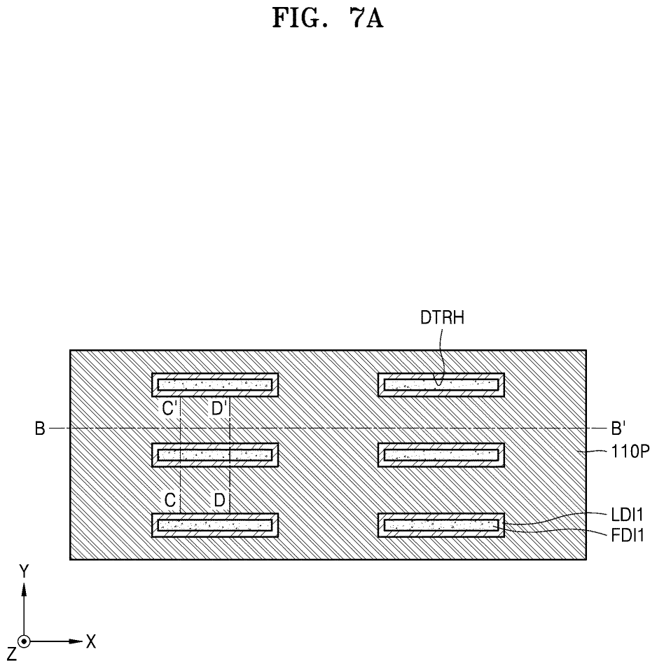

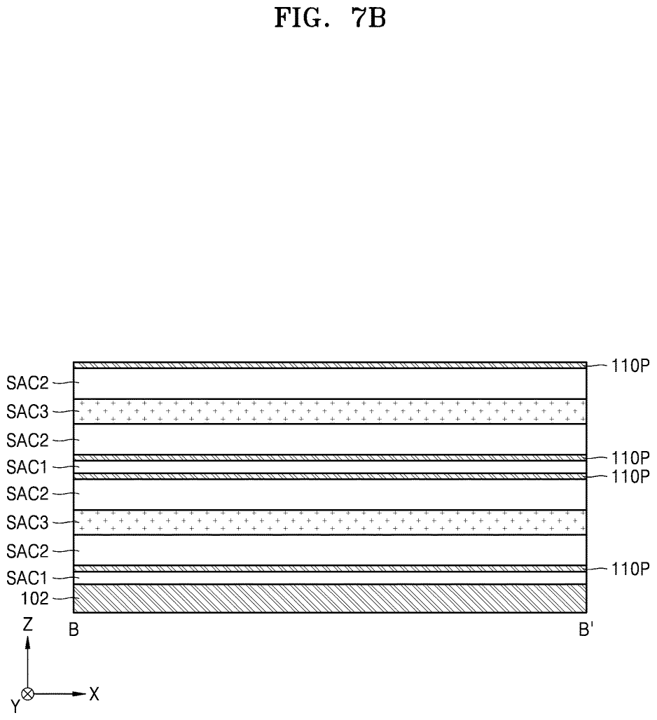

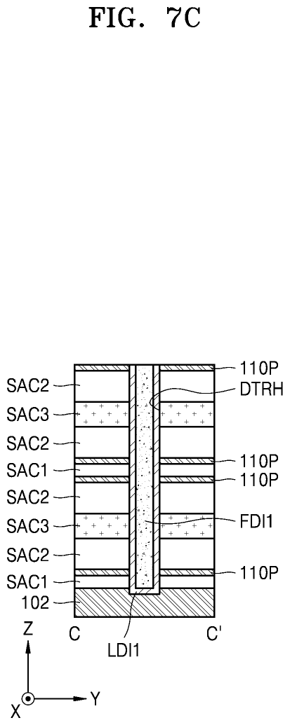

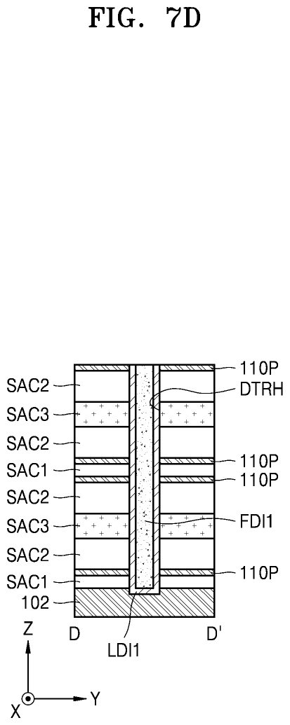

Referring to FIGS. 7A, 7B, 7C, and 7D, a plurality of deep trench holes DTRH may be formed through a stack structure including the plurality of first channel layers 110P, the plurality of first sacrificial layers SAC1, the plurality of second sacrificial layers SAC2, and the plurality of third sacrificial layers SAC3. A portion of the substrate 102 may be exposed in the bottom of each of the deep trench holes DTRH. In one or more example embodiments, the deep trench holes DTRH may extend into the substrate 102 through the stack structure including the first channel layers 110P, the first sacrificial layers SAC1, the second sacrificial layers SAC2, and the third sacrificial layers SAC3. The deep trench holes DTRH may be spaced apart from one another in the first horizontal direction (the X direction) and the second horizontal direction (the Y direction). In one or more example embodiments, the deep trench holes DTRH may each have a rectangular shape, which is longer in the first horizontal direction (the X direction) and is shorter in the second horizontal direction (the Y direction), in a plan view.

A first liner insulating layer LDI1 may be formed to cover the inner sidewall and bottom surface of each of the deep trench holes DTRH, and a first filling insulating layer FDI1 may be formed to cover the first liner insulating layer LDI1 and fill each of the deep trench holes DTRH. The first liner insulating layer LDI1 may be formed to conformally cover the inner sidewall and the bottom surface of each of the deep trench holes DTRH. For example, the first liner insulating layer LDI1 may include SiO₂ or SiOC, and the first filling insulating layer FDI1 may include Si₃N₄ and SiOCN.

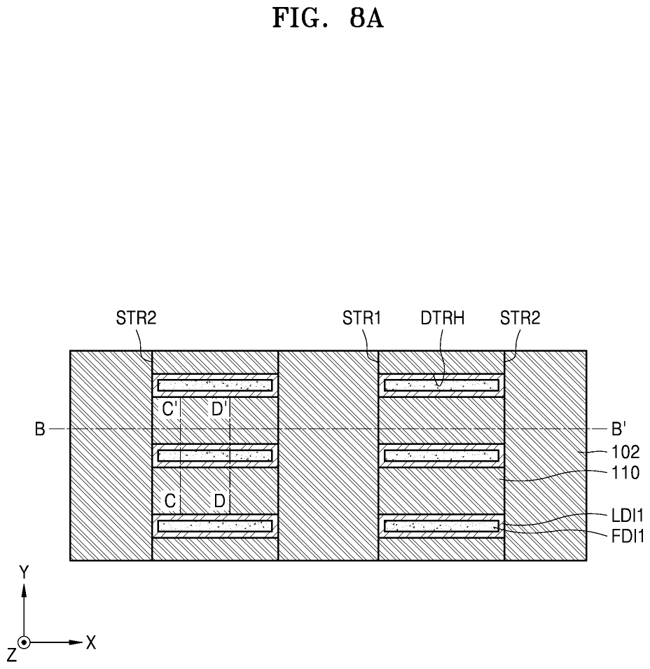

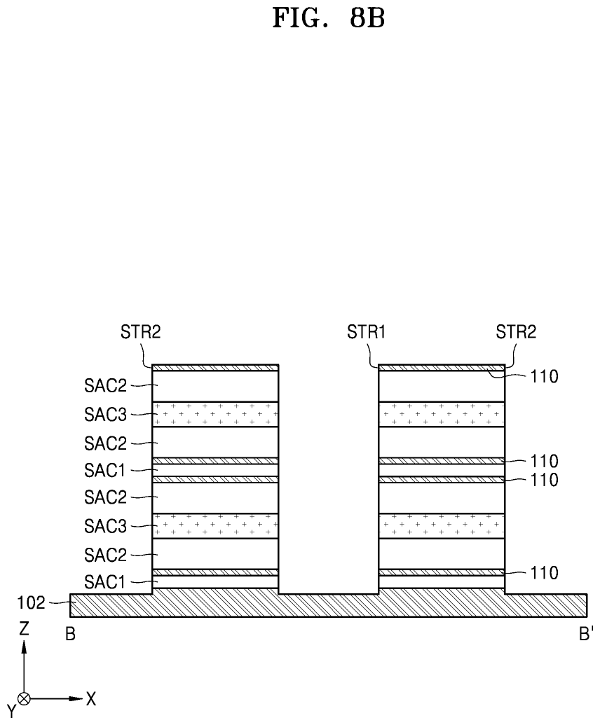

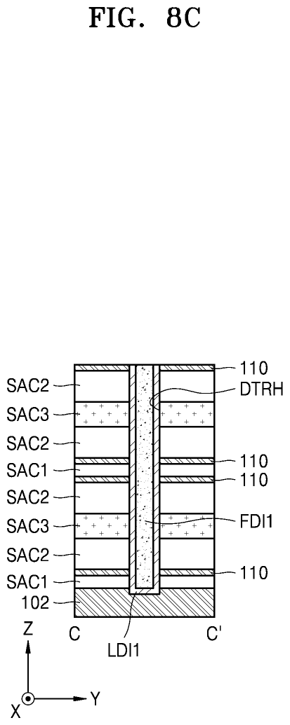

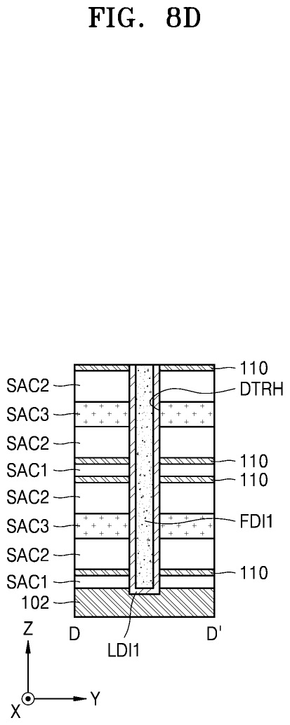

Referring to FIGS. 7A, 7B, 7C, 7D, 8A, 8B, 8C, and 8D, a first isolation trench STR1 and a second isolation trench STR2 may be formed through the stack structure including the first channel layers 110P, the first sacrificial layers SAC1, the second sacrificial layers SAC2, and the third sacrificial layers SAC3. A portion of the substrate 102 may be exposed at the bottom of each of the first isolation trench STR1 and the second isolation trench STR2. In one or more example embodiments, the first isolation trench STR1 and the second isolation trench STR2 may extend into the substrate 102 through the stack structure including the first channel layers 110P, the first sacrificial layers SAC1, the second sacrificial layers SAC2, and the third sacrificial layers SAC3. The first isolation trench STR1 and the second isolation trench STR2 may be spaced apart from each other in the first horizontal direction (the X direction). For example, the first isolation trench STR1 may be arranged between two second isolation trenches STR2 adjacent to each other in the first horizontal direction (the X direction). Although one first isolation trench STR1 and two second isolation trenches STR2 are illustrated in FIGS. 8A and 8B, one or more example embodiments are not limited thereto. For example, a plurality of first isolation trenches STR1 and a plurality of second isolation trenches STR2 may be alternately arranged in the first horizontal direction (the X direction). The first channel layers 110P may be divided into the plurality of first channel patterns 110 by the first isolation trench STR1 and the second isolation trench STR2.

The first isolation trench STR1 and the second isolation trench STR2 may be formed to extend in the second horizontal direction (the Y direction). The first liner insulating layer LDI1 filling each of the deep trench holes DTRH may be exposed at the inner sidewall of each of the first isolation trench STR1 and the second isolation trench STR2 in the first horizontal direction (the X direction). For example, each of the first isolation trench STR1 and the second isolation trench STR2 may be formed to be in communication with deep trench holes DTRH arranged in a row in the second horizontal direction (the Y direction).

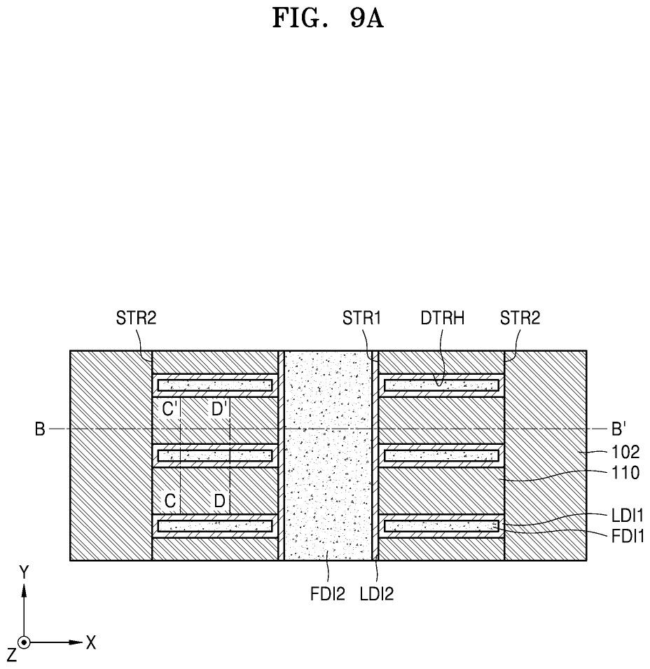

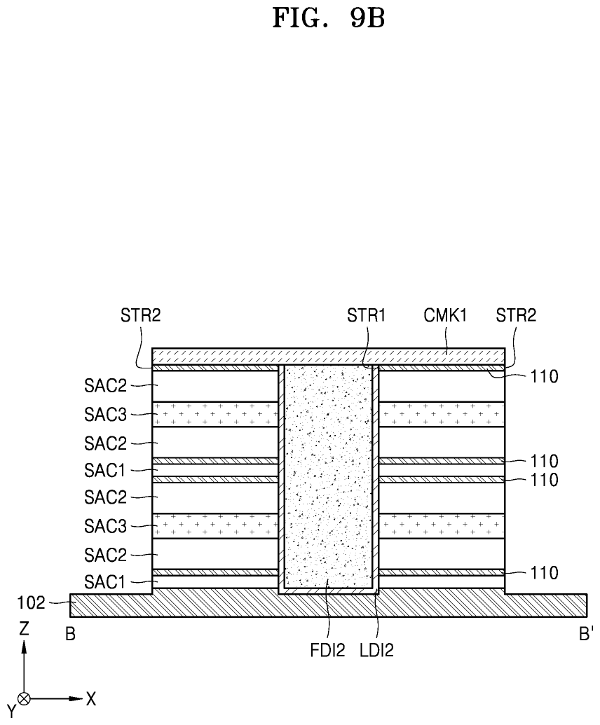

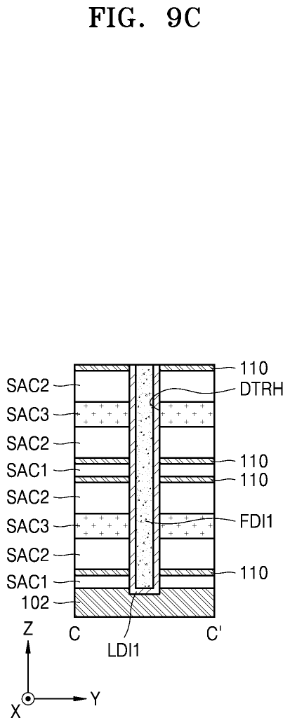

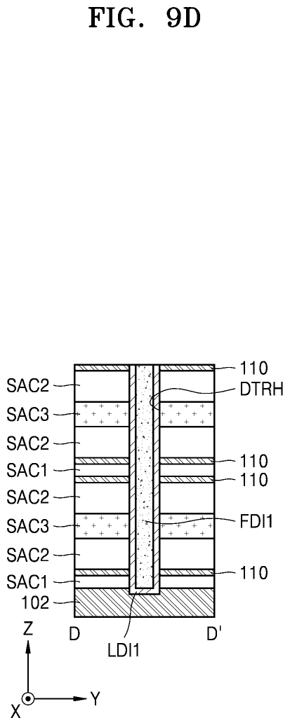

Referring to FIGS. 9A, 9B, 9C, and 9D, a second liner insulating layer LDI2 may be formed to cover the inner sidewall and bottom surface of the first isolation trench STR1, and a second filling insulating layer FDI2 may be formed to cover the second liner insulating layer LDI2 and fill the first isolation trench STR1. The second liner insulating layer LDI2 may be formed to conformally cover the inner sidewall and bottom surface of the first isolation trench STR1. For example, the second liner insulating layer LDI2 may include SiO₂ or SiOC, and the second filling insulating layer FDI2 may include Si₃N₄ and SiOCN.

A first cover mask layer CMK1 may be formed to cover the second liner insulating layer LDI2, the second filling insulating layer FDI2, and the stack structure including the first channel layers 110P, the first sacrificial layers SAC1, the second sacrificial layers SAC2, and the third sacrificial layers SAC3. The first cover mask layer CMK1 may be formed not to overlap the second isolation trench STR2 in the vertical direction (the Z direction).

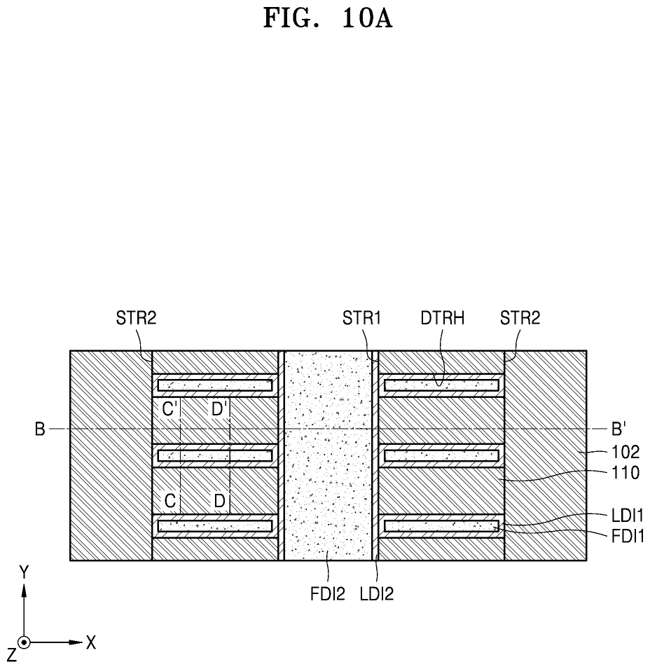

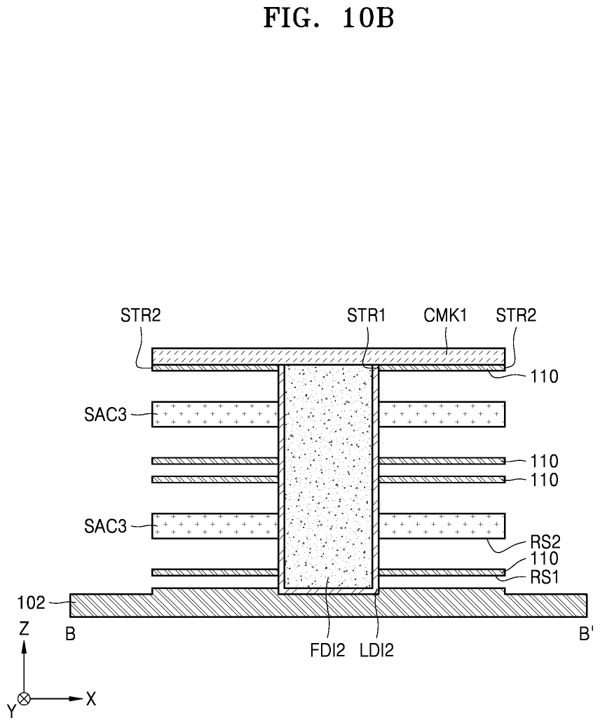

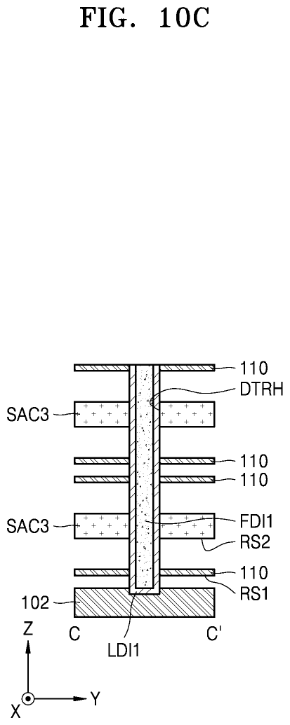

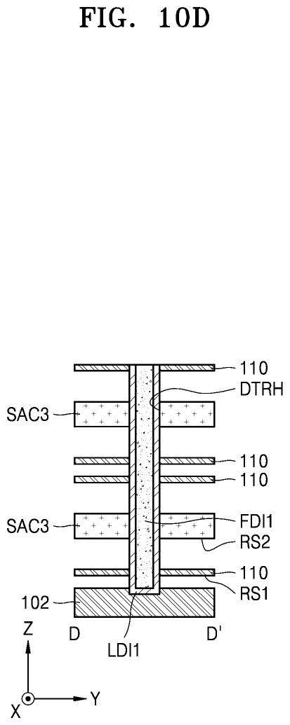

Referring to FIGS. 9A, 9B, 9C, 9D, 10A, 10B, 10C, and 10D, a plurality of first removal spaces RS1 and a plurality of second removal spaces RS2 may be formed by removing the first sacrificial layers SAC1 and the second sacrificial layers SAC2 through the second isolation trench STR2, which is exposed without being covered by the first cover mask layer CMK1. The first removal spaces RS1 may be respectively formed by removing the first sacrificial layers SAC1, and the second removal spaces RS2 may be formed by removing the second sacrificial layers SAC2. The first channel patterns 110, the third sacrificial layers SAC3, the first liner insulating layer LDI1, and the second liner insulating layer LDI2 may be exposed by the first removal spaces RS1 and the second removal spaces RS2. The first removal spaces RS1 and the second removal spaces RS2 may be formed to be in communication with a deep trench hole DTRH and the first isolation trench STR1.

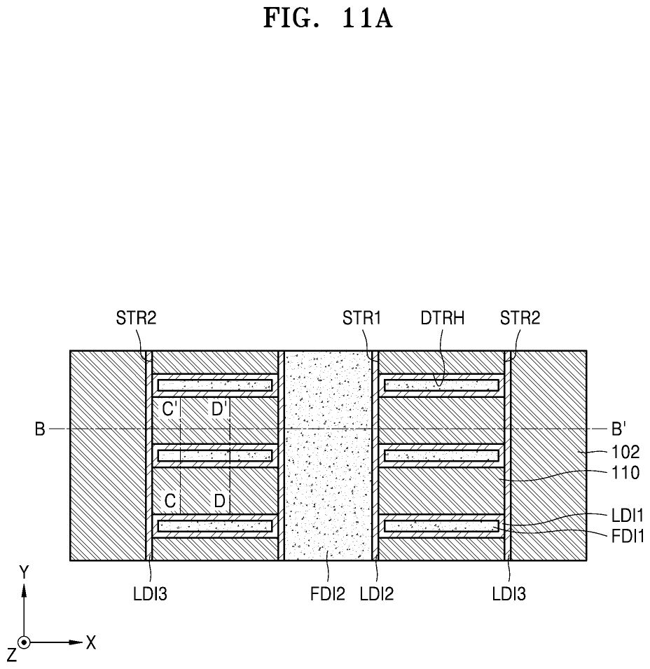

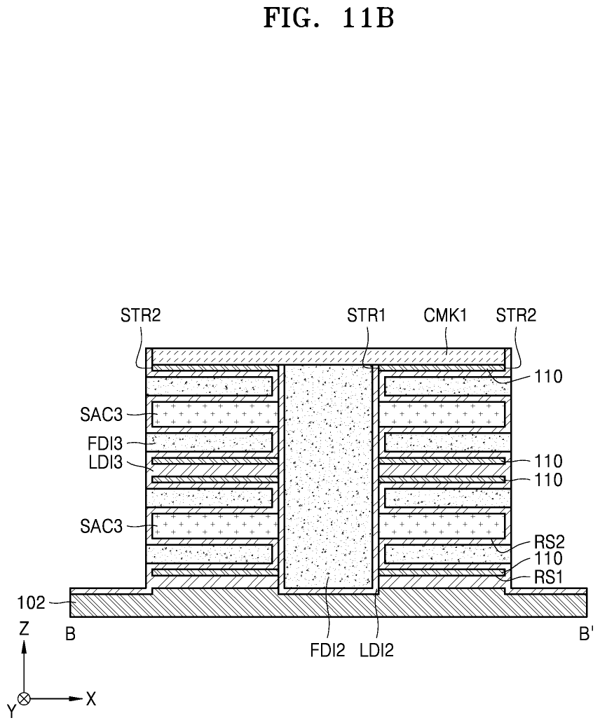

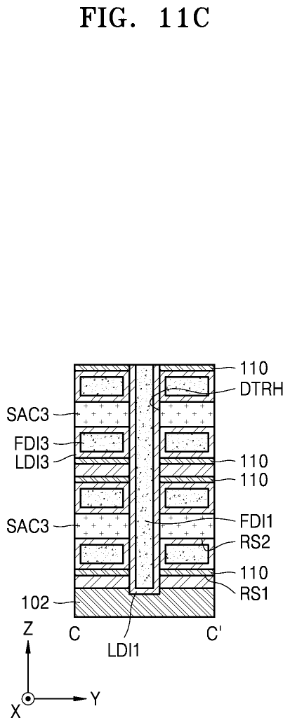

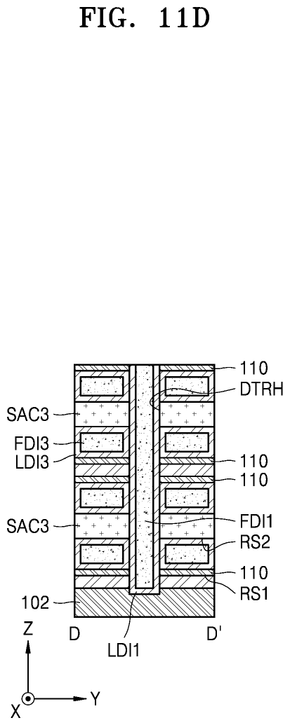

Referring to FIGS. 11A, 11B, 11C, and 11D, a third liner insulating layer LDI3 may be formed to cover the exposed surface of the resultant structure having the first removal spaces RS1 and the second removal spaces RS2, and a third filling insulating layer FDI3 may be formed to cover the third liner insulating layer LDI3 and fill a space defined by the third liner insulating layer LDI3. For example, the third liner insulating layer LDI3 may be formed to conformally cover the inner surface of each of the first removal spaces RS1 and the second removal spaces RS2 and the side surface of each of the first channel patterns 110, the side surface of each of the third sacrificial layers SAC3, and the surface of the substrate 102, which are exposed by the second isolation trench STR2. The third filling insulating layer FDI3 may fill the space defined by the third liner insulating layer LDI3. For example, the first removal spaces RS1 may be completely filled with the third liner insulating layer LDI3, and the second removal spaces RS2 may each be completely filled with the third liner insulating layer LDI3 and the third filling insulating layer FDI3. For example, the third liner insulating layer LDI3 may include SiO₂ or SiOC, and the third filling insulating layer FDI3 may include Si₃N₄ and SiOCN.

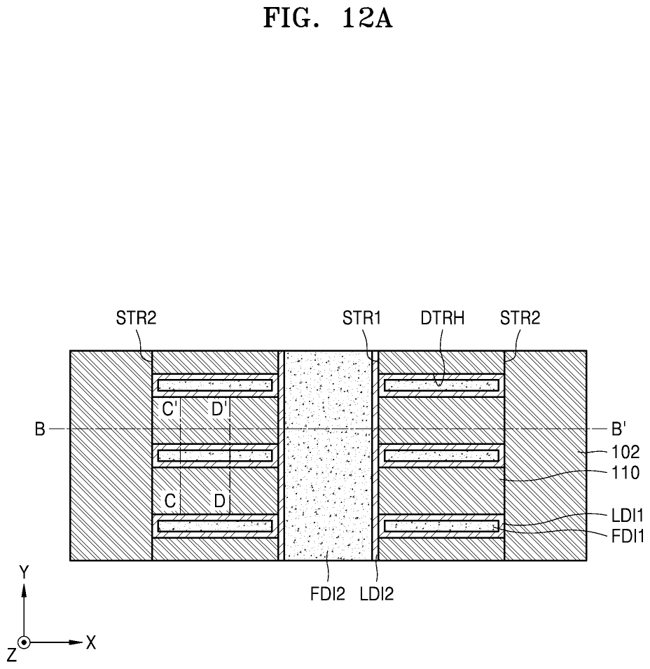

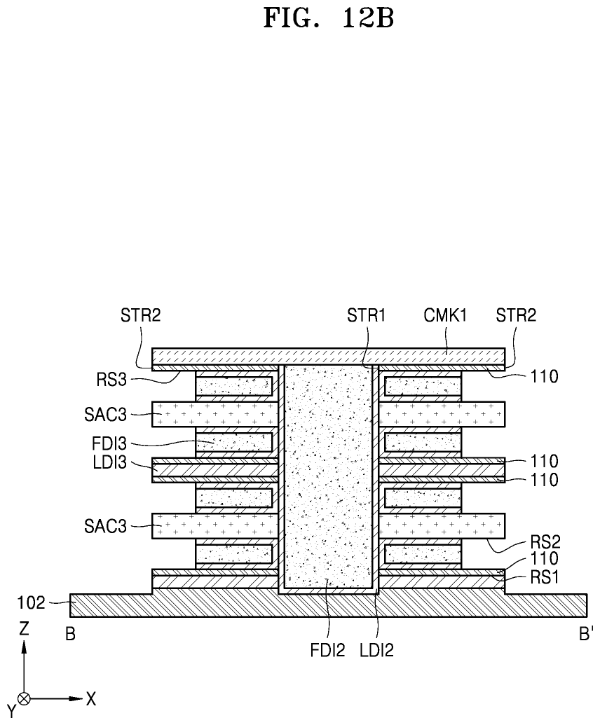

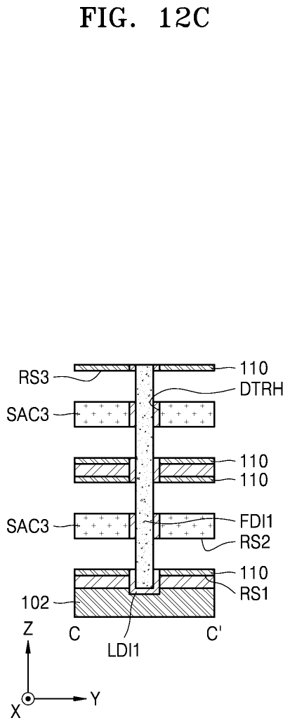

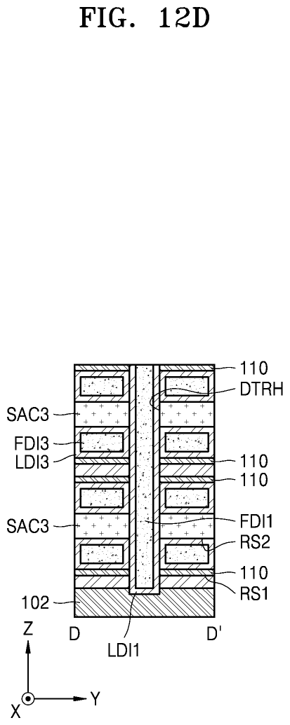

Referring to FIGS. 11A, 11B, 11C, 11D, 12A, 12B, 12C, and 12D, a plurality of third removal spaces RS3 may be formed by removing portions of the third filling insulating layer FDI3 filling the second removal spaces RS2 through the second isolation trench STR2 and removing portions of the third liner insulating layer LDI3 exposed after the portions of the third filling insulating layer FDI3 are removed. The third removal spaces RS3 may respectively correspond to portions of the second removal spaces RS2. The portions of the third liner insulating layer LDI3, which fill the first removal spaces RS1, may remain without being removed. In the process of removing the portions of the third liner insulating layer LDI3, the exposed portions of the first liner insulating layer LDI1 may also be removed. For example, the first filling insulating layer FDI1, the first channel patterns 110, the third sacrificial layers SAC3, the remaining portions of the third filling insulating layer FDI3, and the remaining portion of the third liner insulating layer LDI3 may be exposed by the third removal spaces RS3.

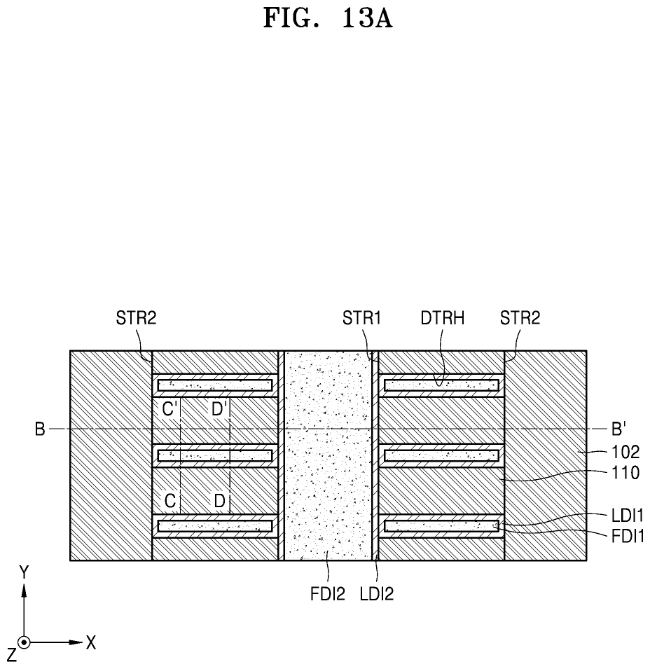

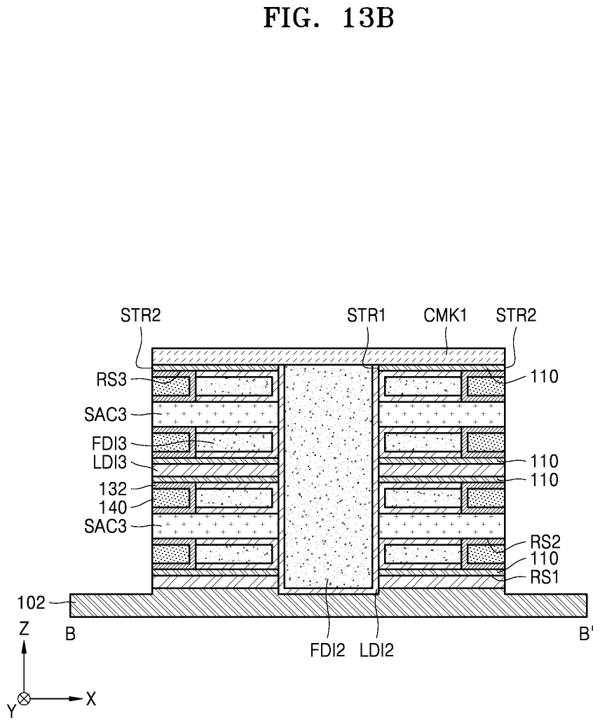

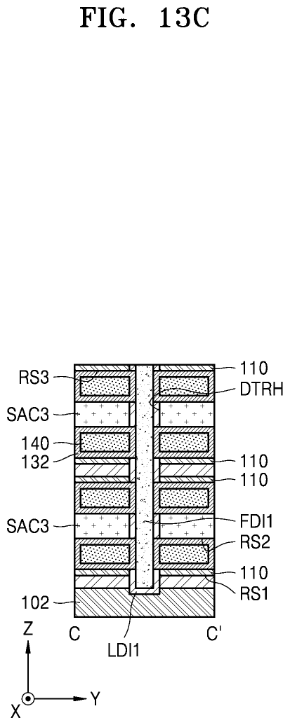

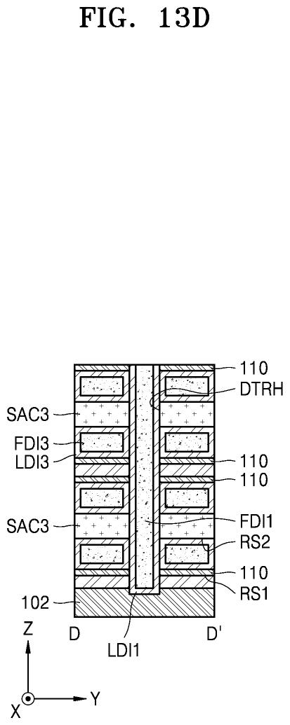

Referring to FIGS. 13A, 13B, 13C, and 13D, a first gate dielectric layer 132 may be formed to cover the inner surface of each of the third removal spaces RS3, and the information storage element 140 may be formed to cover the first gate dielectric layer 132 and fill each of the third removal spaces RS3. The first gate dielectric layer 132 may be formed to conformally cover the inner surface of each of the third removal spaces RS3.

For example, the first gate dielectric layer 132 may include at least one selected from the group consisting of a silicon oxide, a high-k dielectric material having a higher dielectric constant than silicon oxide, and a ferroelectric material. In one or more example embodiments, the first gate dielectric layer 132 may have a stack structure of a first dielectric film including a silicon oxide and a second dielectric film including at least one of a high-k dielectric material and a ferroelectric material. For example, the high-k dielectric material and the ferroelectric material may include at least one selected from the group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO). The information storage element 140 may include an oxide semiconductor material, a 2D semiconductor material, a conductive material, or a combination thereof. For example, the information storage element 140 may include an oxide semiconductor material such as IGZO.

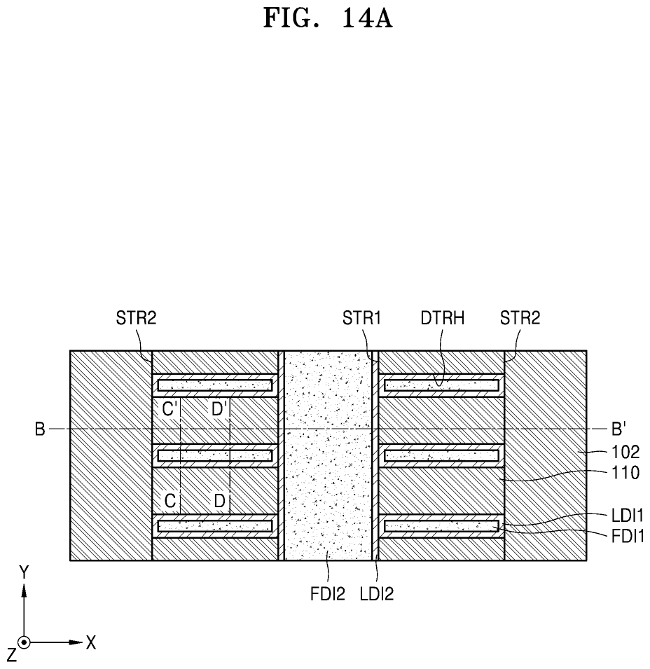

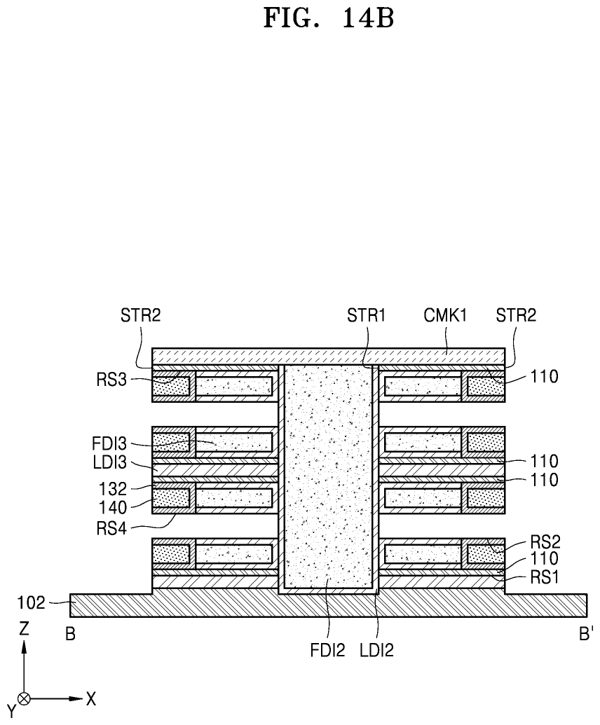

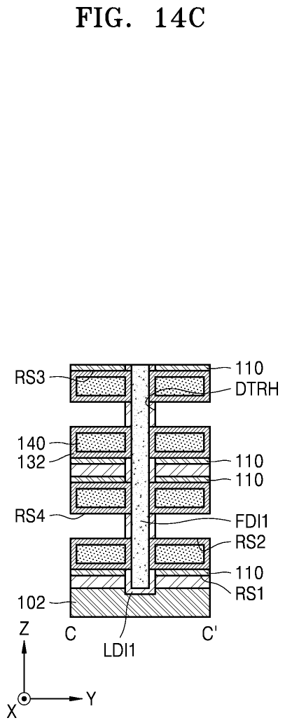

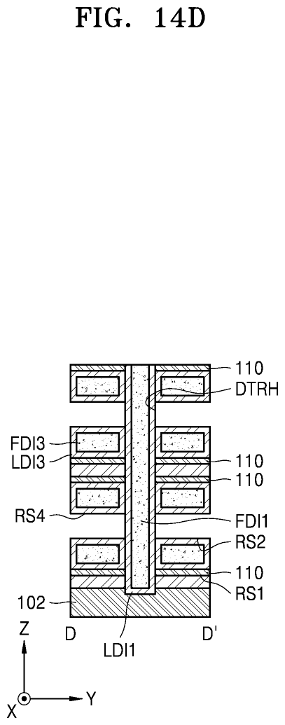

Referring to FIGS. 13A, 13B, 13C, 13D, 14A, 14B, 14C, and 14D, a plurality of fourth removal spaces RS4 may be formed by removing the third removal spaces RS3. Respective portions of the first liner insulating layer LDI1, the second liner insulating layer LDI2, the third liner insulating layer LDI3, and the first gate dielectric layer 132 may be exposed by each of the fourth removal spaces RS4.

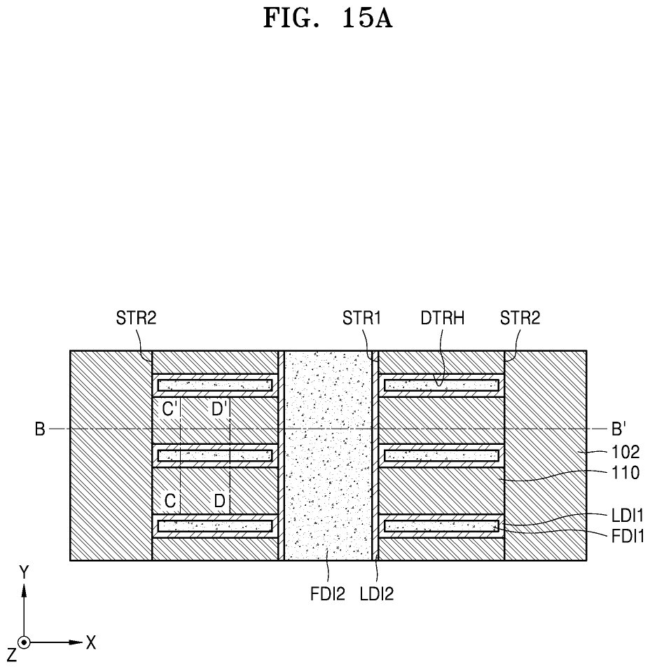

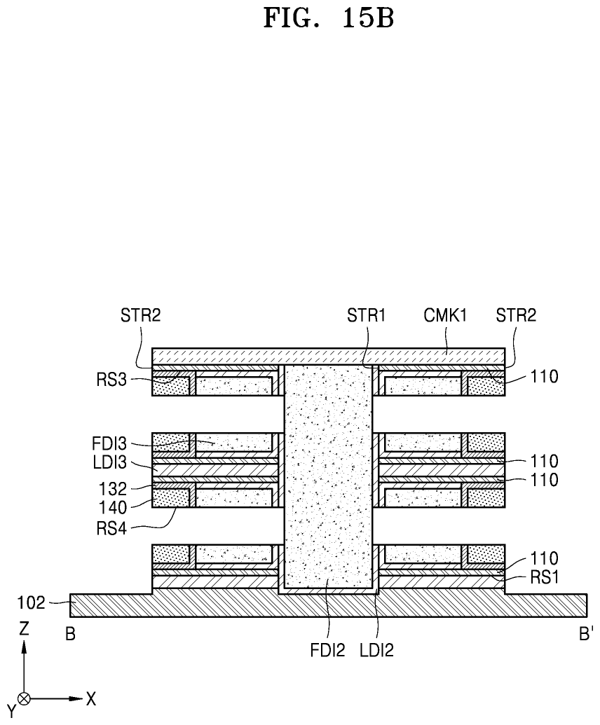

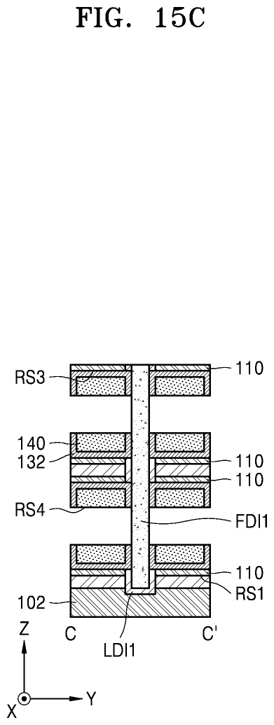

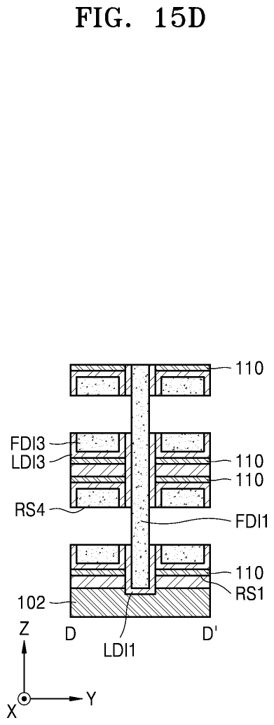

Referring to FIGS. 14A, 14B, 14C, 14D, 15A, 15B, 15C, and 15D, each of the fourth removal spaces RS4 may be expanded by removing the respective portions of the first liner insulating layer LDI1, the second liner insulating layer LDI2, the third liner insulating layer LDI3, and the first gate dielectric layer 132, which are exposed by each of the fourth removal spaces RS4. Respective portions of the information storage element 140, the first gate dielectric layer 132, the third filling insulating layer FDI3, the third liner insulating layer LDI3, the second liner insulating layer LDI2, the second filling insulating layer FDI2, and the first filling insulating layer FDI1 may be exposed by each of the fourth removal spaces RS4 that have been expanded.

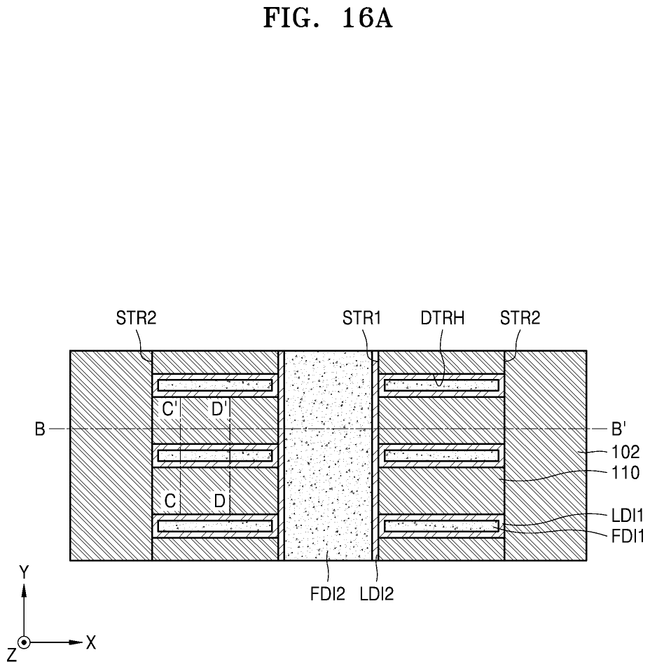

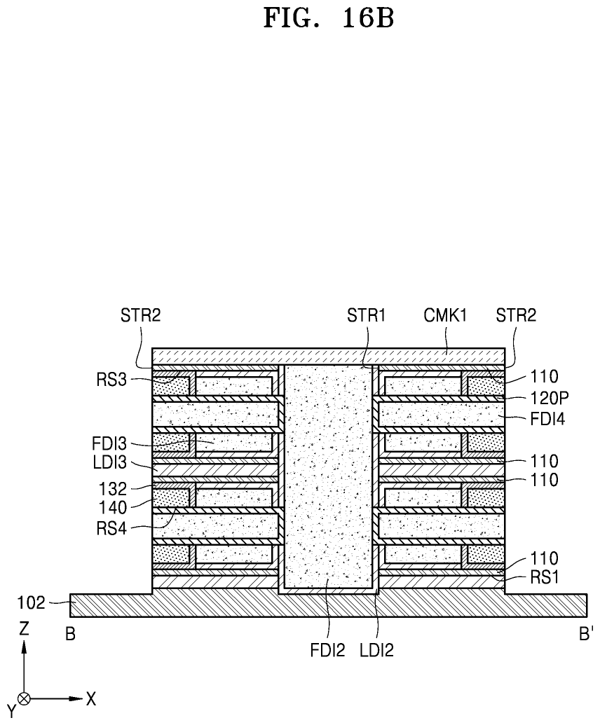

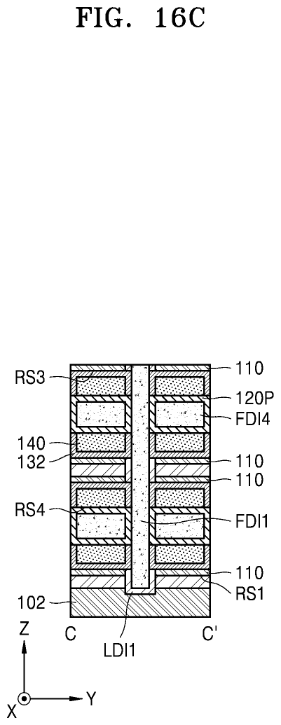

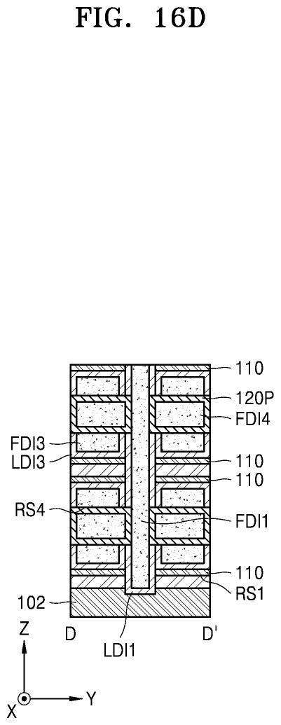

Referring to FIGS. 16A, 16B, 16C, and 16D, a second channel layer 120P may be formed to cover the inner surface of each of the fourth removal spaces RS4, and a fourth filling insulating layer FDI4 may be formed to cover the second channel layer 120P and fill each of the fourth removal spaces RS4. The second channel layer 120P may be formed to conformally cover the inner surface of each of the fourth removal spaces RS4. The fourth filling insulating layer FDI4 may be formed to fill the remaining space of each of the fourth removal spaces RS4. The second channel layer 120P may include a monocrystalline semiconductor material, a polycrystalline semiconductor material, an oxide semiconductor material, or a 2D semiconductor material. For example, the second channel layer 120P may include an oxide semiconductor material such as IGZO. In one or more example embodiments, the second channel layer 120P may include the same material as the information storage element 140. For example, the fourth filling insulating layer FDI4 may include Si₃N₄ or SiOCN.

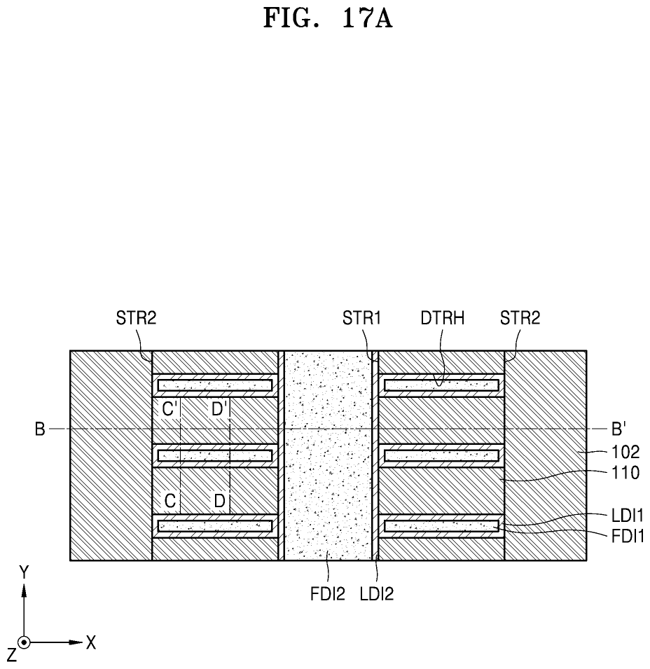

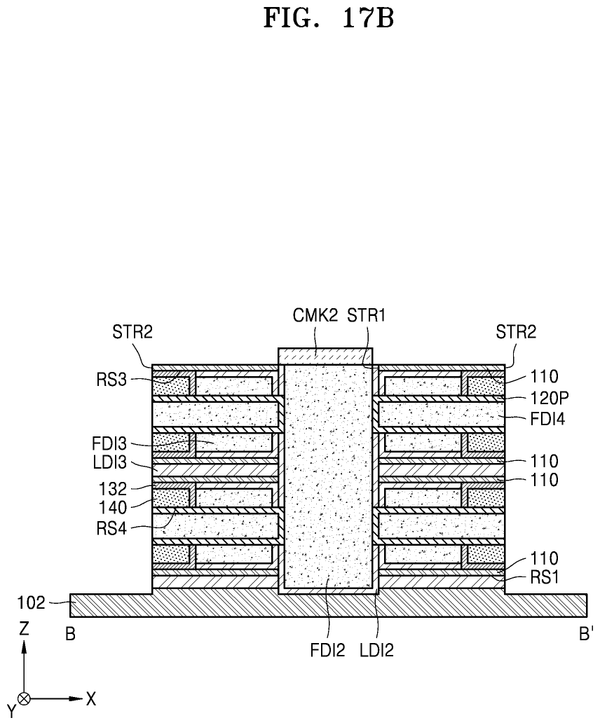

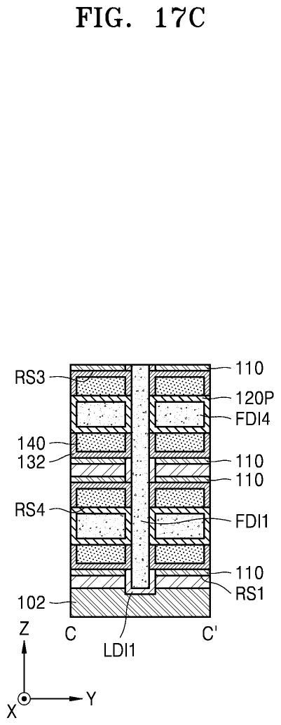

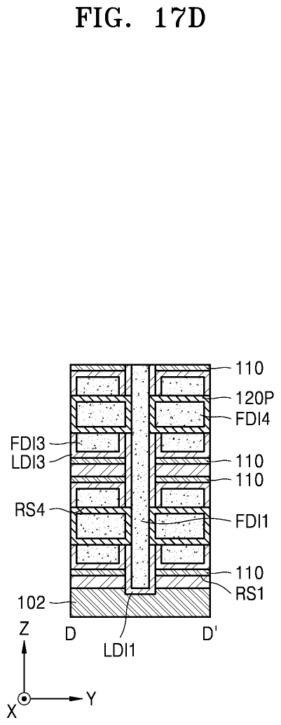

Referring to FIGS. 16A, 16B, 16C, 16D, 17A, 17B, 17C, and 17D, a second cover mask layer CMK2 may be formed by removing a portion of the first cover mask layer CMK1. The second cover mask layer CMK2 may cover the second liner insulating layer LDI2 and the second filling insulating layer FDI2, which fill the first isolation trench STR1. For example, the second cover mask layer CMK2 may be formed by removing a portion of the first cover mask layer CMK1 that overlaps the first channel patterns 110 in the vertical direction (the Z direction).

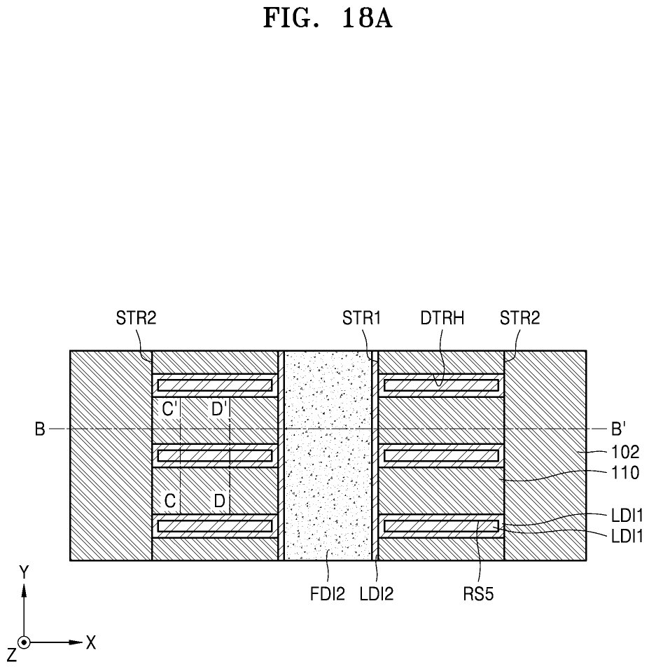

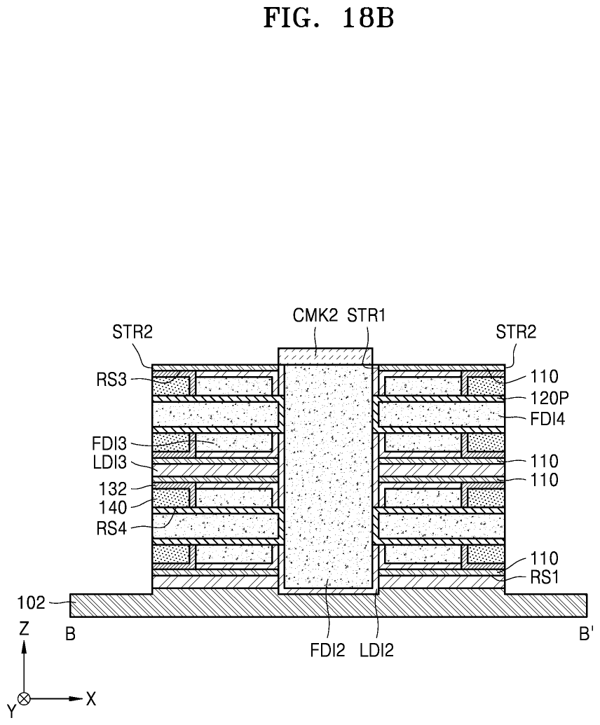

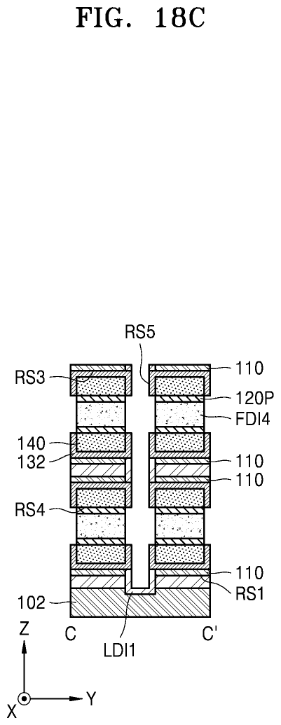

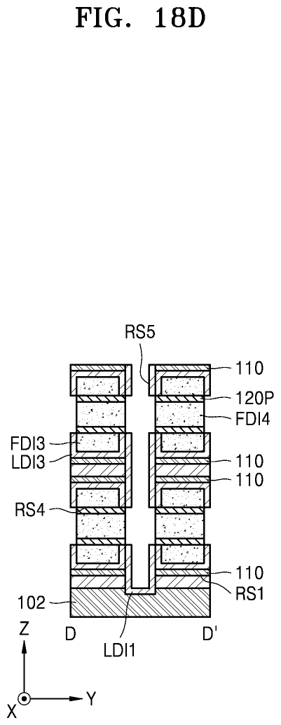

Referring to FIGS. 17A, 17B, 17C, 17D, 18A, 18B, 18C, and 18D, a fifth removal space RS5 may be formed by removing the first filling insulating layer FDI1 and removing a portion of the second channel layer 120P that is exposed by removing the first filling insulating layer FDI1. Respective portions of the first liner insulating layer LDI1, the second channel layer 120P, and the fourth filling insulating layer FDI4 may be exposed by the fifth removal space RS5.

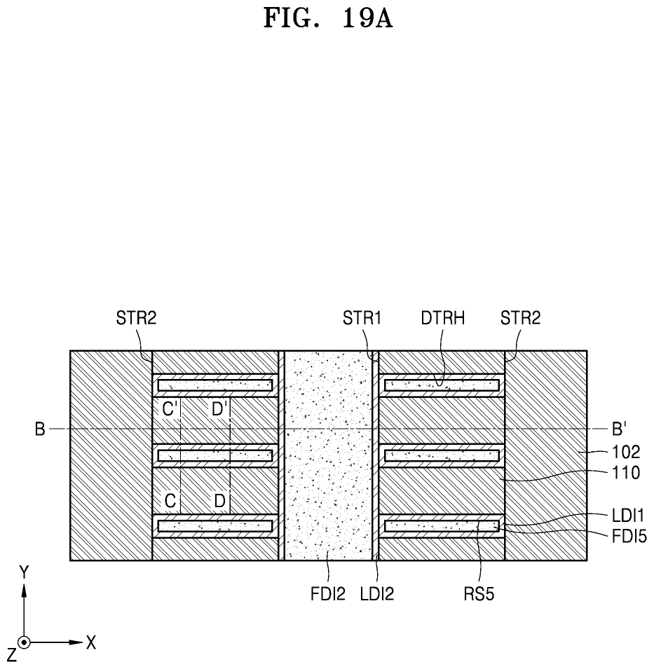

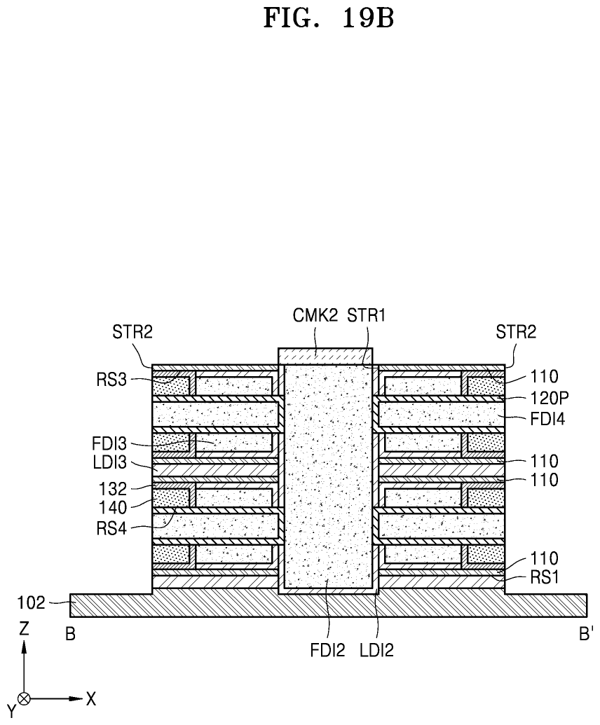

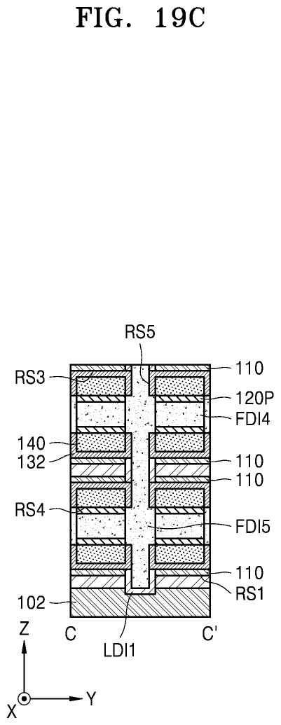

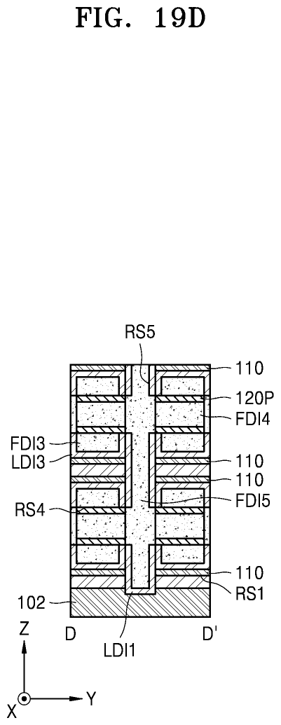

Referring to FIGS. 19A, 19B, 19C, and 19D, a fifth filling insulating layer FDI5 may be formed to fill the fifth removal space RS5. For example, the fifth filling insulating layer FDI5 may include Si₃N₄ or SiOCN. In one or more example embodiments, before the fifth filling insulating layer FDI5 is formed, an impurity may be implanted into the portion of the second channel layer 120P exposed by the fifth removal space RS5. For example, an impurity, such as H or O, may be implanted into the portion of the second channel layer 120P.

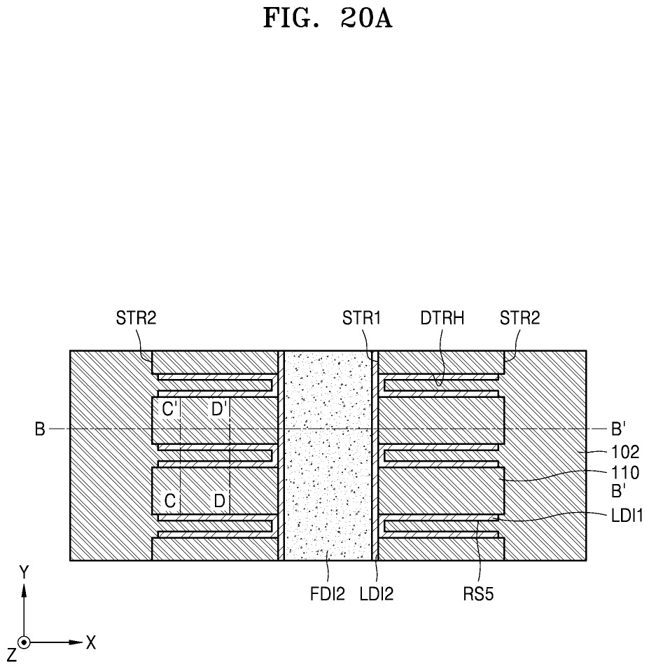

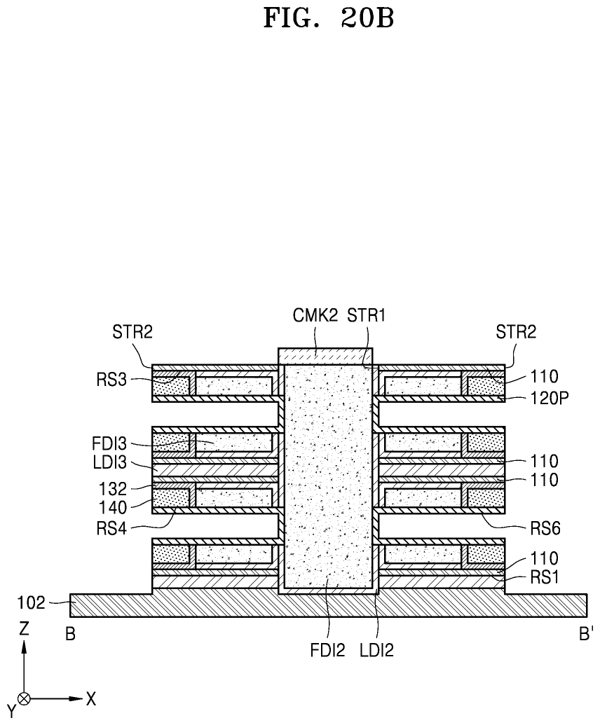

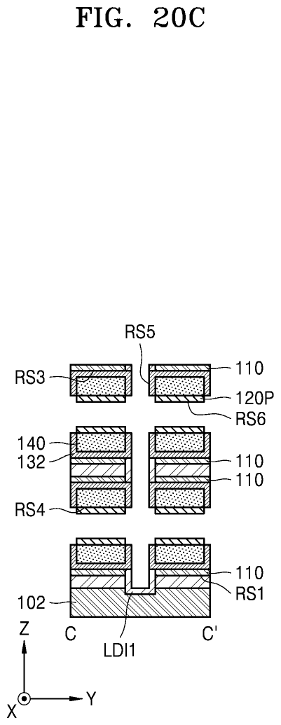

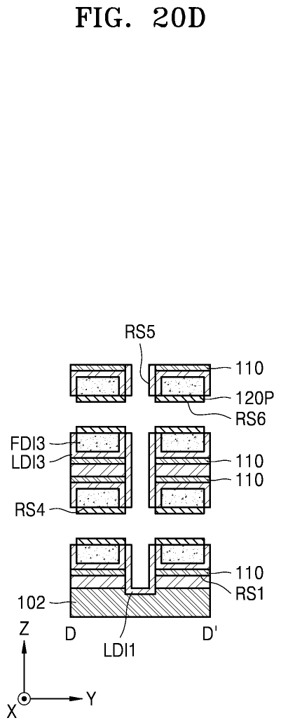

Referring to FIGS. 19A, 19B, 19C, 19D, 20A, 20B, 20C, and 20D, a plurality of sixth removal spaces RS6 may be formed to be in communication with the fifth removal space RS5, which is filled with the fifth filling insulating layer FDI5, by removing the fifth filling insulating layer FDI5 and the fourth filling insulating layer FDI4. In one or more example embodiments, before the fifth filling insulating layer FDI5 and the fourth filling insulating layer FDI4 are removed, portions of the first liner insulating layer LDI1, which are exposed by the second isolation trench STR2, may be removed. The sixth removal spaces RS6 may respectively correspond to respective portions of the fourth removal spaces RS4 in FIGS. 15B, 15C, and 15D. The second channel layer 120P may be exposed by each of the sixth removal spaces RS6. In one or more example embodiments, after the fifth removal space RS5 is formed, the fifth filling insulating layer FDI5 may not be formed, and each sixth removal space RS6 may be formed by removing the fourth filling insulating layer FDI4 through the fifth removal space RS5. The sixth removal space RS6 may correspond to a portion of each of the fourth removal spaces RS4 which is not filled with the second channel layer 120P.

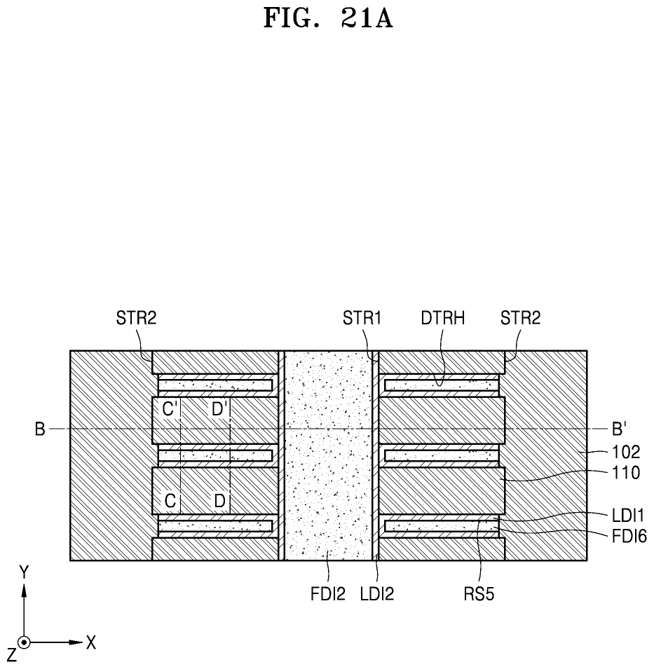

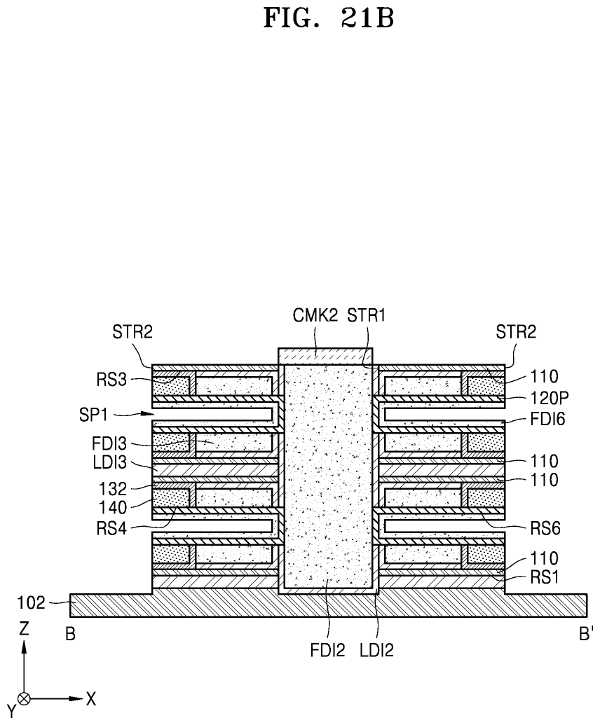

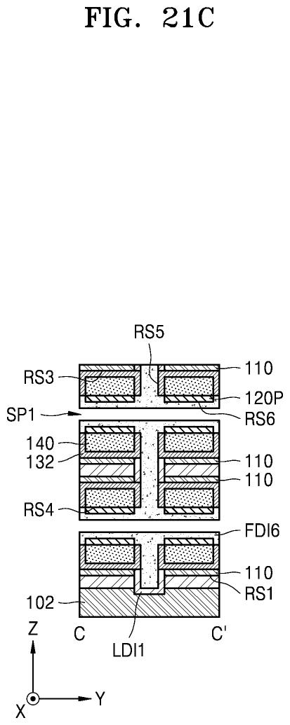

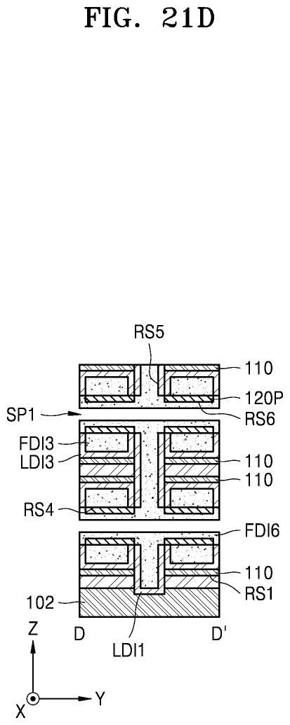

Referring to FIGS. 21A, 21B, 21C, and 21D, a sixth filling insulating layer FDI6 may be formed to fill a portion of the fifth removal space RS5 and a portion of the sixth removal space RS6. For example, the sixth filling insulating layer FDI6 may include Si₃N₄ or SiOCN. The sixth filling insulating layer FDI6 may cover the second channel layer 120P and may not completely fill the sixth removal space RS6. A first limited space SP1 extending in the second horizontal direction (the Y direction) may be defined within the fifth removal space RS5 and the sixth removal space RS6 by the sixth filling insulating layer FDI6.

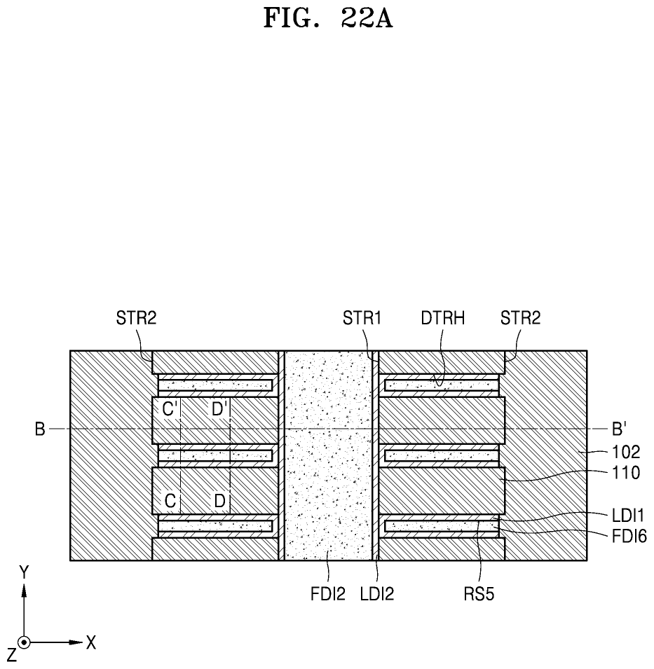

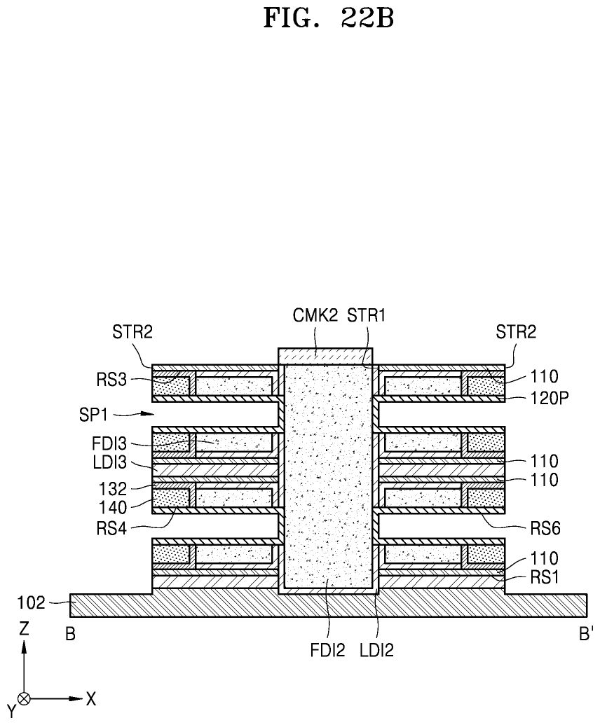

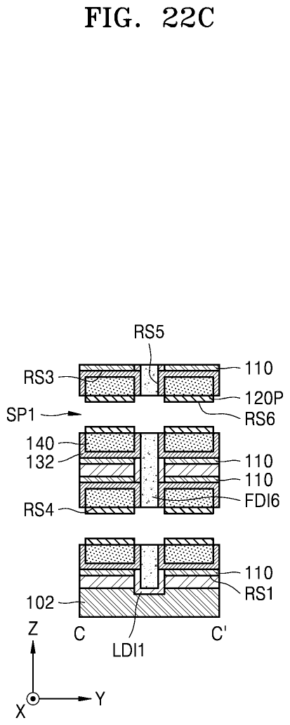

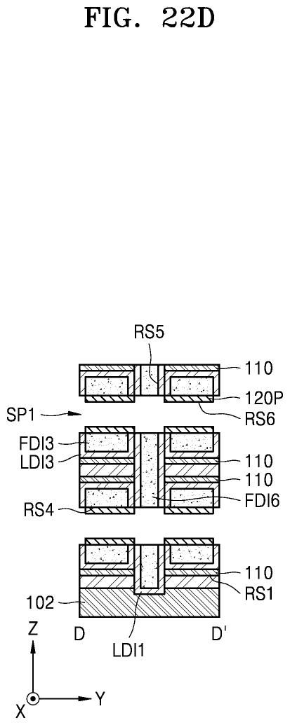

Referring to FIGS. 22A, 22B, 22C, and 22D, the second channel layer 120P may be exposed by removing a portion of the sixth filling insulating layer FDI6 through the first limited space SP1. In one or more example embodiments, a portion of the sixth filling insulating layer FDI6, which fills a portion of the fifth removal space RS5 that does not overlap the fourth removal spaces RS4, may remain without being removed. The first limited space SP1 may be expanded so as to be defined by the sixth filling insulating layer FDI6, the second channel layer 120P, the first gate dielectric layer 132, the first liner insulating layer LDI1, and the third liner insulating layer LDI3 and may extend in the second horizontal direction (the Y direction) within the fifth removal space RS5 and the sixth removal space RS6.

Referring to FIGS. 22A, 22B, 22C, 22D, 23A, 23B, 23C, and 23D, a second gate dielectric layer 158 may be formed to cover the exposed surface of the first limited space SP1. The first separation insulating layer 152, the back-gate line 150, and the second separation insulating layer 154 may be formed to cover the second gate dielectric layer 158 and sequentially fill the first limited space SP1. The back-gate line 150 may extend in the second horizontal direction (the Y direction). The first separation insulating layer 152 and the second separation insulating layer 154 may be respectively arranged at opposite side surfaces of the back-gate line 150 in the first horizontal direction (the X direction) and may extend in the second horizontal direction (the Y direction). For example, the second gate dielectric layer 158 may include at least one selected from the group consisting of a silicon oxide, a high-k dielectric material having a higher dielectric constant than silicon oxide, and a ferroelectric material. In one or more example embodiments, the first gate dielectric layer 132 and the second gate dielectric layer 158 may include the same material. For example, the first separation insulating layer 152 and the second separation insulating layer 154 may include Si₃N₄ or SiOCN.

The first separation insulating layer 152, the back-gate line 150, and the second separation insulating layer 154 may each include a portion which protrudes upwards and downwards to have an increased thickness and which corresponds to a space between second channel layers 120P adjacent to each other in the second horizontal direction (the Y direction). Although only the shape of the second separation insulating layer 154 is illustrated in FIG. 23C, it will be apparent to those skilled in the art that the first separation insulating layer 152 may also include a portion which protrudes upwards and downwards to have an increased thickness and which correspond to a portion between first channel patterns 110 adjacent to each other in the second horizontal direction (the Y direction).

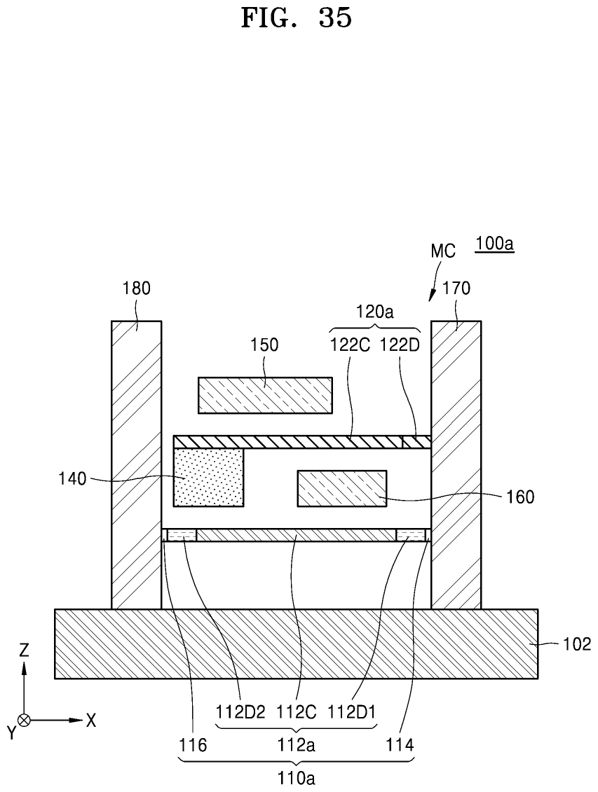

Referring to FIGS. 24A, 24B, 24C, and 24D, a portion of the information storage element 140 and a portion of the second channel layer 120P, which are exposed by the second isolation trench STR2, may be removed, and a third separation insulating layer 145 may be formed to fill a space from which the portion of the information storage element 140 and the portion of the second channel layer 120P have been removed. For example, the third separation insulating layer 145 may include Si₃N₄ or SiOCN. In one or more example embodiments, a second impurity region 112D2 in FIG. 35 may be formed by implanting an impurity into a portion of the first channel pattern 110 exposed by the second isolation trench STR2.

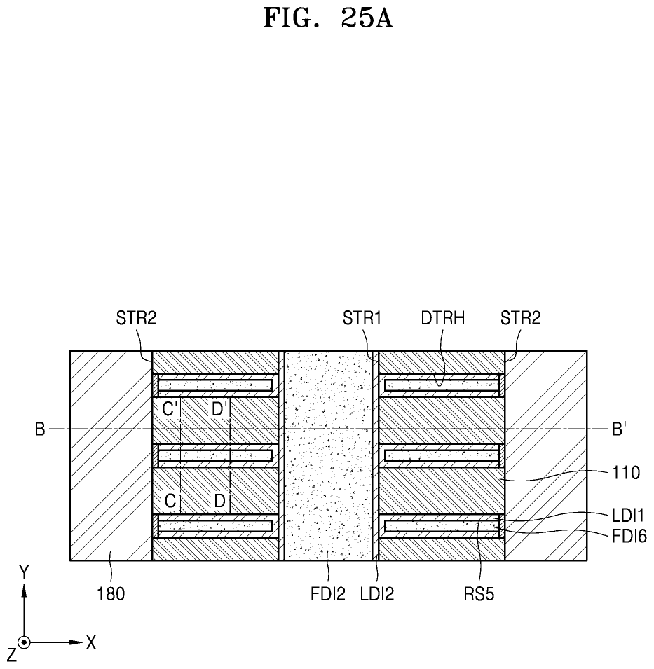

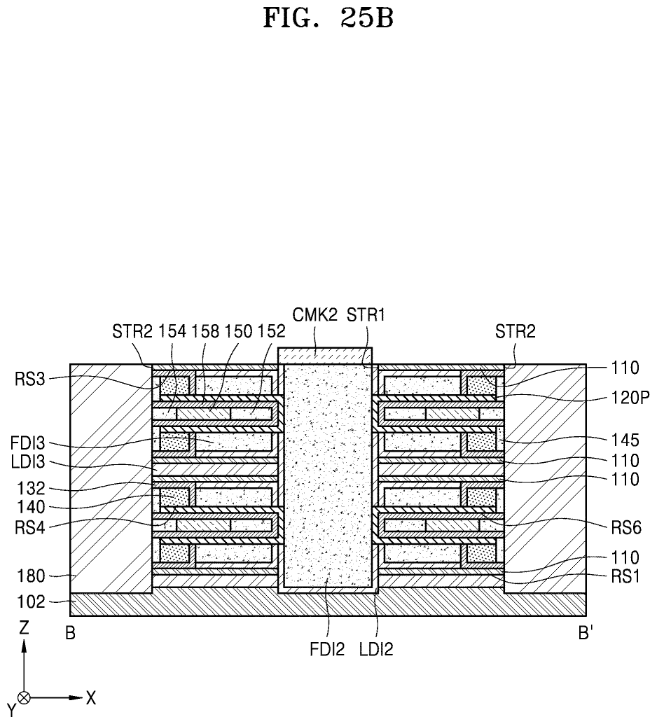

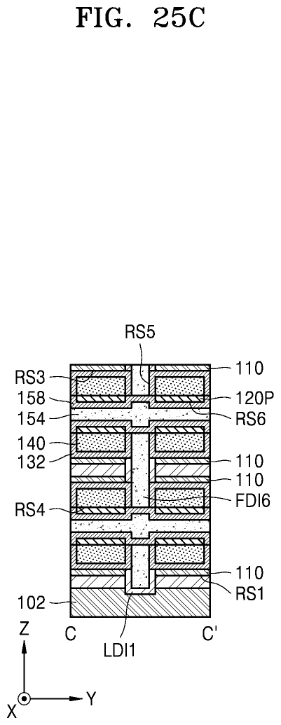

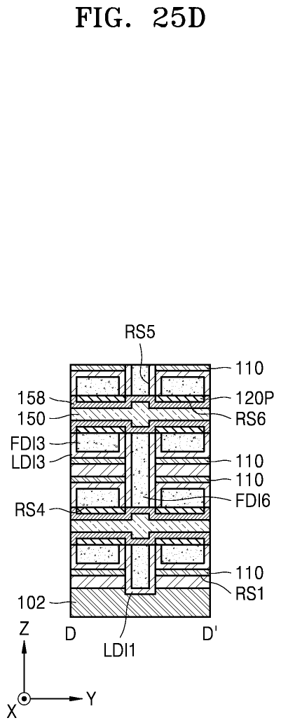

Referring to FIGS. 25A, 25B, 25C, and 25D, the plate electrode 180 may be formed to fill the second isolation trench STR2. The plate electrode 180 may be formed to be in contact with the first channel pattern 110 and spaced apart from the second channel layer 120P and the information storage element 140. For example, the third separation insulating layer 145 may be arranged between the second channel layer 120P and the plate electrode 180 and between the information storage element 140 and the plate electrode 180. The plate electrode 180 may include metal, conductive metal nitride, a metal compound, conductive metal oxide, graphene, a carbon nanotube, or a combination thereof. In one or more example embodiments, before the plate electrode 180 is formed, the second silicide layer 116 in FIG. 3 may be formed in a portion of the first channel pattern 110.

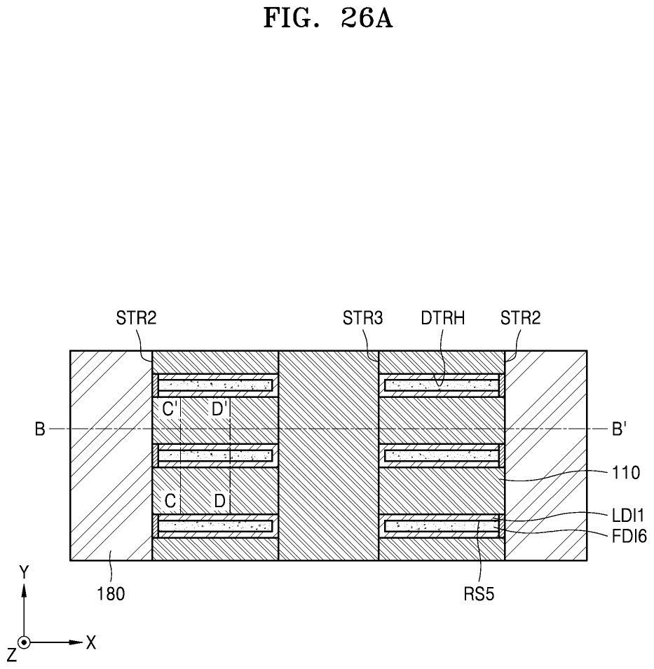

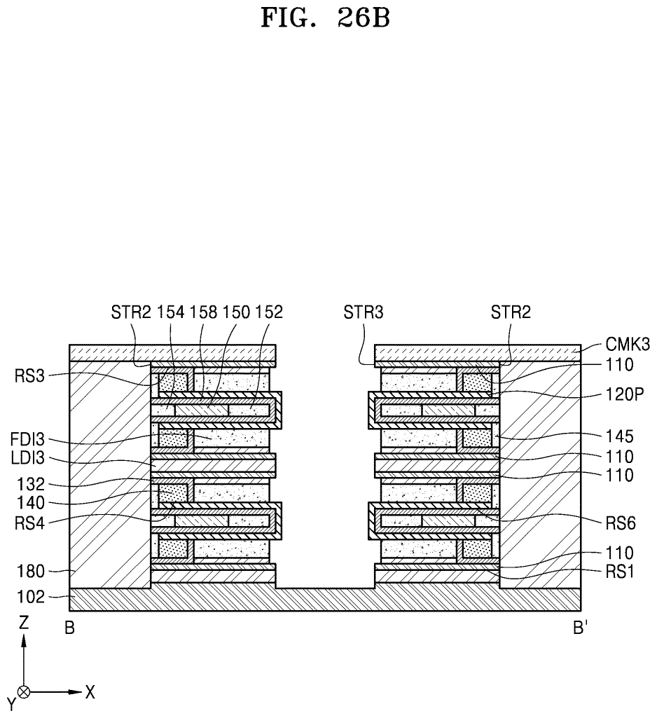

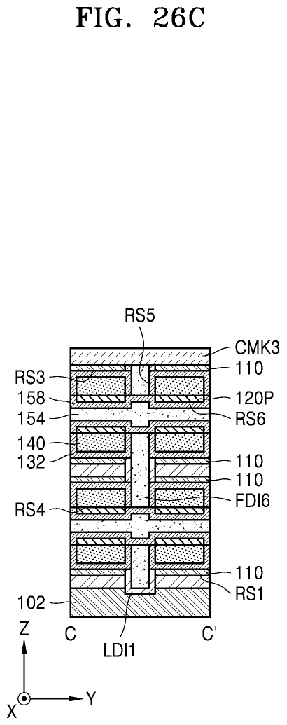

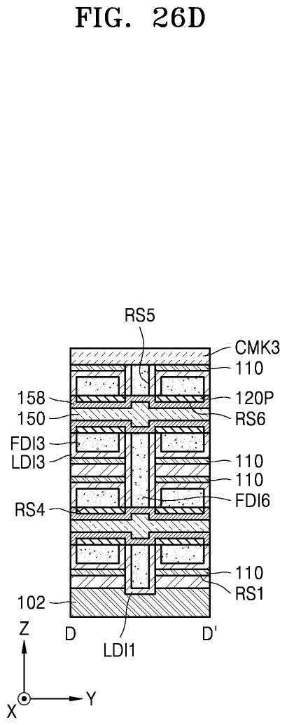

Referring to FIGS. 25A, 25B, 25C, 25D, 26A, 26B, 26C, and 26D, the second cover mask layer CMK2 may be removed, and a third isolation trench STR3 may be formed by removing the second filling insulating layer FDI2 and the second liner insulating layer LDI2 and then removing a portion of the third liner insulating layer LDI3. The third isolation trench STR3 may include the first isolation trench STR1, except for a portion of the first isolation trench STR1 in which a portion of the second channel layer 120P protruding to the first isolation trench STR1 is arranged, and may additionally include the space, from which the portion of the third liner insulating layer LDI3 has been removed, and may be similar overall to the first isolation trench STR1. Accordingly, the third isolation trench STR3 may not be distinguished from the first isolation trench STR1 and may be referred to as the first isolation trench STR1. A third cover mask layer CMK3 may be formed to cover the plurality of first channel patterns 110 and the plurality of plate electrodes 180. The third cover mask layer CMK3 may be formed to overlap the plurality of first channel patterns 110 and the plate electrodes 180 in the vertical direction (the Z direction) but not to overlap the exposed portion of the substrate 102 at the bottom of the third isolation trench STR3 in the vertical direction (the Z direction). In one or more example embodiments, a first impurity region 112D1 in FIG. 35 may be formed by implanting an impurity into a portion of each of the first channel patterns 110 exposed by the third isolation trench STR3.

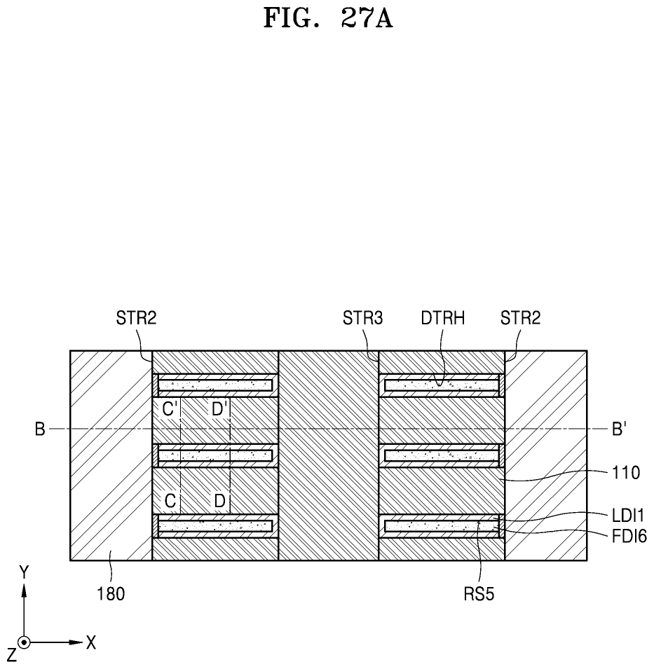

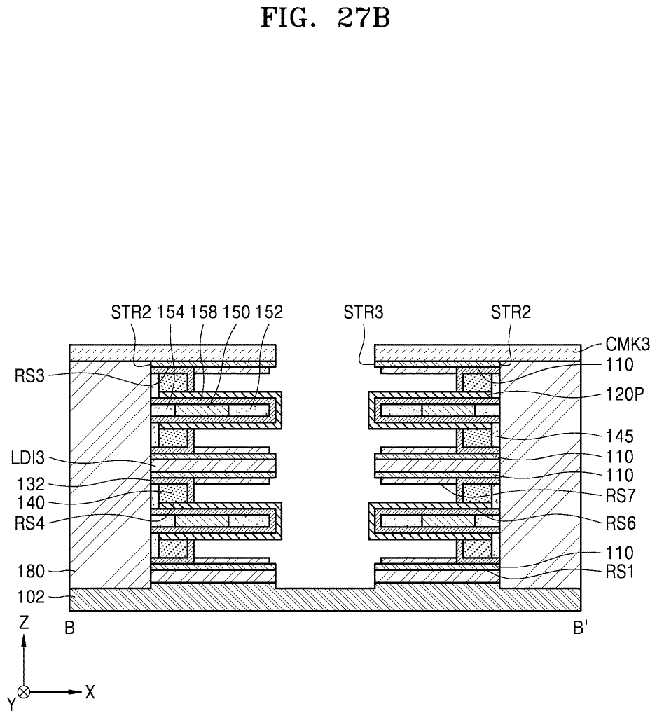

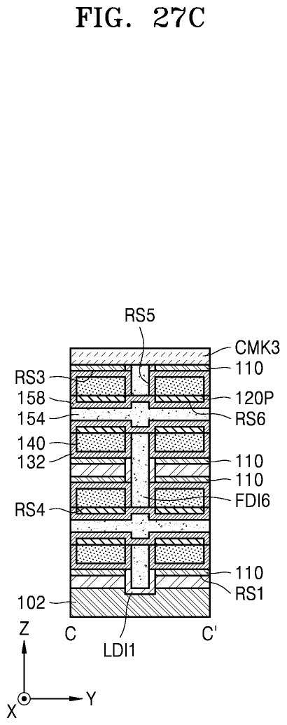

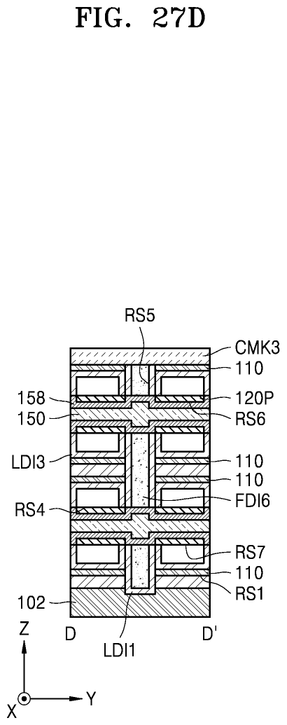

Referring to FIGS. 26A, 26B, 26C, 26D, 27A, 27B, 27C, and 27D, a plurality of seventh removal spaces RS7 may be formed by removing the third filling insulating layer FDI3 through the third isolation trench STR3. The seventh removal spaces RS7 may respectively correspond to portions of the second removal spaces RS2 in FIGS. 10B, 10C, and 10D.

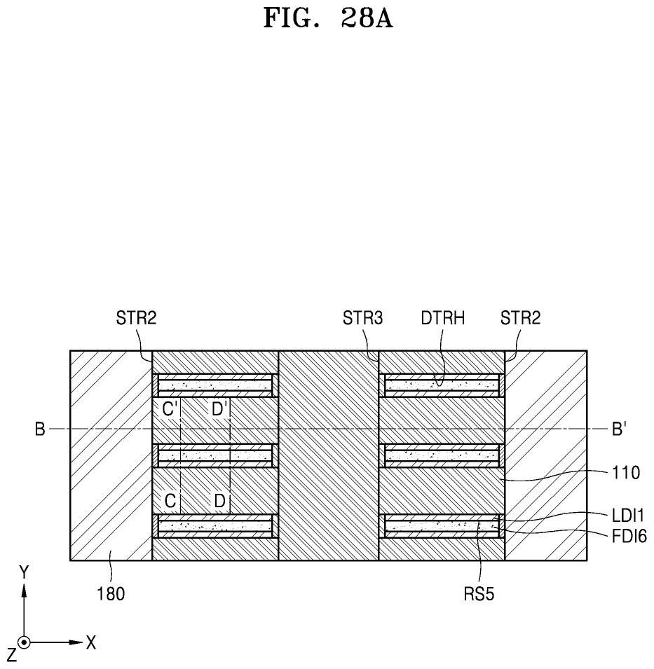

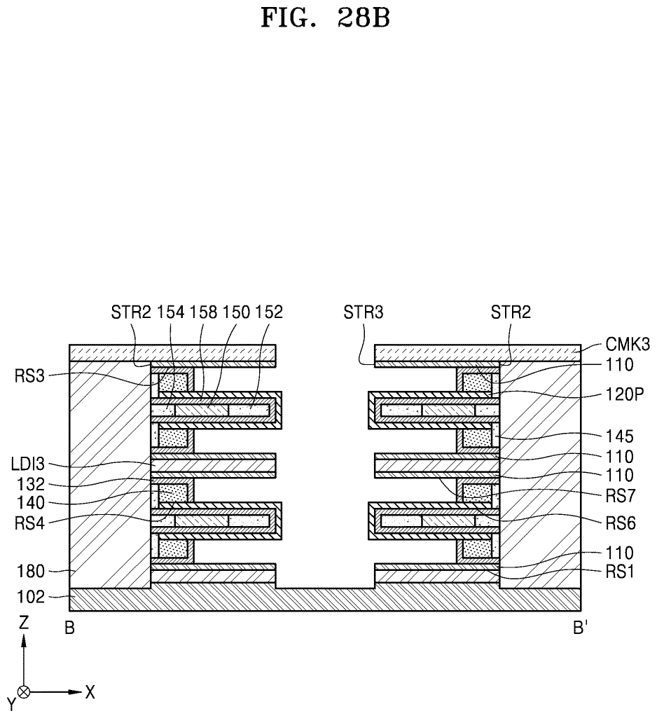

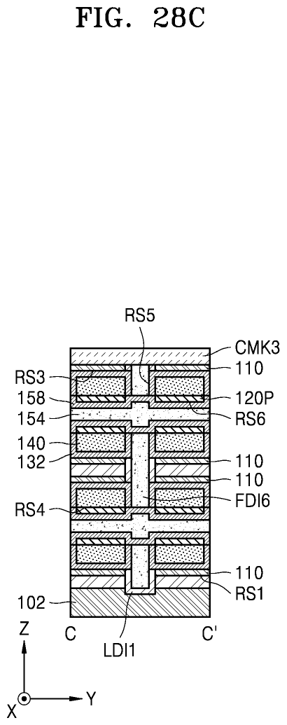

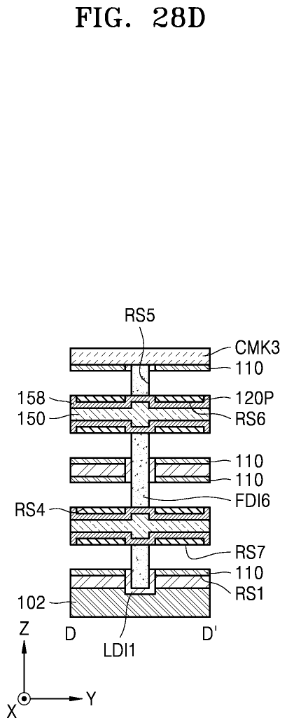

Referring to FIGS. 27A, 27B, 27C, 27D, 28A, 28B, 28C, and 28D, each of the seventh removal spaces RS7 may be expanded by removing a portion of the third liner insulating layer LDI3 in each seventh removal space RS7. In one or more example embodiments, a portion of the third liner insulating layer LDI3 between two first channel patterns 110 adjacent to each other in the vertical direction (the Z direction) may remain without being removed.

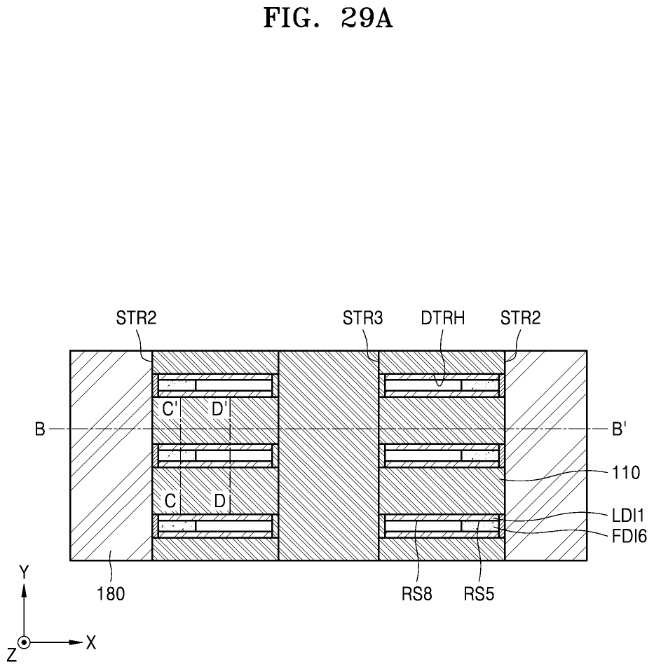

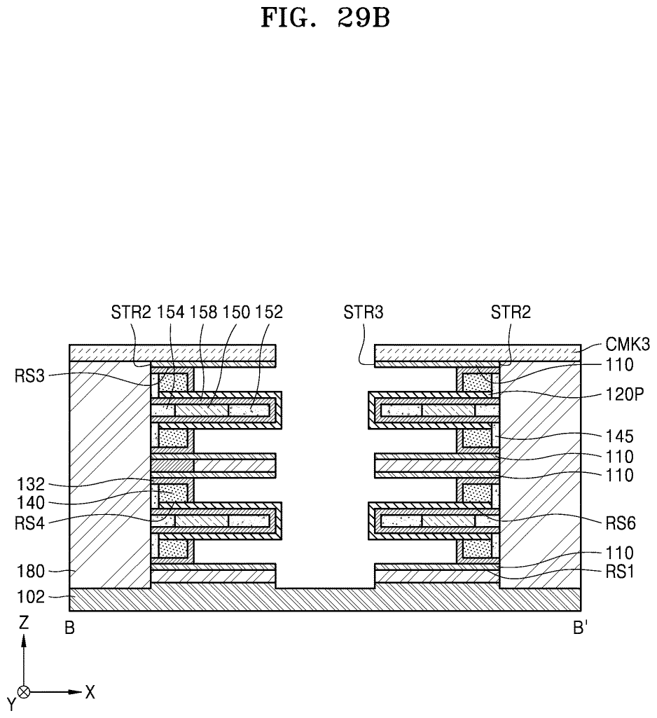

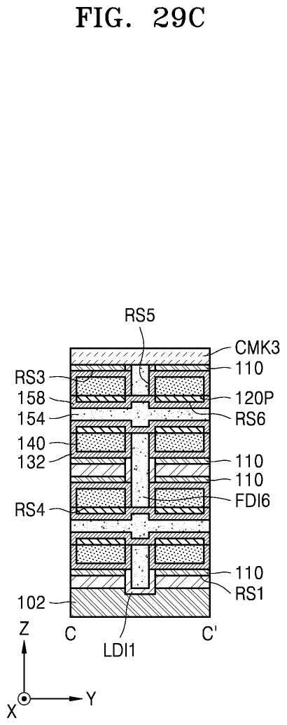

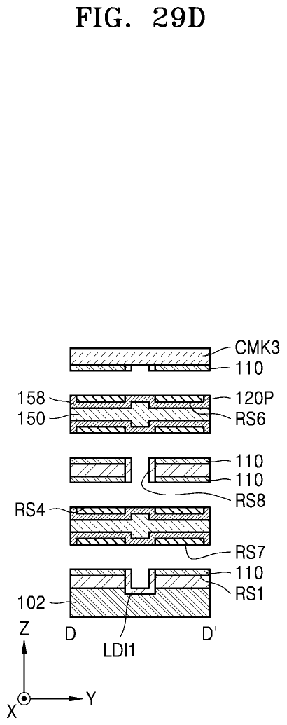

Referring to FIGS. 28A, 28B, 28C, 28D, 29A, 29B, 29C, and 29D, an eighth removal space RS8 may be formed by removing a portion of the sixth filling insulating layer FDI6 exposed by the seventh removal space RS7.

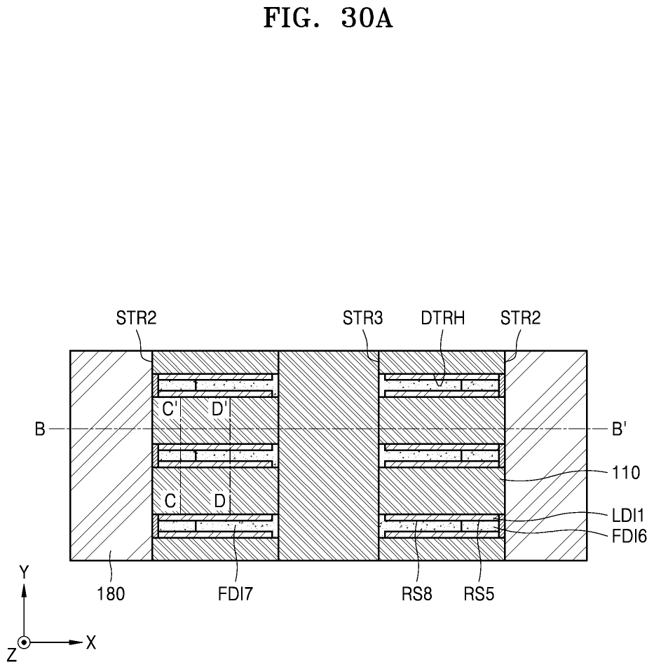

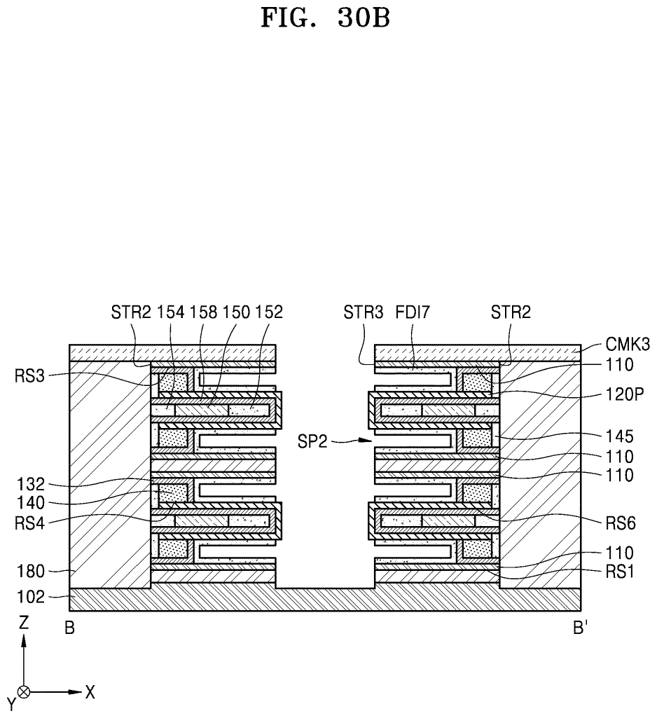

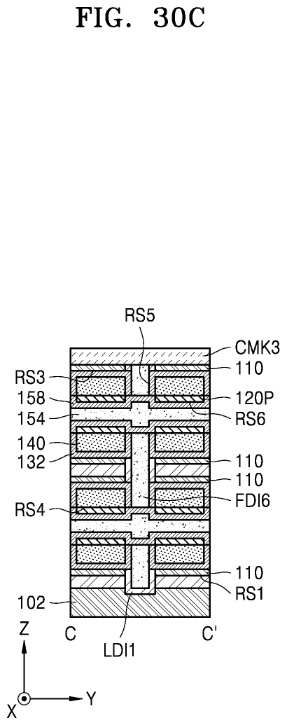

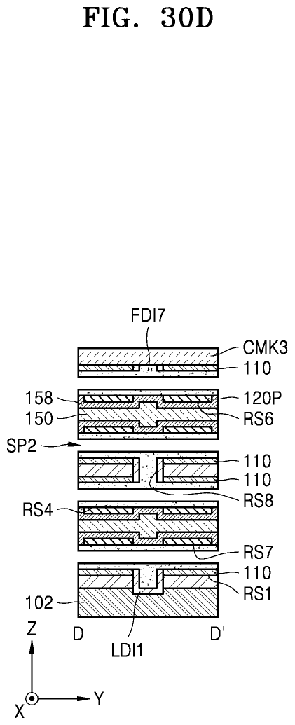

Referring to FIGS. 30A, 30B, 30C, and 30D, a seventh filling insulating layer FDI7 may be formed to fill a portion of the seventh removal space RS7 and a portion of the eighth removal space RS8. For example, the seventh filling insulating layer FDI7 may include Si₃N₄ or SiOCN. The seventh filling insulating layer FDI7 may be formed to completely fill the eighth removal space RS8 but may not completely fill the seventh removal space RS7. A second limited space SP2 extending in the second horizontal direction (the Y direction) in the seventh removal space RS7 may be defined by the seventh filling insulating layer FDI7.

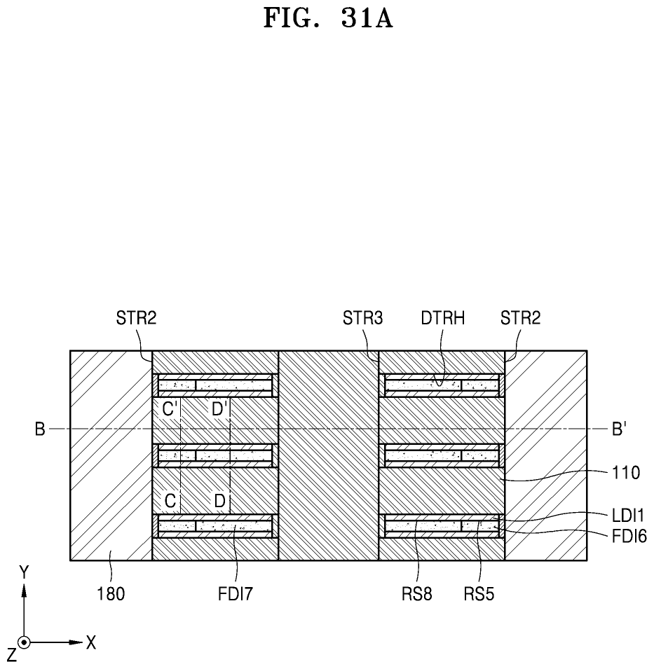

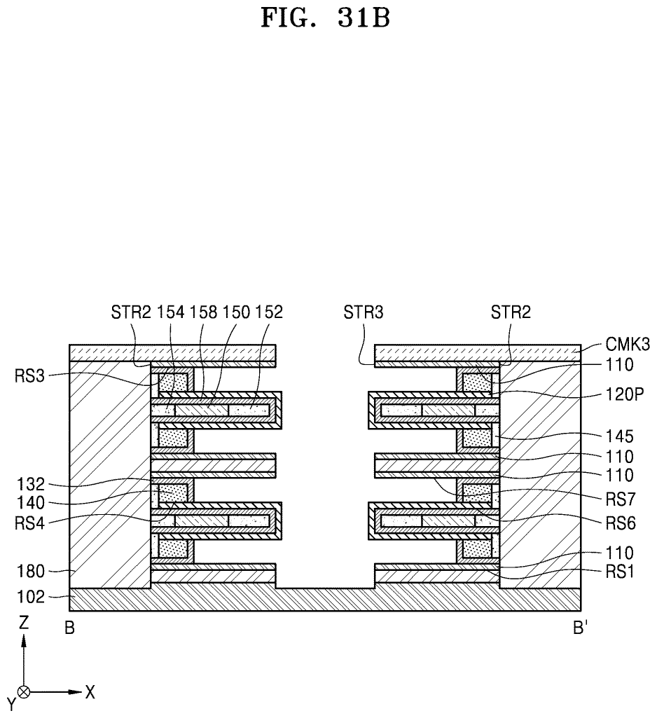

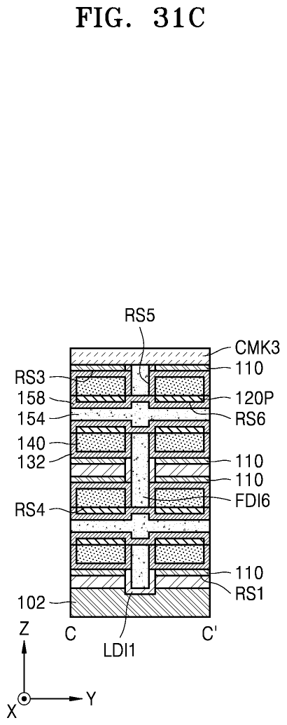

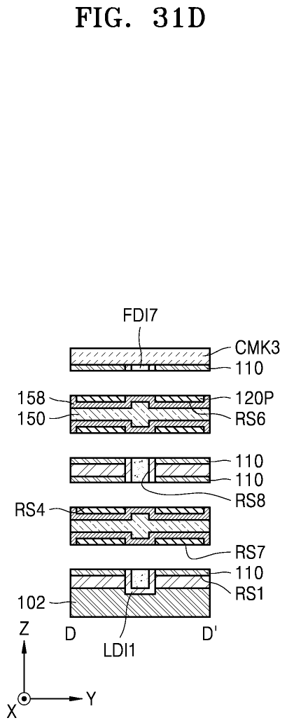

Referring to FIGS. 30A, 30B, 30C, 30D, 31A, 31B, 31C, and 31D, a portion of the seventh filling insulating layer FDI7 that fills the seventh removal space RS7 may be removed.

Referring to FIGS. 32A, 32B, 32C, and 32D, a third gate dielectric layer 168 may be formed to cover the exposed surface of the seventh removal space RS7. The fourth separation insulating layer 162, the word line 160, and the fifth separation insulating layer 164 may be formed to cover the third gate dielectric layer 168 and may sequentially fill the seventh removal space RS7. The word line 160 may extend in the second horizontal direction (the Y direction). The fourth separation insulating layer 162 and the fifth separation insulating layer 164 may be respectively formed at opposite sides of the word line 160 and may extend in the second horizontal direction (the Y direction). For example, the third gate dielectric layer 168 may include at least one selected from the group consisting of a silicon oxide, a high-k dielectric material having a higher dielectric constant than silicon oxide, and a ferroelectric material. In one or more example embodiments, the first gate dielectric layer 132, the second gate dielectric layer 158, and the third gate dielectric layer 168 may include the same material. The first gate dielectric layer 132, the second gate dielectric layer 158, and the third gate dielectric layer 168 may be collectively referred to as gate dielectric layers. For example, the fourth separation insulating layer 162 and the fifth separation insulating layer 164 may include Si₃N₄ or SiOCN.

Referring to FIGS. 32A, 32B, 32C, 32D, 33A, 33B, 33C, and 33D, a second channel pattern 120 may be formed by removing a portion of the second channel layer 120P, which is exposed by the third isolation trench STR3. The second channel layer 120P may be divided into second channel patterns 120 by removing the portion of the second channel layer 120P that is exposed by the third isolation trench STR3.

Referring to FIGS. 34A, 34B, 34C, and 34D, the semiconductor device 1000 may be formed by filling the third isolation trench STR3 with the bit line 170. The bit line 170 may be formed to be in contact with the first channel pattern 110 and the second channel pattern 120. The fifth separation insulating layer 164 may be between the bit line 170 and the word line 160. In one or more example embodiments, before the bit line 170 is formed, the first silicide layer 114 in FIG. 3 may be formed in a portion of the first channel pattern 110. The bit line 170 may include metal, conductive metal nitride, a metal compound, conductive metal oxide, graphene, a carbon nanotube, or a combination thereof.

The semiconductor device 1000 may include the plurality of memory cells MC, each including the first channel pattern 110, the second channel pattern 120, the information storage element 140, the word line 160, the back-gate line 150, the bit line 170, and the plate electrode 180. The first gate dielectric layer 132 may be between the first channel pattern 110 and the information storage element 140. The second gate dielectric layer 158 may be between the second channel pattern 120 and the back-gate line 150. The third gate dielectric layer 168 may be between the first channel pattern 110 and the word line 160. The third gate dielectric layer 168 may also be between the second channel pattern 120 and the word line 160.

The first separation insulating layer 152, the back-gate line 150, and the second separation insulating layer 154 may each include a protrusion that is a portion which protrudes upwards and downwards to have an increased thickness and which corresponds to a space between adjacent second channel patterns 120 in the second horizontal direction (the Y direction). Although only the shape of the second separation insulating layer 154 is illustrated in FIG. 34C, it will be apparent to those skilled in the art that the first separation insulating layer 152 may include a protrusion that is a portion which protrudes upwards and downwards to have an increased thickness and which corresponds to a space between adjacent second channel patterns 120 in the second horizontal direction (the Y direction). The protrusion of each of the first separation insulating layer 152, the back-gate line 150, and the second separation insulating layer 154 may fill the space defined by the second gate dielectric layer 158. For example, a portion of the second gate dielectric layer 158 may be between second channel patterns 120 adjacent to each other in the second horizontal direction (the Y direction).

FIG. 35 illustrates a memory cell of a semiconductor device, according to one or more example embodiments.

Referring to FIG. 35, a semiconductor device 100a may include a first channel pattern 110a, a second channel pattern 120a, the information storage element 140, the word line 160, the back-gate line 150, the bit line 170, and the plate electrode 180, which are arranged on the substrate 102. The first channel pattern 110a, the second channel pattern 120a, the information storage element 140, the word line 160, the back-gate line 150, the bit line 170, and the plate electrode 180 may form a memory cell MC.

The first channel pattern 110a may extend in the first horizontal direction (the X direction). The first channel pattern 110a may be in contact with the bit line 170 and the plate electrode 180. In the first horizontal direction (the X direction), an end of the first channel pattern 110a may be in contact with the bit line 170, and an opposite end of the first channel pattern 110a may be in contact with the plate electrode 180. The first channel pattern 110a may include a monocrystalline semiconductor material or a polycrystalline semiconductor material.

In one or more example embodiments, the first channel pattern 110a may include a first channel region 112a, the first silicide layer 114, and the second silicide layer 116. The first channel region 112a may be arranged between the first silicide layer 114 and the second silicide layer 116. The first channel region 112a may include a first channel portion 112C, the first impurity region 112D1, and the second impurity region 112D2. The first channel portion 112C may be arranged between the first impurity region 112D1 and the second impurity region 112D2. The first impurity region 112D1 and the second impurity region 112D2 may each include an impurity. In one or more example embodiments, when the read transistor Rtr in FIG. 2 is an N-channel metal-oxide semiconductor (NMOS) transistor, the first impurity region 112D1 and the second impurity region 112D2 may each include an N-type impurity, such as P or As. In one or more example embodiments, when the read transistor Rtr in FIG. 2 is a P-channel metal-oxide semiconductor (PMOS) transistor, the first impurity region 112D1 and the second impurity region 112D2 may each include a P-type impurity, such as B or Al.

The second channel pattern 120a may extend in the first horizontal direction (the X direction). The second channel pattern 120a may be spaced apart from the first channel pattern 110a in the vertical direction (the Z direction). The second channel pattern 120a may be in contact with the bit line 170 and the information storage element 140. In the first horizontal direction (the X direction), an end of the second channel pattern 120a may be in contact with the bit line 170, and an opposite end of the second channel pattern 120a may be in contact with the information storage element 140. In one or more example embodiments, the second channel pattern 120a may include a second channel portion 122C and a channel contact 122D. The channel contact 122D may be in contact with the bit line 170. The channel contact 122D may be arranged between the second channel portion 122C and the bit line 170. The channel contact 122D may include doped polysilicon, metal, conductive metal nitride, a metal-semiconductor compound, a metal compound, conductive metal oxide, graphene, a carbon nanotube, or a combination thereof. The channel contact 122D may include an impurity region implanted with an impurity, such as H or O.

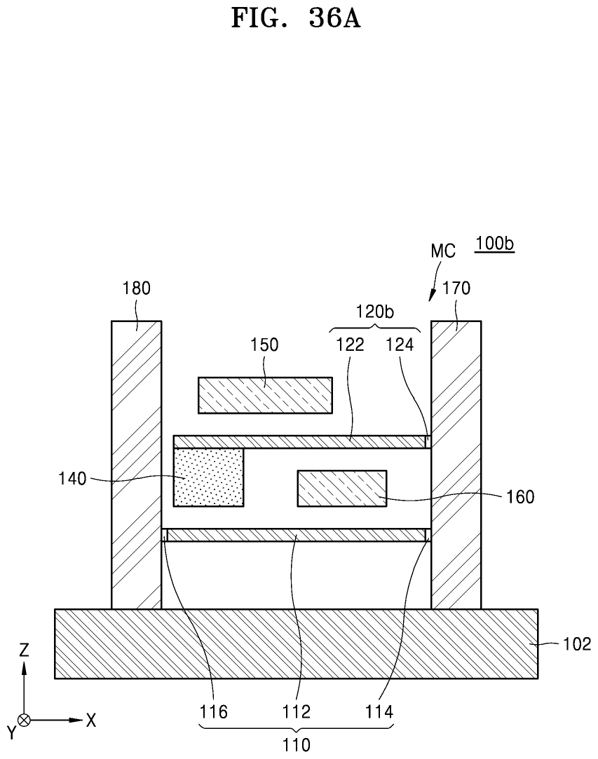

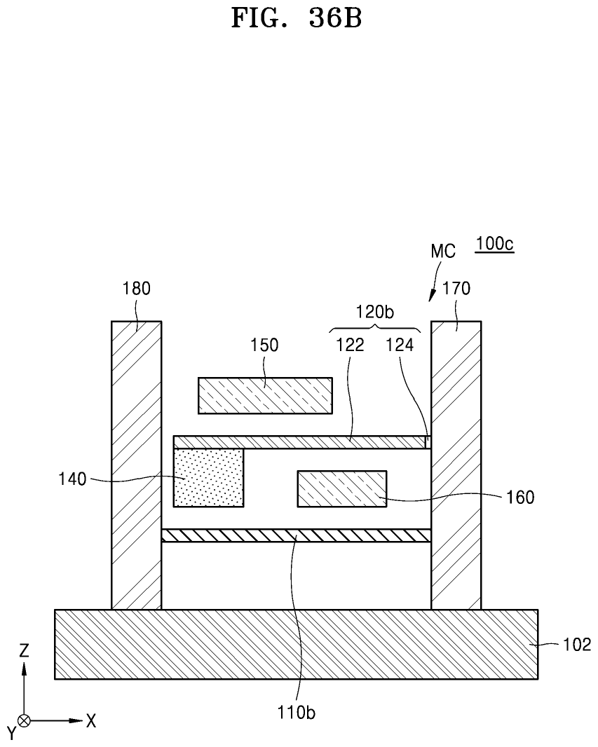

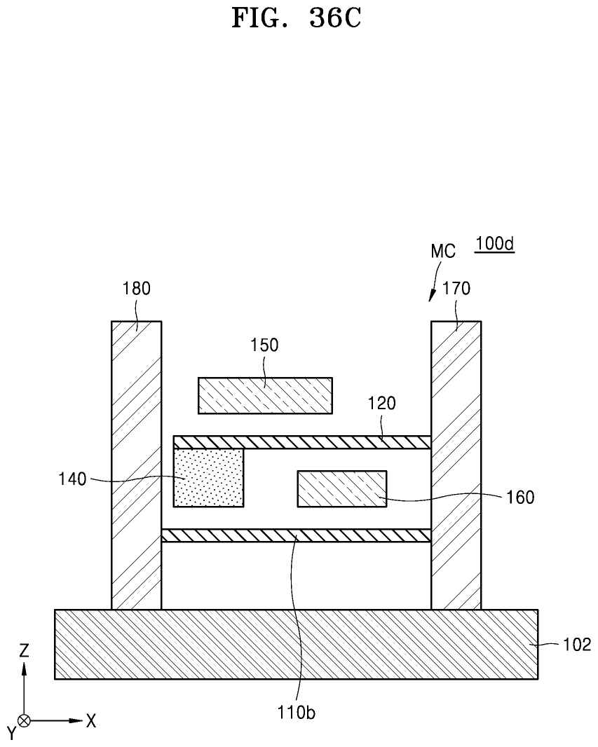

FIGS. 36A, 36B, and 36C illustrate memory cells of semiconductor devices, respectively, according to one or more example embodiments.

Referring to FIG. 36A, a semiconductor device 100b may include the first channel pattern 110, a second channel pattern 120b, the information storage element 140, the word line 160, the back-gate line 150, the bit line 170, and the plate electrode 180, which are arranged on the substrate 102. The first channel pattern 110, the second channel pattern 120b, the information storage element 140, the word line 160, the back-gate line 150, the bit line 170, and the plate electrode 180 may form a memory cell MC.

The second channel pattern 120b may include a monocrystalline semiconductor material or a polycrystalline semiconductor material. In one or more example embodiments, the second channel pattern 120b may include a monocrystalline semiconductor material such as Si or a polycrystalline semiconductor material such as polysilicon. In one or more example embodiments, the monocrystalline semiconductor material or the polycrystalline semiconductor material of the second channel pattern 120b may not contact either the bit line 170 or the plate electrode 180. For example, the second channel pattern 120b may include a second channel region 122, which includes a monocrystalline semiconductor material or a polycrystalline semiconductor material, and a third silicide layer 124. The third silicide layer 124 may be arranged between the second channel region 122 and the bit line 170. The third silicide layer 124 may be in contact with the bit line 170. The second channel region 122 may be spaced apart from the bit line 170 with the third silicide layer 124 therebetween.

Referring to FIG. 36B, a semiconductor device 100c may include a first channel pattern 110b, the second channel pattern 120b, the information storage element 140, the word line 160, the back-gate line 150, the bit line 170, and the plate electrode 180, which are arranged on the substrate 102. The first channel pattern 110b, the second channel pattern 120b, the information storage element 140, the word line 160, the back-gate line 150, the bit line 170, and the plate electrode 180 may form a memory cell MC.

The first channel pattern 110b may include an oxide semiconductor material or a 2D semiconductor material. The oxide semiconductor material or the 2D semiconductor material of the first channel pattern 110b may be in direct contact with the bit line 170 and the plate electrode 180. For example, the first channel pattern 110b may not include the first silicide layer 114 and the second silicide layer 116, which are respectively in direct contact with the bit line 170 and the plate electrode 180 that are included in the first channel pattern 110 in FIGS. 3 and 36A. In one or more example embodiments, the first channel pattern 110b may include an oxide semiconductor material such as IGZO. The second channel pattern 120b may include a monocrystalline semiconductor material such as Si or a polycrystalline semiconductor material such as polysilicon.

Referring to FIG. 36C, a semiconductor device 100d may include the first channel pattern 110b, the second channel pattern 120, the information storage element 140, the word line 160, the back-gate line 150, the bit line 170, and the plate electrode 180, which are arranged on the substrate 102. The first channel pattern 110b, the second channel pattern 120, the information storage element 140, the word line 160, the back-gate line 150, the bit line 170, and the plate electrode 180 may form a memory cell MC.

The first channel pattern 110b and the second channel pattern 120 may each include an oxide semiconductor material or a 2D semiconductor material. The oxide semiconductor material or the 2D semiconductor material of the first channel pattern 110b may be in direct contact with the bit line 170 and the plate electrode 180. The oxide semiconductor material or the 2D semiconductor material of the second channel pattern 120 may be in direct contact with the bit line 170. In one or more example embodiments, the first channel pattern 110b and the second channel pattern 120 may each include an oxide semiconductor material such as IGZO.

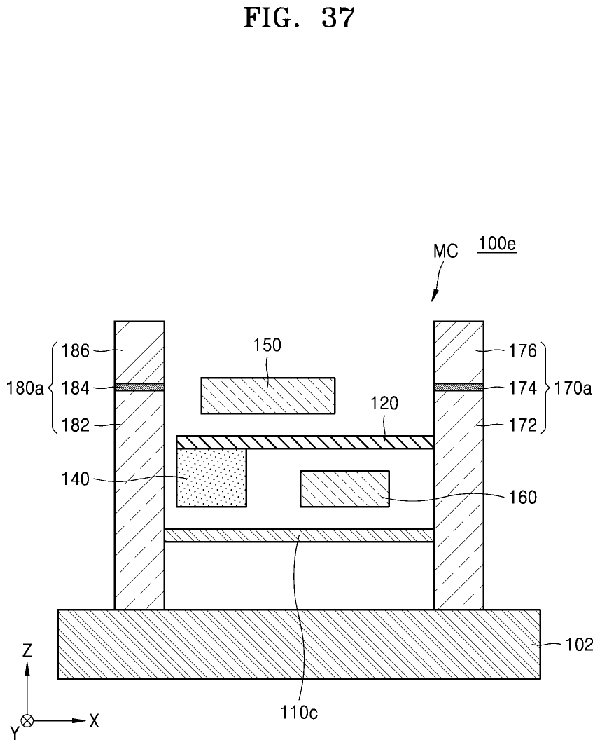

FIG. 37 illustrates a memory cell of a semiconductor device, according to one or more example embodiments.

Referring to FIG. 37, a semiconductor device 100e may include a first channel pattern 110c, the second channel pattern 120, the information storage element 140, the word line 160, the back-gate line 150, a bit line 170a, and a plate electrode 180a, which are arranged on the substrate 102. The first channel pattern 110c may correspond to the first channel region 112 in FIGS. 3 and 36A or may correspond to the first channel region 112a in FIG. 35. The first channel pattern 110c, the second channel pattern 120, the information storage element 140, the word line 160, the back-gate line 150, the bit line 170a, and the plate electrode 180a may form a memory cell MC.

The bit line 170a may have a stack structure of a first conductive semiconductor layer 172, a first silicide electrode layer 174, and a first metallic electrode layer 176. The plate electrode 180a may have a stack structure of a second conductive semiconductor layer 182, a second silicide electrode layer 184, and a second metallic electrode layer 186. For example, the first conductive semiconductor layer 172 and the second conductive semiconductor layer 182 may each include doped polysilicon. For example, the first metallic electrode layer 176 and the second metallic electrode layer 186 may each include metal or conductive metal nitride. In one or more example embodiments, the first metallic electrode layer 176 and the second metallic electrode layer 186 may each have a stack structure of a barrier layer, an electrode layer, and a capping layer. The first channel pattern 110c may be in contact with the first conductive semiconductor layer 172 and the second conductive semiconductor layer 182, and the second channel pattern 120 may be in contact with the first conductive semiconductor layer 172.

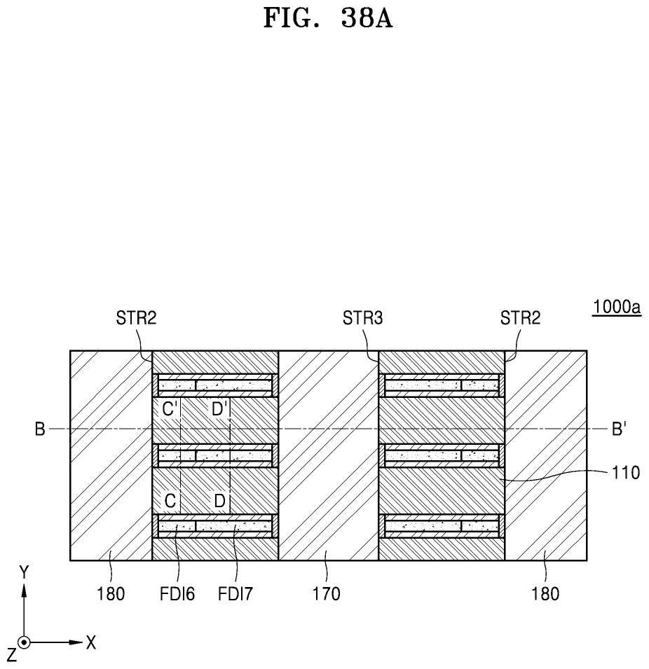

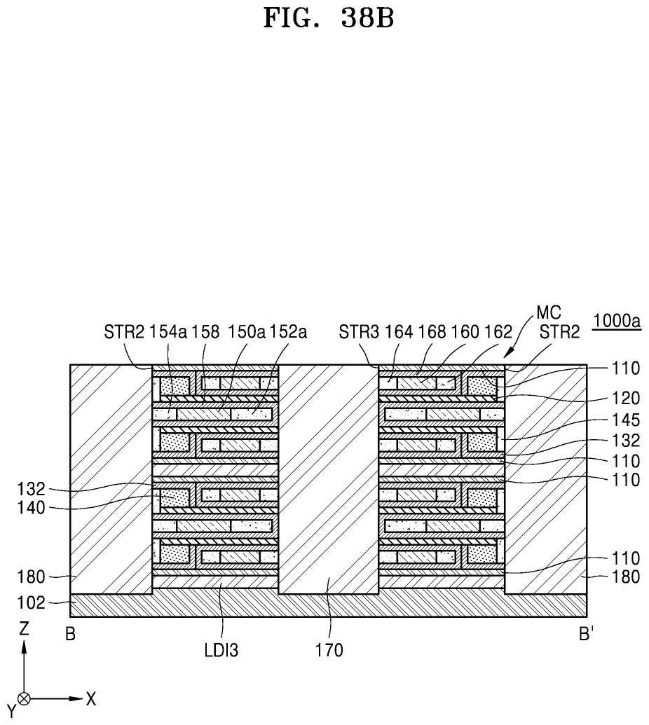

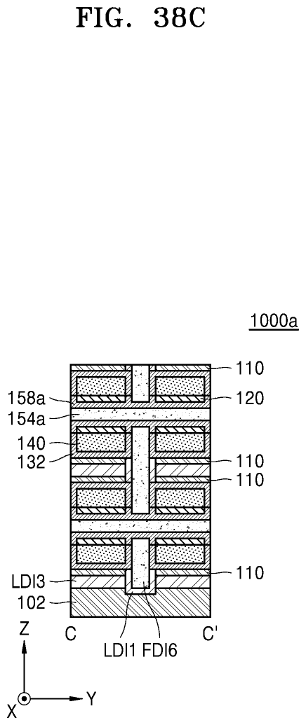

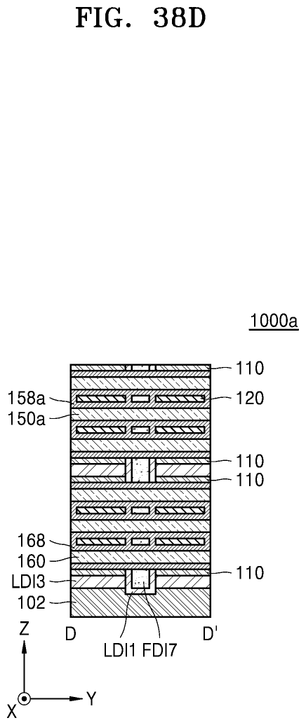

FIGS. 38A, 38B, 38C, and 38D are diagrams illustrating a semiconductor device according to one or more example embodiments. In detail, FIG. 38B is a cross-sectional view taken along line B-B′ in FIG. 38A, FIG. 38C is a cross-sectional view taken along line C-C′ in FIG. 38A, and FIG. 38D is a cross-sectional view taken along line D-D′ in FIG. 38A.

Referring to FIGS. 38A, 38B, 38C, and 38D, a semiconductor device 1000a may include a first separation insulating layer 152a, a back-gate line 150a, and a second separation insulating layer 154a. The first separation insulating layer 152a, the back-gate line 150a, and the second separation insulating layer 154a may extend in the second horizontal direction (the Y direction) with substantially the same thickness in the vertical direction (the Z direction). For example, the first separation insulating layer 152a, the back-gate line 150a, and the second separation insulating layer 154a may not include a protrusion of each of the first separation insulating layer 152, the back-gate line 150, and the second separation insulating layer 154 in FIGS. 34B, 34C, and 34D. For example, rather than a portion of the second gate dielectric layer 158, a portion of the sixth filling insulating layer FDI6 may be arranged between the second channel patterns 120 adjacent to each other in the second horizontal direction (the Y direction). Although only the shape of the second separation insulating layer 154a is illustrated in FIG. 38A, it will be apparent to those skilled in the art that the first separation insulating layer 152a may also extend in the second horizontal direction (the Y direction) with substantially the same thickness.

When, in the process of partially removing the sixth filling insulating layer FDI6 described above with reference to FIGS. 22A, 22B, 22C, and 22D, a portion of the sixth filling insulating layer FDI6 between second channel layers 120P adjacent to each other in the second horizontal direction (the Y direction) is left and the process of forming the first separation insulating layer 152, the back-gate line 150, and the second separation insulating layer 154, described above with reference to FIGS. 23A, 23B, 23C, and 23D, is then performed, the first separation insulating layer 152a, the back-gate line 150a, and the second separation insulating layer 154a may be formed.

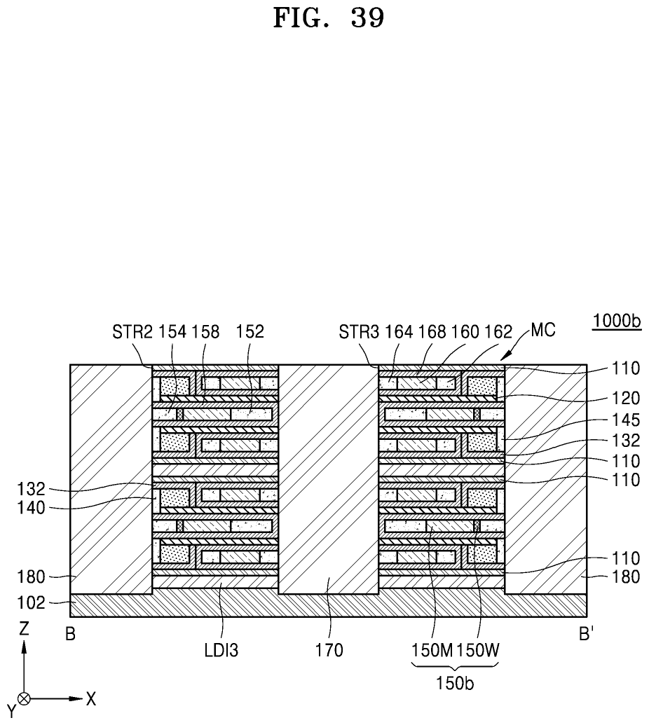

FIG. 39 is a diagram illustrating a semiconductor device according to one or more example embodiments.

Referring to FIG. 39, a semiconductor device 1000b may include a back-gate line 150b. The back-gate line 150b may include a main back-gate line 150M and a work function control layer 150W. In one or more example embodiments, the work function control layer 150W may be arranged between the main back-gate line 150M and the second separation insulating layer 154 but one or more example embodiments are not limited thereto. For example, the work function control layer 150W may be arranged between the main back-gate line 150M and the first separation insulating layer 152.

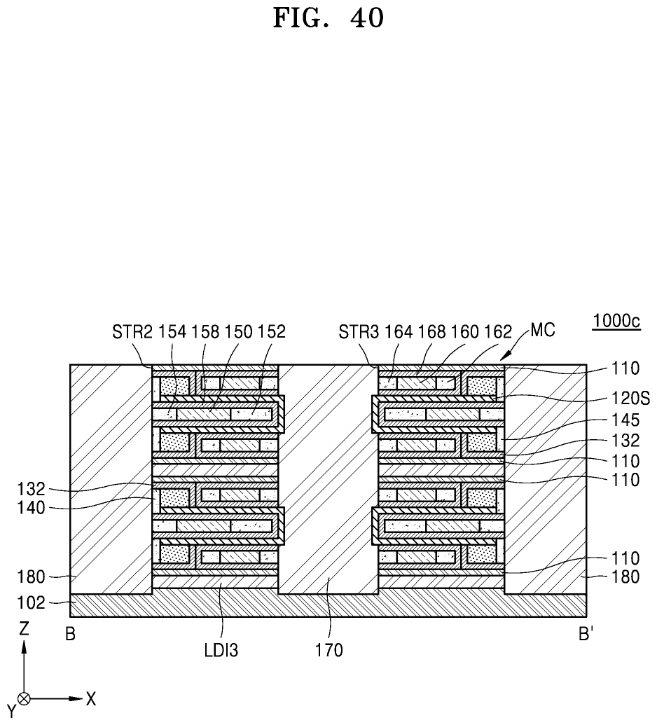

FIG. 40 is a diagram illustrating a semiconductor device according to one or more example embodiments.

Referring to FIG. 40, a semiconductor device 1000c may include the plurality of memory cells MC each including the first channel pattern 110, a second channel pattern 120S, the information storage element 140, the word line 160, the back-gate line 150, the bit line 170, and the plate electrode 180.

Two memory cells MC adjacent to each other in the vertical direction (the Z direction) may share the second channel pattern 120S. For example, in a YZ plane formed by the second horizontal direction (the Y direction) and the vertical direction (the Z direction), the second channel pattern 120S may have a U-shape rotated 90 degrees. The second channel pattern 120S may be formed by omitting the process of removing the exposed portion of the second channel layer 120P in the third isolation trench STR3, which has been described with reference to FIGS. 32A, 32B, 32C, 32D, 33A, 33B, 33C, and 33D above. For example, the second channel pattern 120S may correspond to the second channel layer 120P in FIGS. 32A, 32B, 32C, 32D. The second channel pattern 120S may include a pair of channel portions extending in the second horizontal direction (the Y direction) and a connection portion, which extends in the vertical direction (the Z direction) and connects the channel portions to each other. The channel portions of the second channel pattern 120S may not overlap the bit line 170 in the vertical direction (the Z direction). For example, each of the channel portions of the second channel pattern 120S may correspond to the second channel pattern 120 in FIGS. 34B, 34C, and 34D. The connection portion of the second channel pattern 120S may overlap the bit line 170 in the vertical direction (the Z direction). For example, the connection portion of the second channel pattern 120S may correspond to the removed portion of the second channel layer 120P, which has been described with reference to FIGS. 32A, 32B, 32C, 32D, 33A, 33B, 33C, and 33D.

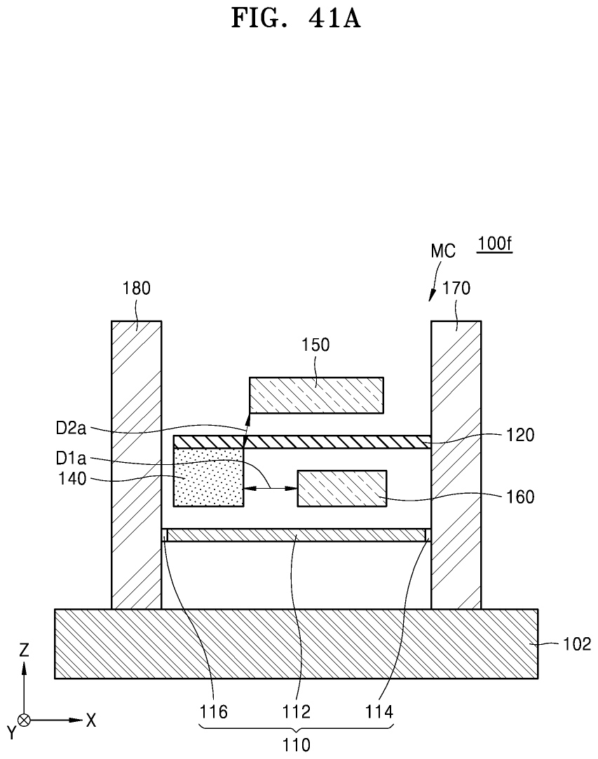

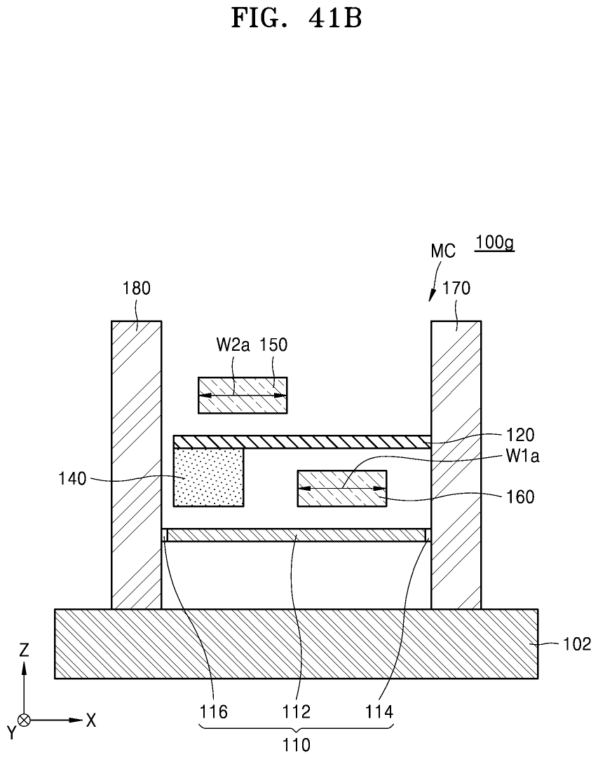

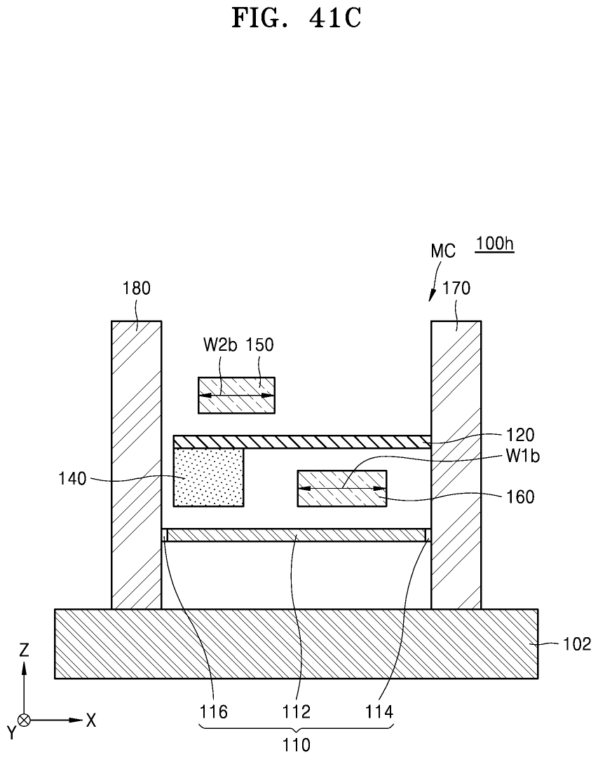

FIGS. 41A, 41B, and 41C illustrate memory cells of semiconductor devices, respectively, according to one or more example embodiments.

Referring to FIG. 41A, a semiconductor device 100f may include the first channel pattern 110, the second channel pattern 120, the information storage element 140, the word line 160, the back-gate line 150, the bit line 170, and the plate electrode 180, which are arranged on the substrate 102. The first channel pattern 110, the second channel pattern 120, the information storage element 140, the word line 160, the back-gate line 150, the bit line 170, and the plate electrode 180 may form a memory cell MC.

The back-gate line 150 may be adjacent to the information storage element 140 but may not overlap the information storage element 140 in the vertical direction (the Z direction). The information storage element 140 may be spaced apart from the word line 160 by a first separation distance D1a and from the back-gate line 150 by a second separation distance D2a. The second separation distance D2a may be less than the first separation distance D1a.

Referring to FIG. 41B, a semiconductor device 100g may include the first channel pattern 110, the second channel pattern 120, the information storage element 140, the word line 160, the back-gate line 150, the bit line 170, and the plate electrode 180, which are arranged on the substrate 102. The first channel pattern 110, the second channel pattern 120, the information storage element 140, the word line 160, the back-gate line 150, the bit line 170, and the plate electrode 180 may form a memory cell MC.

In the first horizontal direction (the X direction), the word line 160 may have a first horizontal width W1a, and the back-gate line 150 may have a second horizontal width W2a. In one or more example embodiments, the first horizontal width W1a may be substantially the same as the second horizontal width W2a. In one or more example embodiments, the back-gate line 150 may overlap the information storage element 140 in the vertical direction (the Z direction), but one or more example embodiments are not limited thereto. In one or more example embodiments, the back-gate line 150 may not overlap the word line 160 in the vertical direction (the Z direction), but one or more example embodiments are not limited thereto.

Referring to FIG. 41C, a semiconductor device 100h may include the first channel pattern 110, the second channel pattern 120, the information storage element 140, the word line 160, the back-gate line 150, the bit line 170, and the plate electrode 180, which are arranged on the substrate 102. The first channel pattern 110, the second channel pattern 120, the information storage element 140, the word line 160, the back-gate line 150, the bit line 170, and the plate electrode 180 may form a memory cell MC.

In the first horizontal direction (the X direction), the word line 160 may have a first horizontal width W1b, and the back-gate line 150 may have a second horizontal width W2b. In one or more example embodiments, the first horizontal width W1b may be greater than the second horizontal width W2b.

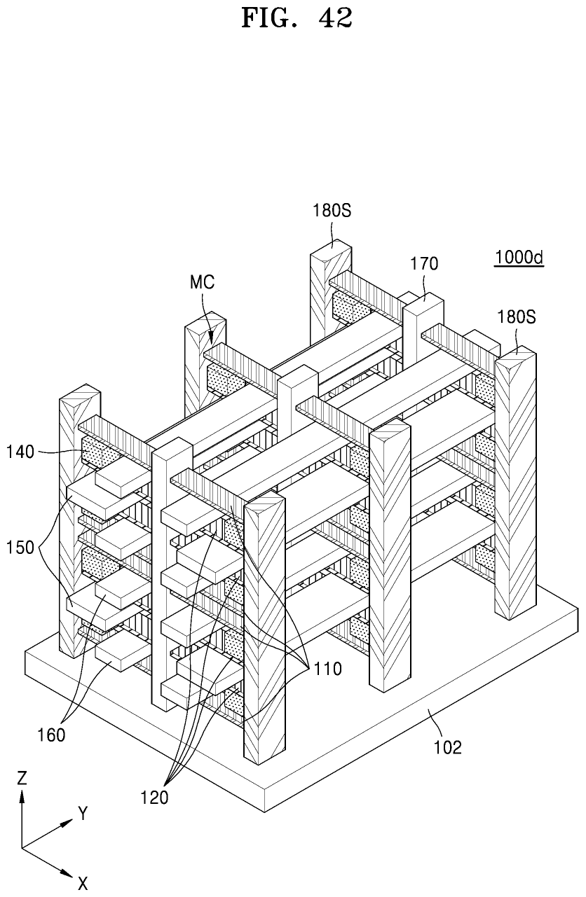

FIG. 42 is a conceptual perspective view of a semiconductor device including a plurality of memory cells, according to one or more example embodiments.

Referring to FIG. 42, a semiconductor device 1000d may include a plurality of plate electrodes 180S each being in contact with the first channel pattern 110. The plate electrodes 180S may extend in the vertical direction (the Z direction) and may be arranged in rows in the second horizontal direction (the Y direction). In one or more example embodiments, the plate electrodes 180S may extend in the vertical direction (the Z direction) and may be spaced apart from one another in the first horizontal direction (the X direction) and the second horizontal direction (the Y direction). Each of the plate electrodes 180S may be in contact with first channel patterns 110 which are arranged in a row in the vertical direction (the Z direction). In one or more example embodiments, the plate electrodes 180S may be electrically grounded.

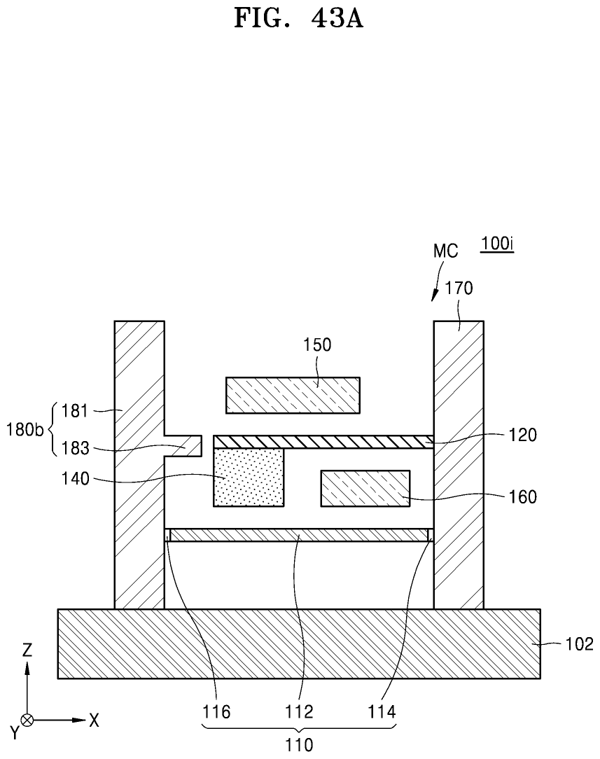

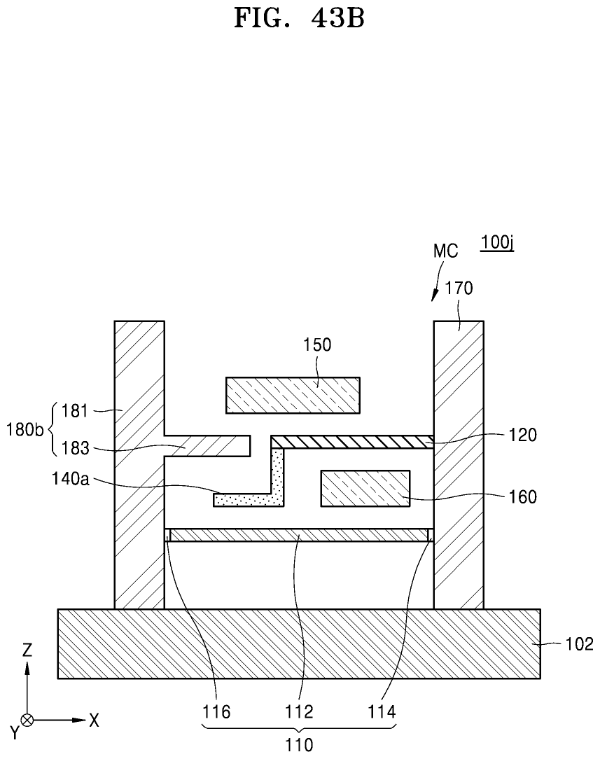

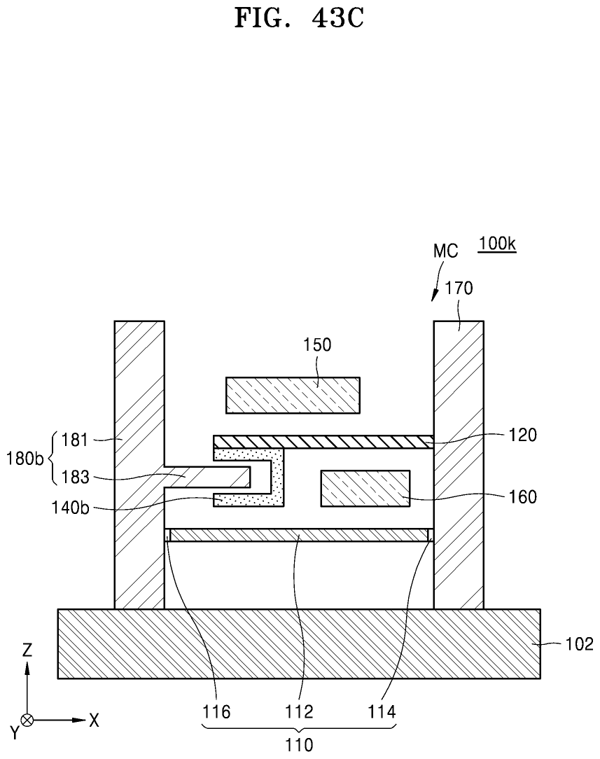

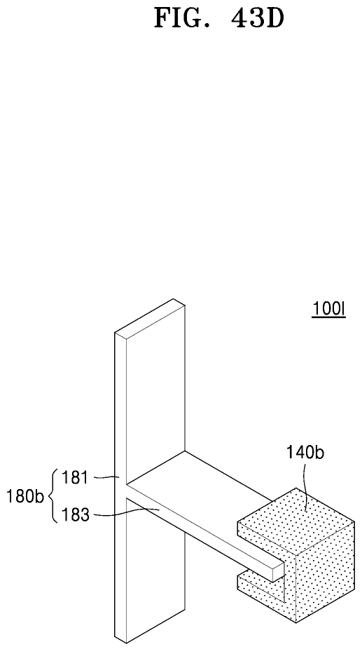

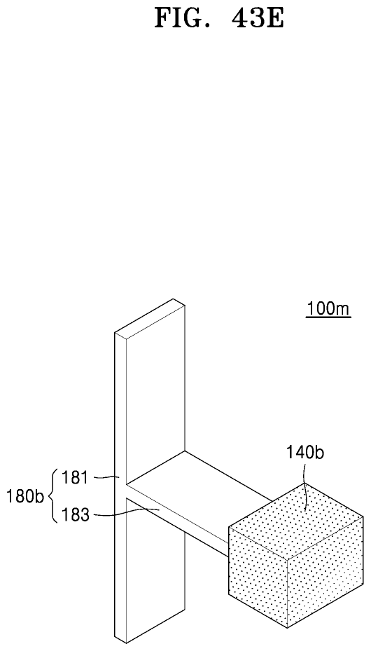

FIGS. 43A, 43B, 43C, 43D, and 43E illustrate memory cells of semiconductor devices, respectively, according to one or more example embodiments.

Referring to FIG. 43A, a semiconductor device 100i may include a plate electrode 180b. In one or more example embodiments, the plate electrode 180b may include a plate body 181 and a protrusion 183 which extends from the plate body 181 toward the information storage element 140. The plate body 181 may correspond to the plate electrode 180 in FIG. 5 or the plate electrode 180S in FIG. 42. The protrusion 183 may extend from the plate body 181 in the first horizontal direction (the X direction).

Because the plate electrode 180b includes the protrusion 183 extending toward the information storage element 140, the distance between the information storage element 140 and the plate electrode 180b may be reduced, and the information storage element 140 may be prevented from being electrically coupled to the word line 160 due to the plate electrode 180b electrically grounded.

Referring to FIG. 43B, the plate electrode 180b of a semiconductor device 100j may include the protrusion 183 extending toward an information storage element 140a. In one or more example embodiments, the information storage element 140a may have a plurality of side surfaces facing the protrusion 183. For example, a portion of the information storage element 140a may overlap the protrusion 183 in the first horizontal direction (the X direction), and another portion of the information storage element 140a may overlap the protrusion 183 in the vertical direction (the Z direction).

Referring to FIG. 43C, the plate electrode 180b of a semiconductor device 100k may include the protrusion 183 extending toward an information storage element 140b. In one or more example embodiments, the information storage element 140b may have a plurality of side surfaces facing the protrusion 183. For example, the information storage element 140b may include a side surface overlapping the protrusion 183 in the first horizontal direction (the X direction) and side surfaces overlapping the protrusion 183 in the vertical direction (the Z direction). At least three side surfaces of the information storage element 140b may overlap the protrusion 183. For example, in a YZ plane formed by the second horizontal direction (the Y direction) and the vertical direction (the Z direction), the information storage element 140b may have a U-shape rotated 90 degrees. The information storage element 140b may include a pair of horizontal extension portions extending in the second horizontal direction (the Y direction) and a vertical extension portion, which extends in the vertical direction (the Z direction) and connects the pair of horizontal extension portions to each other. One of the horizontal extension portions of the information storage element 140b may be adjacent to, be spaced apart from, and at least partially overlap, the top surface of the protrusion 183 in the vertical direction (the Z direction), and the other horizontal extension portion of the information storage element 140b may be adjacent to, be spaced apart from, and at least partially overlap, the bottom surface of the protrusion 183 in the vertical direction (the Z direction). The vertical extension portion of the information storage element 140b may be adjacent to, be spaced apart from, and least partially overlap, a side surface of the protrusion 183 in the first horizontal direction (the X direction).

Referring to FIG. 43D, the plate electrode 180b of a semiconductor device 100l may include the protrusion 183 extending toward the information storage element 140b. At least three side surfaces of the information storage element 140b may overlap the protrusion 183. In one or more example embodiments, the information storage element 140b may have a U-shape, and three side surfaces of the information storage element 140b may overlap the protrusion 183. For example, the information storage element 140b may include a portion which is adjacent to, is spaced apart from, and at least partially overlaps, the top surface of the protrusion 183 in the vertical direction (the Z direction), a portion which is adjacent to, is spaced apart from, and at least partially overlaps, the bottom surface of the protrusion 183 in the vertical direction (the Z direction), and a portion which is adjacent to, is spaced apart from, and at least partially overlaps, a side surface of the protrusion 183 in the first horizontal direction (the X direction).

Referring to FIG. 43E, the plate electrode 180b of a semiconductor device 100m may include the protrusion 183 extending toward the information storage element 140b. At least three side surfaces of the information storage element 140b may overlap the protrusion 183. For example, the information storage element 140b may surround the protrusion 183. In one or more example embodiments, five side surfaces of the information storage element 140b may overlap the protrusion 183. For example, the information storage element 140b may include a portion which is adjacent to, is spaced apart from, and at least partially overlaps, the top surface of the protrusion 183 in the vertical direction (the Z direction), a portion which is adjacent to, is spaced apart from, and at least partially overlaps, the bottom surface of the protrusion 183 in the vertical direction (the Z direction), a portion which is adjacent to, is spaced apart from and at least partially overlaps, a side surface of the protrusion 183 in the first horizontal direction (the X direction), a portion which is adjacent to, is spaced apart from, and at least partially overlaps, a side surface of the protrusion 183 in the second horizontal direction (the Y direction), and a portion which is adjacent to, is spaced apart from, and at least partially overlaps, an opposite side surface of the protrusion 183 in the second horizontal direction (the Y direction).

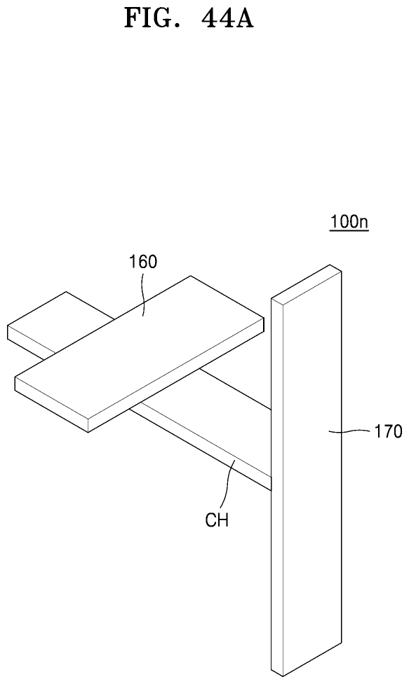

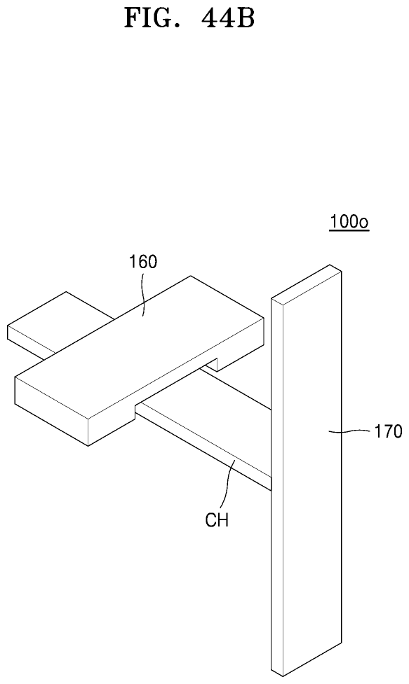

FIGS. 44A and 44B illustrate word lines of semiconductor devices, respectively, according to one or more example embodiments.

Referring to FIG. 44A, a semiconductor device 100n may include the bit line 170 in contact with a channel pattern CH and the word line 160 adjacent to the channel pattern CH. The channel pattern CH may correspond to the first channel pattern 110, 110a, 110b, or 110c or the second channel pattern 120, 120a, or 120b, which have been described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C. The word line 160 may have a side surface facing the channel pattern CH. For example, the word line 160 may overlap a side surface of the channel pattern CH.

Referring to FIG. 44B, a semiconductor device 100o may include the bit line 170 in contact with the channel pattern CH and the word line 160 adjacent to the channel pattern CH. The channel pattern CH may correspond to the first channel pattern 110, 110a, 110b, or 110c or the second channel pattern 120, 120a, or 120b, which have been described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C. The word line 160 may have a plurality of side surfaces facing the channel pattern CH. For example, the word line 160 may overlap three side surfaces of the channel pattern CH. The word line 160 may be spaced apart from the channel pattern CH. The word line 160 may include a portion adjacent to the top surface of the channel pattern CH, a portion adjacent to a side surface of the channel pattern CH, and a portion adjacent to an opposite side surface of the channel pattern CH. The thickness of the portion of the word line 160, which is adjacent to the top surface of the channel pattern CH, may be less than the thickness of each of the portions of the word line 160, which are respectively adjacent to opposite side surfaces of the channel pattern CH.

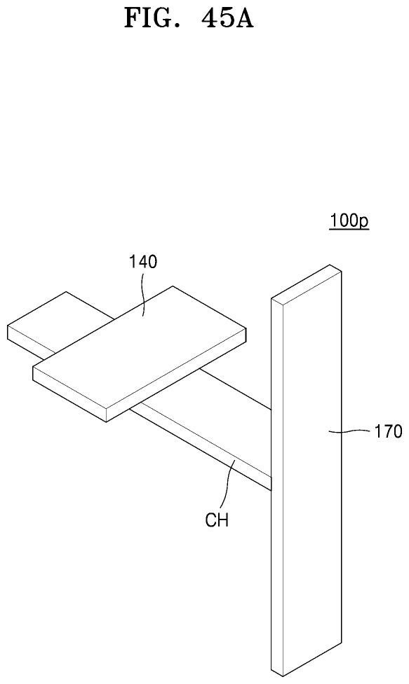

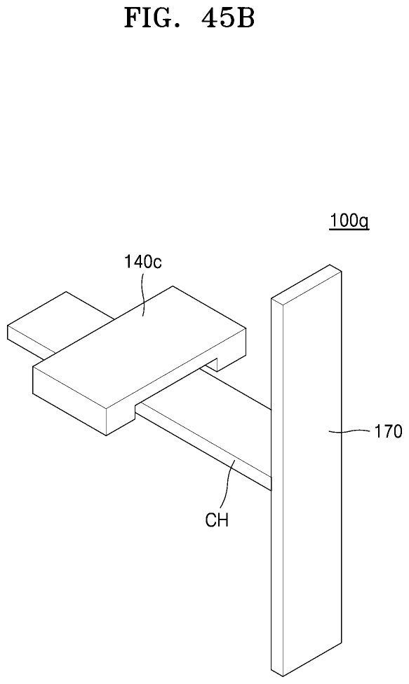

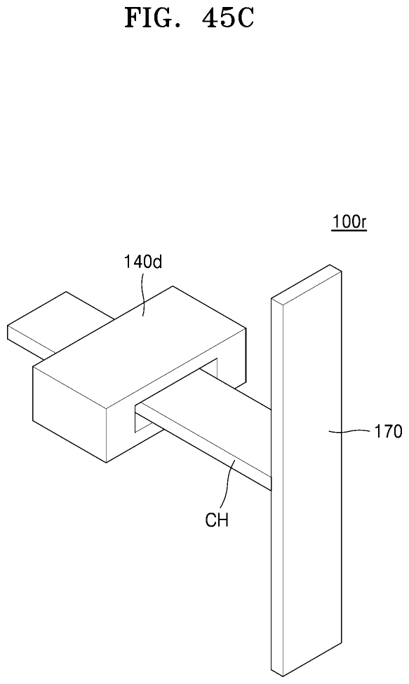

FIGS. 45A, 45B, and 45C illustrate information storage elements of semiconductor devices, respectively, according to one or more example embodiments.

Referring to FIG. 45A, a semiconductor device 100p may include the bit line 170 in contact with the channel pattern CH and the information storage element 140 adjacent to the channel pattern CH. The channel pattern CH may correspond to the first channel pattern 110, 110a, 110b, or 110c or the second channel pattern 120, 120a, or 120b, which have been described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C. The channel pattern CH may have a side facing the information storage element 140. For example, the channel pattern CH may overlap a side of the information storage element 140.

Referring to FIG. 45B, a semiconductor device 100q may include the bit line 170 in contact with the channel pattern CH and an information storage element 140c adjacent to the channel pattern CH. The channel pattern CH may correspond to the first channel pattern 110, 110a, 110b, or 110c or the second channel pattern 120, 120a, or 120b, which have been described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C. The channel pattern CH may have a plurality of sides facing the information storage element 140c. For example, the channel pattern CH may overlap three sides of the information storage element 140c. When the channel pattern CH corresponds to the first channel pattern 110, 110a, 110b, or 110c described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C, the information storage element 140c may be spaced apart from the channel pattern CH. When the channel pattern CH corresponds to the second channel pattern 120, 120a, or 120b, described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C, the information storage element 140c may be in contact with the channel pattern CH. The information storage element 140c may include a portion adjacent to the top surface of the channel pattern CH, a portion adjacent to a side surface of the channel pattern CH, and a portion adjacent to an opposite side surface of the channel pattern CH. The thickness of the portion of the information storage element 140c, which is adjacent to the top surface of the channel pattern CH, may be less than the thickness of each of the portions of the information storage element 140c, which are respectively adjacent to opposite side surfaces of the channel pattern CH.

Referring to FIG. 45C, a semiconductor device 100r may include the bit line 170 in contact with the channel pattern CH and an information storage element 140d adjacent to the channel pattern CH. The channel pattern CH may correspond to the first channel pattern 110, 110a, 110b, or 110c or the second channel pattern 120, 120a, or 120b, which have been described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C. The channel pattern CH may have a plurality of sides facing the information storage element 140d. For example, the channel pattern CH may surround the information storage element 140d and may overlap four sides of the information storage element 140d. When the channel pattern CH corresponds to the first channel pattern 110, 110a, 110b, or 110c, described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C, the information storage element 140d may be spaced apart from the channel pattern CH. When the channel pattern CH corresponds to the second channel pattern 120, 120a, or 120b, described above with reference to FIGS. 3-5, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, 33D, 34A, 34B, 34C, 34D, 35, 36A, 36B, 36C, 37, 38A, 38B, 38C, 38D, 39, 40, 41A, 41B, 41C, 42, 43A, 43B, and 43C, the information storage element 140d may be in contact with the channel pattern CH. The information storage element 140d may include a portion adjacent to the top surface of the channel pattern CH, a portion adjacent to the bottom surface of the channel pattern CH, a portion adjacent to a side surface of the channel pattern CH, and a portion adjacent to an opposite side surface of the channel pattern CH. The thickness of each of the portions of the information storage element 140d, which are respectively adjacent to the top and bottom surfaces of the channel pattern CH, may be less than the thickness of each of the portions of the information storage element 140d, which are respectively adjacent to opposite side surfaces of the channel pattern CH.

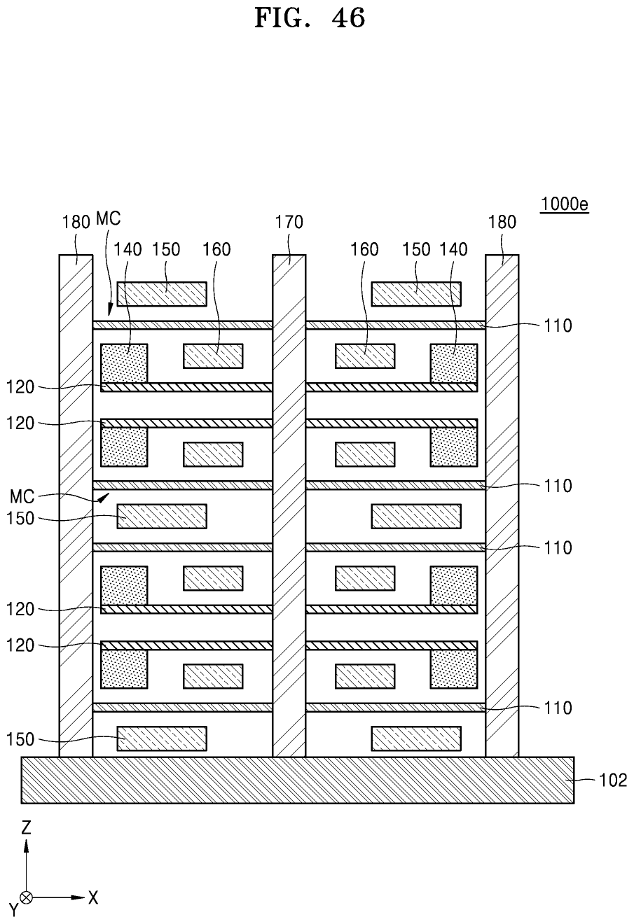

FIG. 46 illustrates a semiconductor device including a plurality of memory cells, according to one or more example embodiments.

Referring to FIG. 46, a semiconductor device 1000e may include the plurality of memory cells MC each including the first channel pattern 110, the second channel pattern 120, the information storage element 140, the word line 160, the back-gate line 150, the bit line 170, and the plate electrode 180.

The word line 160 may be adjacent to the first channel pattern 110 and the second channel pattern 120. The back-gate line 150 may be adjacent to the information storage element 140. In one or more example embodiments, the back-gate line 150 may be closer to the first channel pattern 110 than to the second channel pattern 120. For example, the back-gate line 150 may be arranged between two first channel patterns 110 respectively included in two memory cells MC adjacent to each other in the vertical direction (the Z direction) to be spaced apart from the two first channel patterns 110. For example, two word lines 160 may be respectively arranged at opposite sides of the back-gate line 150 in the vertical direction (the Z direction), and the back-gate line 150 and another word line 160 may be respectively arranged at an opposite sides of one of the two word lines 160 in the vertical direction (the Z direction).

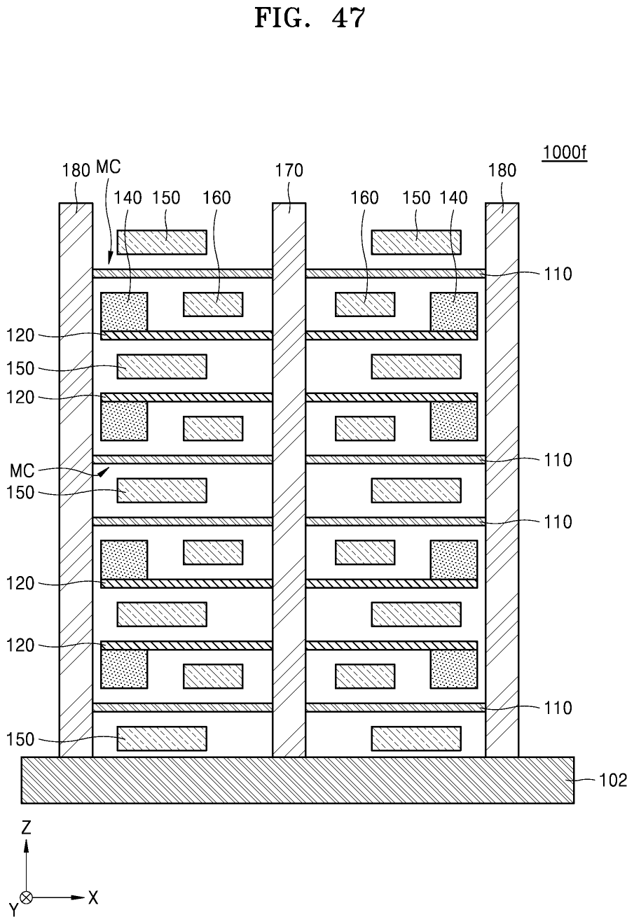

FIG. 47 illustrates a semiconductor device including a plurality of memory cells, according to one or more example embodiments.

Referring to FIG. 47, a semiconductor device 1000f may include the plurality of memory cells MC each including the first channel pattern 110, the second channel pattern 120, the information storage element 140, the word line 160, the back-gate line 150, the bit line 170, and the plate electrode 180.

The word line 160 may be adjacent to the first channel pattern 110 and the second channel pattern 120. The back-gate line 150 may be adjacent to the information storage element 140. In one or more example embodiments, the back-gate line 150 may be adjacent to either the first channel pattern 110 or the second channel pattern 120. For example, the back-gate line 150 may be arranged between two first channel patterns 110 respectively included in two memory cells MC adjacent to each other in the vertical direction (the Z direction) to be spaced apart from the two first channel patterns 110 and between two second channel patterns 120 respectively included in the two memory cells MC adjacent to each other in the vertical direction (the Z direction) to be spaced apart from the two second channel patterns 120. For example, two word lines 160 may be respectively arranged at opposite sides of the back-gate line 150 in the vertical direction (the Z direction), and back-gate lines 150 may be respectively arranged at an opposite sides of one word line 160 in the vertical direction (the Z direction).

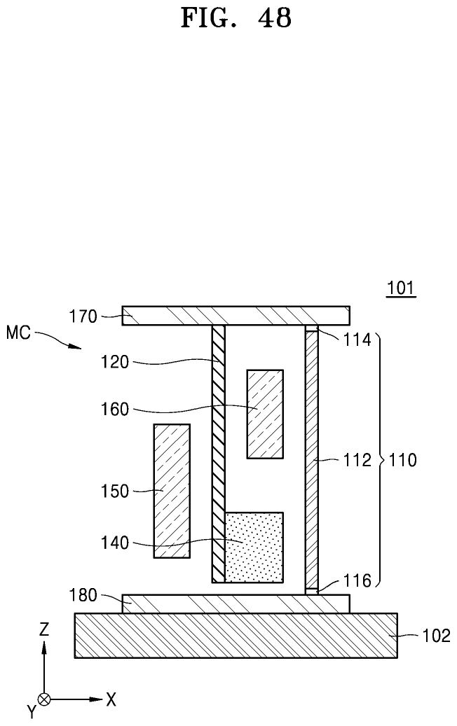

FIG. 48 illustrates a memory cell of a semiconductor device, according to one or more example embodiments.

Referring to FIG. 48, a semiconductor device 101 may include the first channel pattern 110, the second channel pattern 120, the information storage element 140, the word line 160, the back-gate line 150, the bit line 170, and the plate electrode 180, which are arranged on the substrate 102. The first channel pattern 110, the second channel pattern 120, the information storage element 140, the word line 160, the back-gate line 150, the bit line 170, and the plate electrode 180 may form a memory cell MC. In one or more example embodiments, the plate electrode 180 may be arranged on the substrate 102, and the bit line 170 may be arranged above the plate electrode 180 to be spaced apart from the plate electrode 180 in the vertical direction (the Z direction). The first channel pattern 110, the second channel pattern 120, the information storage element 140, the word line 160, and the back-gate line 150 may be arranged between the bit line 170 and the plate electrode 180.

The first channel pattern 110 may extend in the vertical direction (the Z direction). The first channel pattern 110 may be in contact with the bit line 170 and the plate electrode 180. In the vertical direction (the Z direction), an end of the first channel pattern 110 may be in contact with the bit line 170, and an opposite end of the first channel pattern 110 may be in contact with the plate electrode 180. In one or more example embodiments, the first channel pattern 110 may include the first channel region 112, the first silicide layer 114, and the second silicide layer 116. The first silicide layer 114 may be in contact with the bit line 170, and the second silicide layer 116 may be spaced apart from the first silicide layer 114 in the vertical direction (the Z direction) and may be in contact with the plate electrode 180.

The second channel pattern 120 may extend in the vertical direction (the Z direction). The second channel pattern 120 may be spaced apart from the first channel pattern 110 in the first horizontal direction (the X direction). The second channel pattern 120 may be in contact with the bit line 170 and the information storage element 140. In the vertical direction (the Z direction), an end of the second channel pattern 120 may be in contact with the bit line 170, and an opposite end of the second channel pattern 120 may be in contact with the information storage element 140.

The information storage element 140 may be in contact with, and electrically connected to, the second channel pattern 120. For example, at least a portion of the information storage element 140 may overlap the second channel pattern 120 in the first horizontal direction (the X direction). The information storage element 140 may be adjacent to the first channel pattern 110. For example, at least a portion of the information storage element 140 may be adjacent to the first channel pattern 110 and may overlap the first channel pattern 110 in the first horizontal direction (the X direction). The width of the information storage element 140 in the first horizontal direction (the X direction) may be greater than the width of the second channel pattern 120 in the first horizontal direction (the X direction). The information storage element 140 may be spaced apart from the substrate 102 and the plate electrode 180 in the vertical direction (the Z direction).

The word line 160 may be adjacent to both the first channel pattern 110 and the second channel pattern 120. For example, at least a portion of the word line 160 may extend in the second horizontal direction (the Y direction) between the first channel pattern 110 and the second channel pattern 120. At least a portion of the word line 160 may overlap the first channel pattern 110 in the first horizontal direction (the X direction), and at least a portion of the word line 160 may overlap the second channel pattern 120 in the first horizontal direction (the X direction).

The back-gate line 150 may be adjacent to the information storage element 140. The back-gate line 150 may be adjacent to the first channel pattern 110 and/or the second channel pattern 120. In one or more example embodiments, the back-gate line 150 may be adjacent to the second channel pattern 120. For example, the back-gate line 150 may be adjacent to the second channel pattern 120 and spaced apart from the second channel pattern 120 in the first horizontal direction (the X direction). For example, at least a portion of the back-gate line 150 may be adjacent to the second channel pattern 120 and may extend in the second horizontal direction (the Y direction). At least a portion of the back-gate line 150 may overlap the second channel pattern 120 in the first horizontal direction (the X direction). In one or more example embodiments, at least a portion of the back-gate line 150 may overlap the information storage element 140 in the first horizontal direction (the X direction), but one or more example embodiments are not limited thereto. For example, the back-gate line 150 may be adjacent to the information storage element 140 and may not overlap the information storage element 140 in the first horizontal direction (the X direction).

The bit line 170 may extend in the first horizontal direction (the X direction). The bit line 170 may be in contact with, and electrically connected to, the first channel pattern 110 and the second channel pattern 120. For example, the bit line 170 may be in contact with an end of the first channel pattern 110 and an end of the second channel pattern 120 in the vertical direction (the Z direction).

The plate electrode 180 may be in contact with the first channel pattern 110. The plate electrode 180 may be in contact with an opposite end of the first channel pattern 110 in the vertical direction (the Z direction). The plate electrode 180 may be spaced apart from the second channel pattern 120. For example, in one or more example embodiments, the plate electrode 180 may be electrically grounded.

The vertical direction (the Z direction), the first horizontal direction (the X direction), and the second horizontal direction (the Y direction) may be respectively referred to as the first direction, the second direction, and the third direction, which are orthogonal with one another.

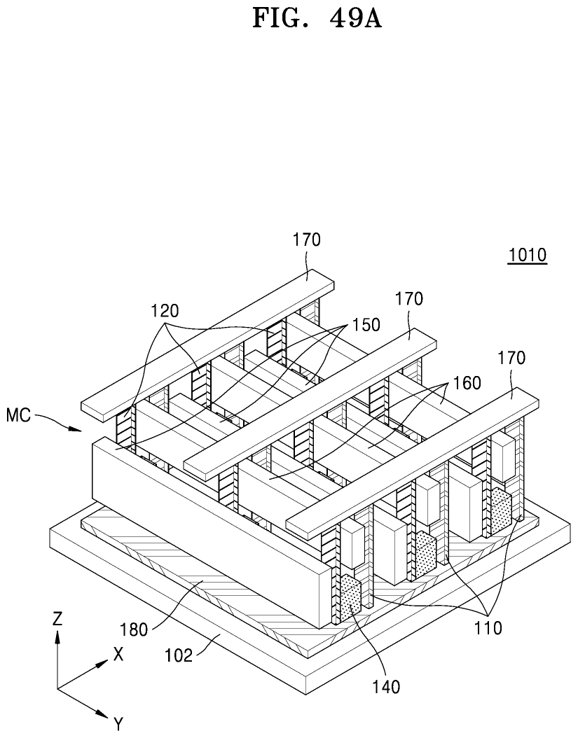

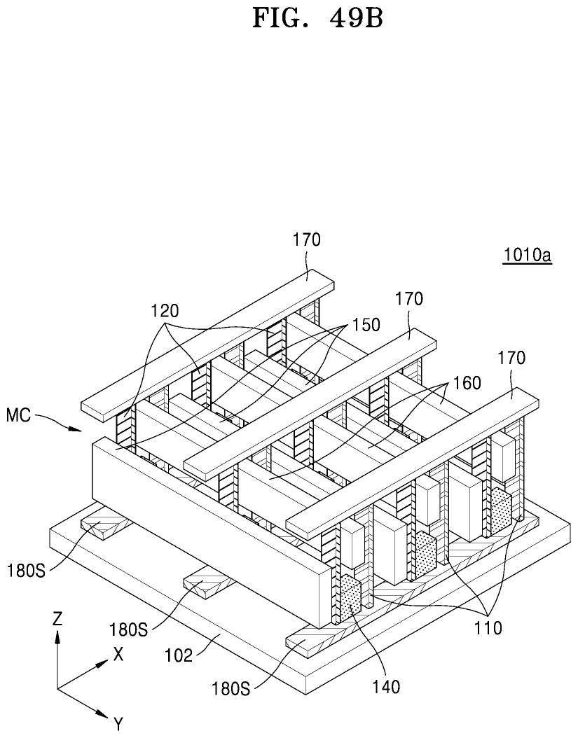

FIGS. 49A and 49B are respectively conceptual perspective views of semiconductor devices including a plurality of memory cells, according to one or more example embodiments.

Referring to FIG. 49A, a semiconductor device 1010 may include the plurality of memory cells MC each including the first channel pattern 110, the second channel pattern 120, the information storage element 140, the word line 160, the back-gate line 150, the bit line 170, and the plate electrode 180. The memory cells MC may be arranged in rows in the first horizontal direction (the X direction) and the second horizontal direction (the Y direction).

The plurality of first channel patterns 110 may extend in the vertical direction (the Z direction) and may be spaced apart from one another in the first horizontal direction (the X direction) and the second horizontal direction (the Y direction). The plurality of second channel patterns 120 may extend in the vertical direction (the Z direction) and may be spaced apart from one another in the first horizontal direction (the X direction) and the second horizontal direction (the Y direction). A second channel pattern 120 may be spaced apart from a first channel pattern 110 in the first horizontal direction (the X direction). The second channel pattern 120 may be in contact with the bit line 170 and the information storage element 140. The information storage element 140 may be in contact with and electrically connected to the second channel pattern 120. The information storage element 140 may be adjacent to, and spaced apart from, the first channel pattern 110.

The word line 160 may be adjacent to both the first channel pattern 110 and the second channel pattern 120. The word line 160 may be arranged between the first channel pattern 110 and the second channel pattern 120, which are included in one memory cell MC, in the first horizontal direction (the X direction) to be spaced apart from the first channel pattern 110 and the second channel pattern 120, which are included in the memory cell MC.

The back-gate line 150 may be adjacent to the information storage element 140. In one or more example embodiments, the back-gate line 150 may be adjacent to the second channel pattern 120. For example, the back-gate line 150 may be arranged to be adjacent to the second channel pattern 120 and spaced apart from the second channel pattern 120 in the first horizontal direction (the X direction). For example, at least a portion of the back-gate line 150 may be adjacent to the second channel pattern 120 and may extend in the second horizontal direction (the Y direction).

The plurality of bit lines 170 may extend in the first horizontal direction (the X direction) and may be spaced apart from each other in the second horizontal direction (the Y direction). The bit lines 170 may be in contact with, and electrically connected to, the plurality of first channel patterns 110 and the plurality of second channel patterns 120. For example, the bit lines 170 may be in contact with respective ends of the first channel patterns 110 and respective ends of the second channel patterns 120 in the vertical direction (the Z direction).

The plate electrode 180 may be in contact with the first channel patterns 110. For example, the plate electrode 180 may be in contact with respective opposite ends of the first channel patterns 110 in the vertical direction (the Z direction). The plate electrode 180 may have a plate shape extending in the first horizontal direction (the X direction) and the second horizontal direction (the Y direction) and may be in contact with the first channel patterns 110 arranged in rows in the first horizontal direction (the X direction) and the second horizontal direction (the Y direction). In one or more example embodiments, the plate electrode 180 may be electrically grounded.

Referring to FIG. 49B, a semiconductor device 1010a may include the plurality of plate electrodes 180S each being in contact with the plurality of second channel patterns 120. The plate electrodes 180S may extend in the first horizontal direction (the X direction) and may be arranged in a row in the second horizontal direction (the Y direction). Each of the plate electrodes 180S may be in contact with the plurality of first channel patterns 110 arranged in a row in the first horizontal direction (the X direction). In one or more example embodiments, the plate electrodes 180S may be electrically grounded.

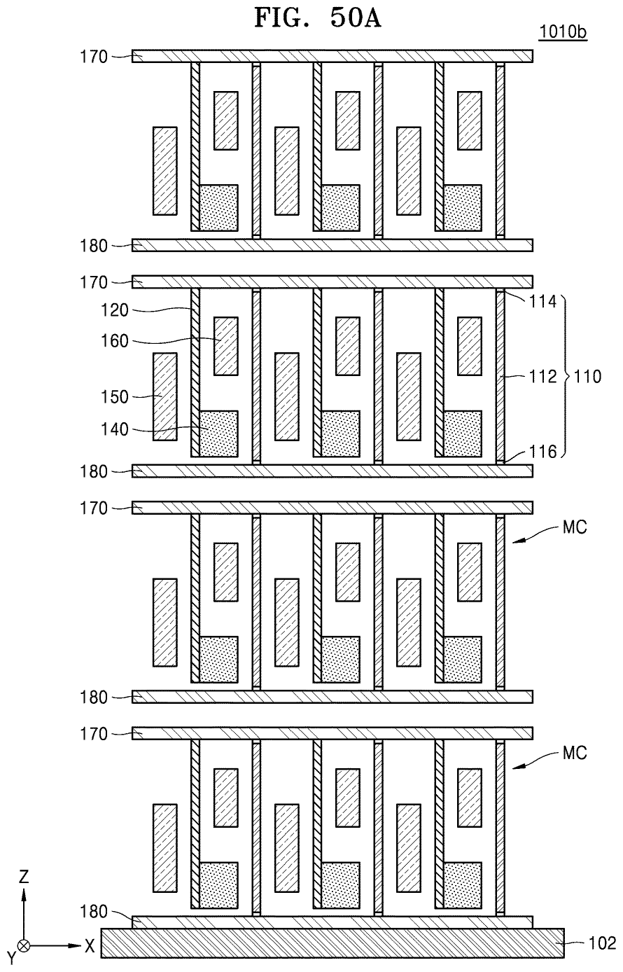

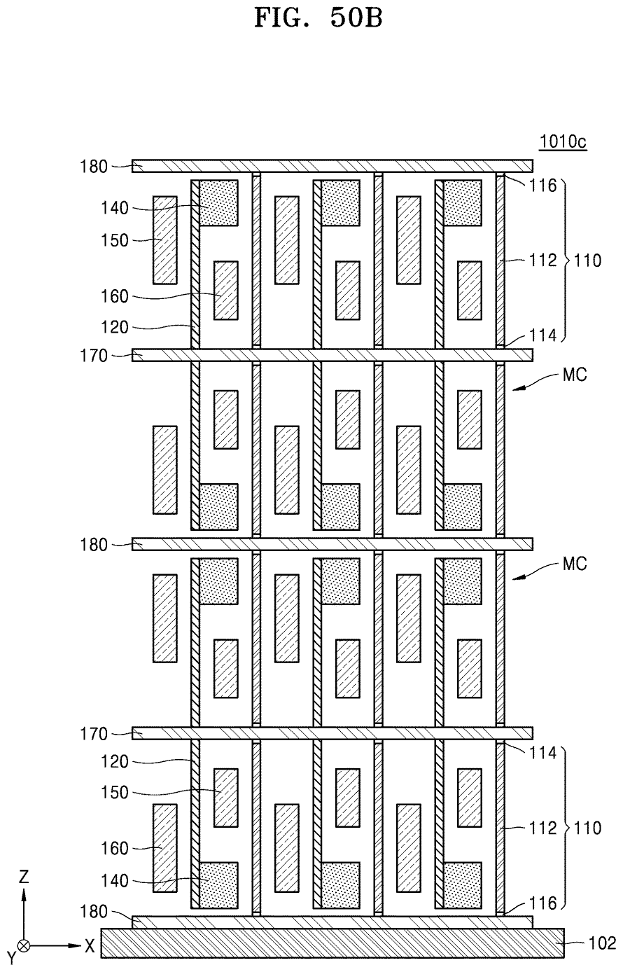

FIGS. 50A and 50B respectively illustrate semiconductor devices including a plurality of memory cells, according to one or more example embodiments.

Referring to FIG. 50A, a semiconductor device 1010b may include the memory cells MC stacked in the vertical direction (the Z direction) on the substrate 102. Each of the memory cells MC may include the first channel pattern 110, the second channel pattern 120, the information storage element 140, the word line 160, the back-gate line 150, the bit line 170, and the plate electrode 180. For example, the plurality of first channel patterns 110 may extend in the vertical direction (the Z direction) and may be spaced apart from each other in the vertical direction (the Z direction). The plurality of second channel patterns 120 may extend in the vertical direction (the Z direction) and may be spaced apart from each other in the vertical direction (the Z direction). The plurality of bit lines 170 and the plurality of plate electrodes 180 may extend in the first horizontal direction (the X direction) and may be spaced apart from each other in the vertical direction (the Z direction).

In one or more example embodiments, the bit lines 170 and the plate electrodes 180 may be alternately arranged in the vertical direction (the Z direction). Each of the bit lines 170 may be in contact with the plurality of first channel patterns 110 and the plurality of second channel patterns 120, and each of the plate electrodes 180 may be in contact with the first channel patterns 110. The first channel pattern 110, the second channel pattern 120, the information storage element 140, the word line 160, and the back-gate line 150, may be arranged between one plate electrode 180 and one bit line 170 above the plate electrode 180. The first channel pattern 110, the second channel pattern 120, the information storage element 140, the word line 160, and the back-gate line 150 may not be arranged between one bit line 170 and one plate electrode 180 above the bit line 170.

Referring to FIG. 50B, a semiconductor device 1010c may include the memory cells MC stacked in the vertical direction (the Z direction) on the substrate 102. The bit lines 170 and the plate electrodes 180 may be alternately arranged in the vertical direction (the Z direction). The memory cells MC adjacent to each other in the vertical direction (the Z direction) may share the bit line 170 and the plate electrode 180.

The first channel pattern 110, the second channel pattern 120, the information storage element 140, the word line 160, and the back-gate line 150 may be arranged between one plate electrode 180 and one bit line 170 above the plate electrode 180. The first channel pattern 110, the second channel pattern 120, the information storage element 140, the word line 160, and the back-gate line 150 may be arranged between one bit line 170 and one plate electrode 180 above the bit line 170.

The memory cells MC adjacent to each other in the vertical direction (the Z direction) may be arranged in mirror symmetry with respect to the bit line 170. The memory cells MC adjacent to each other in the vertical direction (the Z direction) may be arranged in mirror symmetry with respect to the plate electrode 180. The top surfaces and the bottom surfaces of the bit lines 170 may be in contact with first channel patterns 110 and second channel patterns 120. The top surfaces and the bottom surfaces of the plate electrodes 180 may be in contact with the first channel patterns 110.

While example embodiments have been particularly shown and described, it will be apparent to those skilled in the art that various changes in form and details may be made therein without departing from the spirit and scope of the following claims.

What is claimed is:

1. A semiconductor device comprising:
a first channel pattern extending in a first direction;
a second channel pattern adjacent to the first channel pattern and extending in the first direction;
a bit line connected to a first end of the first channel pattern and a first end of the second channel pattern and extending in a second direction orthogonal to the first direction;
an information storage element connected to a second end of the second channel pattern, the second end of the second channel pattern being opposite to the first end of the second channel pattern in the first direction;
a word line between the first channel pattern and the second channel pattern and adjacent to the information storage element in the first direction; and
a back-gate line adjacent to at least one of the first channel pattern and the second channel pattern.

2. The semiconductor device of claim 1, wherein the word line is spaced apart from the information storage element by a first separation distance in the first direction, and
wherein the back-gate line is spaced apart from the information storage element by a second separation distance in the second direction, and the second separation distance is less than the first separation distance.

3. The semiconductor device of claim 1, wherein the word line is spaced apart from the bit line by a third separation distance in the first direction, and
wherein the back-gate line is spaced apart from the bit line by a fourth separation distance in the first direction, and the fourth separation distance is greater than the third separation distance.

4. The semiconductor device of claim 1, wherein the first channel pattern is spaced apart from the second channel pattern in the second direction.

5. The semiconductor device of claim 1, wherein each of the word line and the back-gate line extends in a third direction that is orthogonal to the first direction and the second direction.

6. The semiconductor device of claim 1, further comprising:
a plate electrode spaced apart from the bit line in the first direction and connected to a second end of the first channel pattern, wherein the second end of the first channel pattern is opposite to the first end of the first channel pattern in the first direction.

7. The semiconductor device of claim 6, wherein the plate electrode is spaced apart from the second channel pattern in the first direction and is spaced apart from the information storage element in the first direction.

8. The semiconductor device of claim 1, wherein the back-gate line is closer to the second channel pattern than to the first channel pattern.

9. The semiconductor device of claim 1, wherein the back-gate line is closer to the first channel pattern than to the second channel pattern.

10. The semiconductor device of claim 1, further comprising:
a first gate dielectric layer between the first channel pattern and the information storage element;
a second gate dielectric layer between the second channel pattern and the back-gate line; and
a third gate dielectric layer between the first channel pattern and the word line and provided between the second channel pattern and the word line.

11. A semiconductor device comprising:
a substrate;
first channel patterns extending in a first direction on the substrate;
second channel patterns extending in the first direction on the substrate and spaced apart from the first channel patterns in a second direction that is orthogonal to the first direction;
bit lines connected to first ends of the first channel patterns and first ends of the second channel patterns and extending in the second direction;
information storage elements connected to second ends of the second channel patterns, the second ends of the second channel patterns being opposite to the first ends of the second channel patterns in the first direction;
word lines, each of the word lines being between one of the first channel patterns and one of the second channel patterns, which are adjacent to each other in the second direction, each of the word lines being adjacent to one of the information storage elements in the first direction, and each of the word lines extending in a third direction that is orthogonal to the first direction and the second direction; and
back-gate lines adjacent to the information storage elements and extending in the third direction.

12. The semiconductor device of claim 11, wherein each of the word lines is spaced apart from an adjacent one of the information storage elements by a first separation distance in the first direction, and
wherein each of the back-gate lines is spaced apart from an adjacent one of the information storage elements by a second separation distance in the second direction, and the second separation distance is less than the first separation distance.

13. The semiconductor device of claim 12, wherein each of the back-gate lines and the adjacent one of the information storage elements at least partially overlap each other in the second direction and are spaced apart from each other by the second separation distance in the second direction.

14. The semiconductor device of claim 11, further comprising:
at least one plate electrode spaced apart from the bit lines, spaced apart from the second channel patterns, spaced apart from the information storage elements, and connected to second ends of the first channel patterns, wherein the second ends of the first channel patterns are opposite to the first ends of the first channel patterns in the first direction.

15. The semiconductor device of claim 11, wherein the first channel patterns are arranged in rows in the second direction and rows in the third direction,
wherein the second channel patterns are arranged in rows in the second direction and rows in the third direction, and
wherein the bit lines are arranged in a row in the third direction.

16. The semiconductor device of claim 15, wherein two of the second channel patterns adjacent to each other in the second direction are between two of the first channel patterns adjacent to each other in the second direction, and
wherein each of the back-gate lines is between the two of the second channel patterns adjacent to each other in the second direction.

17. A semiconductor device comprising:
a substrate;
first channel patterns extending in a first horizontal direction on the substrate;
second channel patterns extending in the first horizontal direction on the substrate and spaced apart from the first channel patterns in a vertical direction;
bit lines connected to first ends of the first channel patterns and first ends of the second channel patterns and extending in the vertical direction;
information storage elements connected to second ends of the second channel patterns, the second ends of the second channel patterns being opposite to the first ends of the second channel patterns in the first horizontal direction;
word lines, each of the word lines being between one of the first channel patterns and one of the second channel patterns, which are adjacent to each other in the vertical direction, each of the word lines being adjacent to one of the information storage elements in the first horizontal direction, and each of the word lines extending in a second horizontal direction that is orthogonal to the first horizontal direction;
back-gate lines adjacent to the second channel patterns and the information storage elements, and extending in the second horizontal direction;
first gate dielectric layers between the first channel patterns and the information storage elements;
second gate dielectric layers between the second channel patterns and the back-gate lines; and
third gate dielectric layers between the first channel patterns and the word lines and between the second channel patterns and the word lines,
wherein each of the word lines is spaced apart from an adjacent one of the information storage elements by a first separation distance in the first horizontal direction, and
wherein each of the back-gate lines is spaced apart from an adjacent one of the information storage elements by a second separation distance in the vertical direction, and the second separation distance is less than the first separation distance.

18. The semiconductor device of claim 17, wherein each of the word lines is spaced apart from an adjacent one of the bit lines by a third separation distance in the first horizontal direction, and
wherein each of the back-gate lines is spaced apart from an adjacent one of the bit lines by a fourth separation distance in the first horizontal direction, and the fourth separation distance is greater than the third separation distance.

19. The semiconductor device of claim 17, wherein each of the first channel patterns comprises a monocrystalline semiconductor material,
wherein each of the second channel patterns comprises an oxide semiconductor material, and
wherein each of the information storage elements comprises an oxide semiconductor material.

20. The semiconductor device of claim 17, wherein the first gate dielectric layers, the second gate dielectric layers, and the third gate dielectric layers comprise an identical material.
